(19) United States
(12) Patent Application Publication
(10) Pub. No.: US 2025/0379144 A1
(43) Pub. Date: Dec. 11, 2025

(54) INSULATING CHIP AND SIGNAL TRANSMISSION DEVICE

(71) Applicant: ROHM CO., LTD., Kyoto (JP)

(72) Inventor: Akira TODA, Kyoto (JP)

(73) Assignee: ROHM CO., LTD., Kyoto (JP)

(21) Appl. No.: 19/223,736

(22) Filed: May 30, 2025

(30) Foreign Application Priority Data
Jun. 5, 2024 (JP) 2024-091685

(51) Int. Cl. H01L 23/528

(52) U.S. Cl. CPC H01L 23/528

(57) ABSTRACT

An insulating chip includes a first coil and a second coil that faces the first coil in the Z direction. The second coil includes a second upper surface, a second lower surface on the opposite side of the second upper surface, a second side surface provided between the second upper surface and the second lower surface in the Z direction, and a second corner portion between the second side surface and the second upper surface. The second corner portion includes a second recess having a second curved surface so as to be convex inward toward the second coil.

### CROSS REFERENCE TO RELATED APPLICATION

This application is based upon and claims the benefit of priority of the prior Japanese Patent Application No. 2024-091685, filed on Jun. 5, 2024, the entire contents of which are incorporated herein by reference.

### TECHNICAL FIELD

The present disclosure relates to an insulating chip and a signal transmission device.

### BACKGROUND ART

Conventionally, a signal transmission device that transmits a pulse signal while insulating between input and output has been used in various applications such as power supply devices and motor drive devices. As one example of a signal transmission device, an insulating-type gate driver that applies a gate voltage to the gate of a switching element such as a transistor is known. As one example of an insulating chip used in such a gate driver, a structure including a coil formed within an insulating-layer laminated structure is known (for example, see Japanese Unexamined Patent Application Publication No. 2018-78169).

### BRIEF DESCRIPTION OF THE DRAWINGS

FIG. 1 is a schematic circuit diagram of an exemplary signal transmission device according to the first embodiment.

FIG. 2 is a schematic plan view schematically showing the configuration of the signal transmission device of FIG. 1.

FIG. 3 is a schematic cross-sectional view taken along line F3-F3 in FIG. 2 of the signal transmission device.

FIG. 4 is a schematic perspective view showing the insulating chip of the first embodiment.

FIG. 5 is a schematic plan view of the insulating chip of FIG. 4.

FIG. 6 is a schematic cross-sectional view showing the first coil of the insulating chip of FIG. 5.

FIG. 7 is a schematic cross-sectional view showing the second coil of the insulating chip of FIG. 5.

FIG. 8 is a schematic cross-sectional view taken along line F8-F8 in FIG. 5 of the insulating chip.

FIG. 9 is a schematic cross-sectional view taken along line F9-F9 in FIG. 5 of the insulating chip.

FIG. 10 is a schematic cross-sectional view showing an enlarged view of the first coil and its surroundings in FIG. 8 of the insulating chip.

FIG. 11 is a schematic cross-sectional view showing an enlarged portion of the first coil of FIG. 10.

FIG. 12 is a schematic cross-sectional view showing an enlarged portion of the inner end wiring of FIG. 10.

FIG. 13 is a schematic cross-sectional view showing an enlarged view of the second coil and its surroundings in FIG. 8 of the insulating chip.

FIG. 14 is a schematic cross-sectional view showing an enlarged portion of the second coil of FIG. 13.

FIG. 15 is a schematic cross-sectional view for explaining the manufacturing process of the second coil of FIG. 13.

FIG. 16 is a schematic cross-sectional view showing the subsequent manufacturing process following FIG. 15.

FIG. 17 is a schematic cross-sectional view showing the subsequent manufacturing process following FIG. 16.

FIG. 18 is a schematic cross-sectional view showing the subsequent manufacturing process following FIG. 17.

FIG. 19 is a schematic cross-sectional view showing the subsequent manufacturing process following FIG. 18.

FIG. 20 is a schematic cross-sectional view showing the subsequent manufacturing process following FIG. 19.

FIG. 21 is a schematic cross-sectional view showing the subsequent manufacturing process following FIG. 20.

FIG. 22 is a schematic cross-sectional view showing the subsequent manufacturing process following FIG. 21.

FIG. 23 is a schematic cross-sectional view of the through wiring and its surroundings in the exemplary insulating chip according to the second embodiment.

FIG. 24 is a schematic cross-sectional view showing an enlarged portion of the first layer wiring of FIG. 23.

FIG. 25 is a schematic cross-sectional view showing an enlarged portion of the second layer wiring of FIG. 23.

FIG. 26 is a schematic cross-sectional view showing an enlarged seal portion of the insulating chip of the third embodiment.

FIG. 27 is a schematic cross-sectional view of the first seal portion of FIG. 26 and its surroundings.

FIG. 28 is a schematic cross-sectional view of the second seal portion of FIG. 26 and its surroundings.

FIG. 29 is a schematic circuit diagram of an exemplary signal transmission device according to the fourth embodiment.

FIG. 30 is a schematic cross-sectional view of the insulating chip in the signal transmission device of FIG. 29.

FIG. 31 is a schematic cross-sectional view showing an enlarged portion of the first electrode plate, second electrode plate, and their surroundings of the insulating chip in FIG. 30.

FIG. 32 is a schematic cross-sectional view showing an enlarged portion of a part of the first electrode plate and its surroundings of FIG. 30.

FIG. 33 is a schematic cross-sectional view showing an enlarged portion of a part of the second electrode plate and its surroundings of FIG. 30.

FIG. 34 is a schematic cross-sectional view showing an enlarged portion of a part of the second coil and its surroundings in the insulating chip of the modification example.

FIG. 35 is a schematic cross-sectional view showing an enlarged portion of a part of the first coil and its surroundings in the insulating chip of the modification example.

FIG. 36 is a schematic plan view of the insulating chip of the modification example.

FIG. 37 is a schematic cross-sectional view of the insulating chip of the modification example.

FIG. 38 is a schematic cross-sectional view showing an enlarged portion of the through wiring and its surroundings of FIG. 37.

FIG. 39 is a schematic cross-sectional view showing an enlarged portion of each of the first via and second via of FIG. 38.

FIG. 40 is a schematic cross-sectional view of the through wiring and its surroundings in the insulating chip of the modification example.

FIG. 41 is a schematic cross-sectional view of each of the first via and second via in the through wiring of FIG. 40.

FIG. 42 is a schematic cross-sectional view of the through wiring and its surroundings in the insulating chip of the modification example.

FIG. 43 is a schematic cross-sectional view of the through wiring and its surroundings in the insulating chip of the modification example.

FIG. 44 is a schematic cross-sectional view of each of the first via and second via in the insulating chip of the modification example.

FIG. 45 is a schematic cross-sectional view of each of the first via and second via in the insulating chip of the modification example.

FIG. 46 is a schematic cross-sectional view of each of the first via and second via in the insulating chip of the modification example.

FIG. 47 is a schematic cross-sectional view of each of the first via and second via in the insulating chip of the modification example.

FIG. 48 is a schematic plan view of the signal transmission device of the modification example.

### DETAILED DESCRIPTION OF EMBODIMENTS

Hereinafter, several embodiments of the insulating chip and signal transmission device of the present disclosure will be described with reference to the accompanying drawings. For clarity and simplicity of explanation, the components shown in the drawings are not necessarily drawn to scale. In addition, in the cross-sectional views, hatching lines may be omitted to facilitate understanding. The accompanying drawings merely illustrate embodiments of the present disclosure and should not be construed as limiting the present disclosure.

The following detailed description includes devices, systems, and methods that embody exemplary embodiments of the present disclosure. This detailed description is intended solely for explanation and is not intended to limit the embodiments of the present disclosure or the application and use of such embodiments.

The terms “first,” “second,” “third,” and so on, used in the present disclosure are merely labels and are not intended to necessarily indicate any order of the corresponding items.

The expression “at least one” used in the present disclosure means “one or more” of the desired choices. As one example, the expression “at least one” used in the present disclosure means “only one choice” or “both of the two choices” when the number of choices is two.

As another example, the expression “at least one” used in the present disclosure means “only one choice” or “any combination of two or more choices” when the number of choices is three or more.

The expression “dimension (width, length) of A is equal to the dimension (width, length) of B” or “the dimension (width, length) of A and the dimension (width, length) of B are equal to each other” as used in the present disclosure includes a relationship in which the difference between the dimension (width, length) of A and the dimension (width, length) of B is within 10% of the dimension (width, length) of A, for example.

### First Embodiment

### [Overall Configuration of Signal Transmission Device]

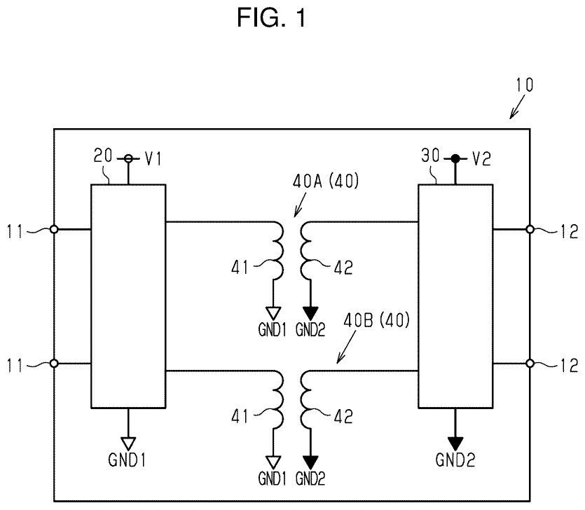

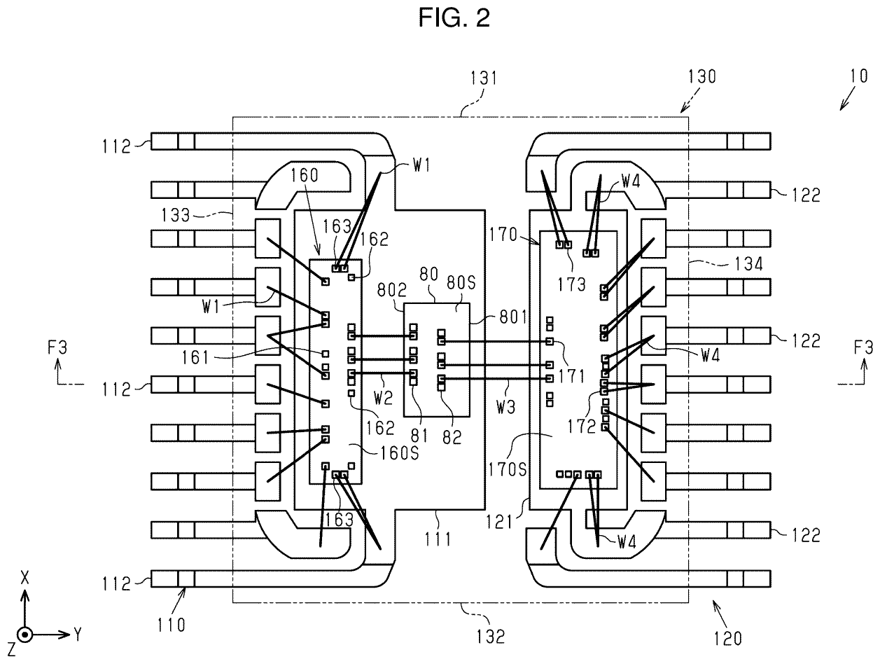

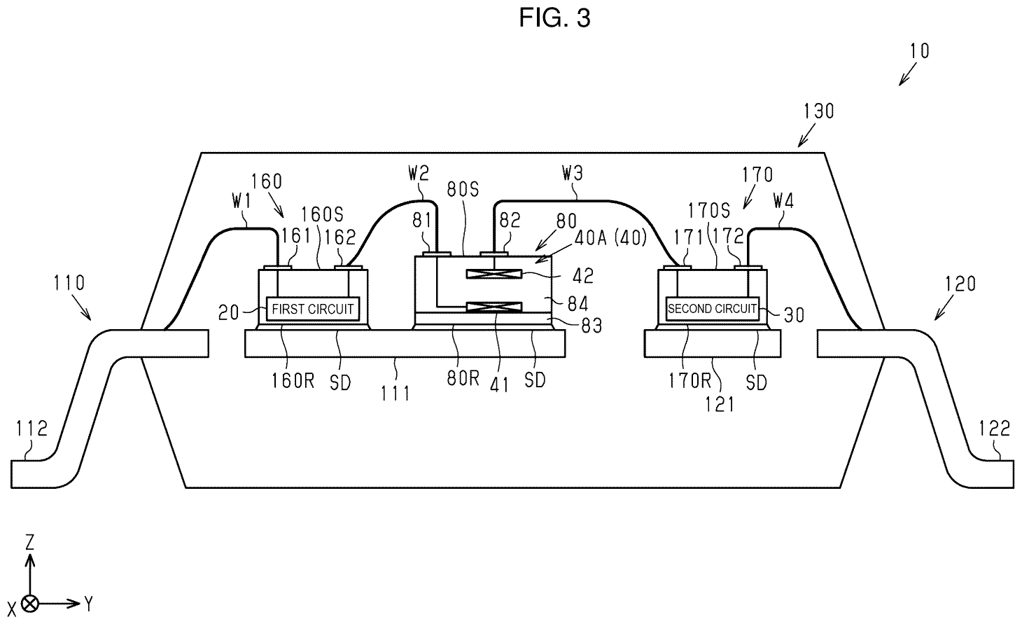

The overall configuration of a signal transmission device 10 of the first embodiment will be described with reference to FIGS. 1 to 3. FIG. 1 schematically shows an example of a circuit configuration of the signal transmission device 10. FIG. 2 shows an example of a planar structure schematically illustrating the internal structure of the signal transmission device 10. FIG. 3 shows an example of a sectional structure schematically illustrating a part of the internal configuration of the signal transmission device 10. In FIG. 3, hatching lines are omitted to facilitate understanding of the drawing.

As shown in FIG. 1, the signal transmission device 10 includes a plurality of first terminals 11 and a plurality of second terminals 12. The plurality of first terminals 11 and the plurality of second terminals 12 are external terminals that are electrically connected to wiring on a circuit board when the signal transmission device 10 is mounted on a circuit board (not shown). The plurality of first terminals 11 and the plurality of second terminals 12 are used as signal input/output terminals (input terminals, output terminals), power supply terminals that supply a drive power supply, and ground terminals in the signal transmission device 10.

The signal transmission device 10 is a device that transmits signals while electrically insulating between the first terminal 11 and the second terminal 12, which are used as input and output terminals. The signal transmission device 10 is, for example, a digital isolator.

The signal transmission device 10 includes a first circuit 20 electrically connected to the first terminal 11, a second circuit 30 electrically connected to the second terminal 12, and a transformer 40 connected between the first circuit 20 and the second circuit 30.

The first circuit 20 is a circuit configured to operate when a first voltage V1 is applied.

The first circuit 20 is electrically connected to an external control device (not shown), for example. The second circuit 30 is a circuit configured to operate when a second voltage V2 is applied. In one example, the second voltage V2 may be a voltage different from the first voltage V1. In one example, the second voltage V2 may be a voltage higher than the first voltage V1. The second voltage V2 may also be a voltage lower than the first voltage V1.

The second voltage V2 may also be equal to the first voltage V1. The first voltage V1 and the second voltage V2 are direct current voltages. The second circuit 30 is electrically connected to a drive circuit that is subject to control by a control device, for example. One example of the drive circuit is a switching circuit. The second circuit 30 may include the drive circuit.

In the signal transmission device 10, the ground of the second circuit 30 and the ground of the first circuit 20 are independently provided. In one example, the potentials of the grounds of the first circuit 20 and the second circuit 30 may be used as reference potentials. That is, the potential of the ground GND1 of the first circuit 20 may be used as a first reference potential, and the potential of the ground GND2 of the second circuit 30 may be used as a second reference potential. The first voltage V1 is a voltage from the first reference potential, and the second voltage V2 is a voltage from the second reference potential.

The signal transmission device 10 shown in FIG. 1 is configured to output two signals from the first circuit 20 toward the second circuit 30. The transformer 40 includes two transformers 40A and 40B corresponding to the two signals.

The transformers 40A and 40B each include a first coil 41 and a second coil 42. The first coil 41 and the second coil 42 of each of the transformers 40A and 40B are electrically insulated from each other and configured to allow magnetic coupling. Therefore, the first circuit 20 and the second circuit 30 are electrically insulated from each other. The first circuit 20 and the second circuit 30 are magnetically coupled via the first coil 41 and the second coil 42 of the transformers 40A and 40B, and are connected so as to allow signal transmission.

The first coil 41 of the transformers 40A and 40B is electrically connected to the first circuit 20. The second coil 42 of the transformers 40A and 40B is electrically connected to the second circuit 30. In one example, a control signal from a control device, for example, is input to the first circuit 20 through the first terminal 11. The first circuit 20 outputs a transmission signal toward the second circuit 30 in accordance with the control signal.

The transmission signal is received by the second circuit 30 via the transformers 40A and 40B. The second circuit 30 outputs a signal corresponding to the received signal, such as a gate drive signal, to the drive circuit through the second terminal 12. The second circuit 30 may be configured to output a signal toward the first circuit 20, and the first circuit 20 may be configured to receive the signal. The first circuit 20 and the second circuit 30 may each be configured to transmit and receive signals.

As described above, in the signal transmission device 10, the first circuit 20 and the second circuit 30 are electrically insulated by the transformer 40. More specifically, the transformer 40 restricts the transmission of direct current voltage between the first circuit 20 and the second circuit 30. On the other hand, the transformer 40 allows the transmission of pulse signals between the first circuit 20 and the second circuit 30. The transformer 40 is an insulating element that electrically insulates between the second circuit 30 and the first circuit 20 and transmits signals between the second circuit 30 and the first circuit 20.

In other words, the state in which the first circuit 20 and the second circuit 30 are insulated means a state in which the transmission of direct current voltage between the first circuit 20 and the second circuit 30 is blocked, while the transmission of pulse signals from the first circuit 20 to the second circuit 30 is allowed. In this way, in the first embodiment, the second circuit 30 is configured to receive signals from the first circuit 20.

The first circuit 20 and the second circuit 30 may also be referred to as a primary-side circuit and a secondary-side circuit with respect to the transformer 40. In one example, the second circuit 30 is the secondary-side circuit, and the first circuit 20 is the primary-side circuit.

The second circuit 30 may be the primary-side circuit, and the first circuit 20 may be the secondary-side circuit. The second circuit 30 and the first circuit 20 may each include a primary-side circuit and a secondary-side circuit.

As shown in FIGS. 2 and 3, the signal transmission device 10 includes a first support member 110, a second support member 120, an insulating chip 80, a first circuit chip 160, a second circuit chip 170, and sealing resin 130. The first support member 110 mounts the first circuit chip 160 and the insulating chip 80. The second support member 120 mounts the second circuit chip 170. In this way, the signal transmission device 10 is a semiconductor module in which the first circuit chip 160, the second circuit chip 170, and the insulating chip 80 are packaged. The insulating chip 80 includes the transformers 40A and 40B shown in FIG. 1.

The first circuit chip 160 includes the first circuit 20 shown in FIG. 1. The second circuit chip 170 includes the second circuit 30 shown in FIG. 1. The configuration of the signal transmission device 10 can be arbitrarily modified. In one example, the signal transmission device 10 may include chips other than the first circuit chip 160, the second circuit chip 170, and the insulating chip 80.

The package type of the signal transmission device 10 is an SO (Small Outline) type, and in one example, is an SOP (Small Outline Package). The package type of the signal transmission device 10 can be arbitrarily changed. The package type of the signal transmission device 10 is not limited to SOP, and may be a QFN (Quad Flat Non-lead Package), a DFP (Dual Flat Package), a DIP (Dual Inline Package), an SOJ (Small Outline J-leaded Package), or various package types similar to these.

The sealing resin 130 seals the first circuit chip 160, the second circuit chip 170, and the insulating chip 80, and also partially seals the first support member 110 and the second support member 120. In FIG. 2, the sealing resin 130 is indicated by a two-dot chain line for the purpose of explaining the internal structure of the signal transmission device 10.

The sealing resin 130 is made of a resin material having electrical insulation properties.

As this resin material, for example, a resin containing epoxy resin is used. The resin may be colored, such as black. The sealing resin 130 is a rectangular plate shape having the Z direction as the thickness direction. The sealing resin 130 includes four resin side surfaces 131 to 134. The resin side surfaces 131 and 132 form both end surfaces of the sealing resin 130 in the X direction. The resin side surfaces 133 and 134 form both end surfaces of the sealing resin 130 in the Y direction. Here, the X direction and the Y direction are directions orthogonal to the Z direction. The X direction and the Y direction are mutually orthogonal.

In the following description, “plan view” means viewing the signal transmission device 10 or each component of the signal transmission device 10 from the Z direction.

Each of the first support member 110 and the second support member 120 is conductive. Each of the first support member 110 and the second support member 120 is made of a conductive material including Cu (copper), Fe (iron), or Al (aluminum). Each of the first support member 110 and the second support member 120 is provided so as to span the inside and outside of the sealing resin 130.

The first support member 110 includes a first die pad 111 disposed inside the sealing resin 130 and a plurality of first lead terminals 112 disposed so as to span the inside and outside of the sealing resin 130. The first die pad 111 is a flat plate shape having the Z direction as the thickness direction. In plan view, the first die pad 111 is disposed such that the center in the Y direction is positioned closer to the resin side surface 133 than the center in the Y direction of the sealing resin 130. The first die pad 111 is not exposed from the sealing resin 130.

In one example, the first die pad 111 has a rectangular shape in which the X direction is the long side and the Y direction is the short side in plan view. The shape of the first die pad 111 in plan view can be arbitrarily changed.

The plurality of first lead terminals 112 are arranged spaced apart from each other in the X direction. Each of the first lead terminals 112 disposed at both ends in the X direction among the plurality of first lead terminals 112 is integrated with the first die pad 111. A part of each first lead terminal 112 protrudes outward from the sealing resin 130 through the resin side surface 133. The plurality of first lead terminals 112 are external terminals of the signal transmission device 10 and correspond to the first terminals 11 in FIG. 1. Here, in FIG. 1, the circuit configuration of the signal transmission device 10 is shown in a simplified manner, so the number of first lead terminals 112 shown in FIG. 2 is greater than the number of first terminals 11 shown in FIG. 1.

The second support member 120 includes a second die pad 121 disposed inside the sealing resin 130 and a plurality of second lead terminals 122 disposed so as to span the inside and outside of the sealing resin 130. The second die pad 121 is a flat plate shape having the Z direction as the thickness direction. In plan view, the second die pad 121 is disposed closer to the resin side surface 134 than the first die pad 111. The second die pad 121 is not exposed from the sealing resin 130. In one example, the second die pad 121 has a rectangular shape in which the X direction is the long side and the Y direction is the short side in plan view.

The first die pad 111 and the second die pad 121 are arranged spaced apart from each other in the Y direction. Therefore, the Y direction can be considered the arrangement direction of the first die pad 111 and the second die pad 121.

The dimension in the Y direction of the first die pad 111 and the second die pad 121 is set according to the size and number of the semiconductor chips mounted thereon. In the first embodiment, both the first circuit chip 160 and the insulating chip 80 are mounted on the first die pad 111, and the second circuit chip 170 is mounted on the second die pad 121. Therefore, the dimension in the Y direction of the first die pad 111 is set to be greater than the dimension in the Y direction of the second die pad 121.

The plurality of second lead terminals 122 are arranged spaced apart from each other in the X direction. Among the plurality of second lead terminals 122, two of the second lead terminals 122 are integrated with the second die pad 121. A part of each second lead terminal 122 protrudes outward from the sealing resin 130 through the resin side surface 134. The plurality of second lead terminals 122 are external terminals of the signal transmission device 10 and correspond to the second terminals 12 in FIG. 1. Here, in FIG. 1, the circuit configuration of the signal transmission device 10 is shown in a simplified manner, so the number of second lead terminals 122 shown in FIG. 2 is greater than the number of second terminals 12 shown in FIG. 1.

In the first embodiment, the number of second lead terminals 122 is the same as the number of first lead terminals 112. As seen from FIG. 2, the plurality of first lead terminals 112 and the plurality of second lead terminals 122 are arranged in a direction (X direction) orthogonal to the arrangement direction (Y direction) of the first die pad 111 and the second die pad 121. The number of second lead terminals 122 and the number of first lead terminals 112 can each be arbitrarily changed.

The first support member 110 and the second support member 120 are formed from a lead frame (not shown). In the manufacturing process of the signal transmission device 10, the first die pad 111, the plurality of first lead terminals 112, the second die pad 121, and the plurality of second lead terminals 122 are formed from the same lead frame.

The lead frame includes an outer frame formed so as to surround the first support member 110 and the second support member 120. The first lead terminals 112 and the second lead terminals 122 are connected to the outer frame. In the manufacturing process of the signal transmission device 10, the first lead terminals 112 and the second lead terminals 122 are formed by being cut off from the outer frame.

The first die pad 111 is integrated with two first lead terminals 112. The first die pad 111 is supported by the two first lead terminals 112 integrated with the first die pad 111. The second die pad 121 is integrated with two second lead terminals 122. The second die pad 121 is supported by the two second lead terminals 122 integrated with the second die pad 121. Therefore, no suspension leads are provided on the first die pad 111 and the second die pad 121 that are exposed from the resin side surfaces 131 and 132. Accordingly, a large insulation distance (creepage distance) can be secured between the first support member 110 and the second support member 120.

The first die pad 111 may be supported by one first lead terminal 112. Similarly, the second die pad 121 may be supported by one second lead terminal 122.

The first circuit chip 160 and the insulating chip 80 mounted on the first die pad 111 and the second circuit chip 170 mounted on the second die pad 121 are arranged spaced apart from each other in the Y direction. In the Y direction, the first circuit chip 160, the insulating chip 80, and the second circuit chip 170 are arranged in this order from the first lead terminal 112 toward the second lead terminal 122. Therefore, the Y direction can be considered the arrangement direction of the first circuit chip 160, the insulating chip 80, and the second circuit chip 170. The insulating chip 80 is disposed between the first circuit chip 160 and the second circuit chip 170 in the Y direction.

The first circuit chip 160 has a rectangular shape having a short side and a long side in plan view. In one example, the first circuit chip 160 is mounted on the first die pad 111 such that the long side extends along the X direction and the short side extends along the Y direction in plan view.

As shown in FIG. 3, the first circuit chip 160 includes a chip front surface 160S and a chip back surface 160R, which face in opposite directions in the Z direction. The chip back surface 160R is bonded to the first die pad 111 by a conductive bonding material SD. As the conductive bonding material SD, for example, solder or Ag (silver) paste is used.

As shown in FIG. 2, the chip front surface 160S of the first circuit chip 160 is provided with a plurality of first electrode pads 161, a plurality of second electrode pads 162, and a plurality of third electrode pads 163. At least one of the plurality of first electrode pads 161, at least one of the plurality of second electrode pads 162, and at least one of the plurality of third electrode pads 163 are each electrically connected to the first circuit 20 shown in FIG. 1.

The plurality of first electrode pads 161 are disposed on the chip front surface 160S closer to the first lead terminal 112 than the center in the Y direction of the chip front surface 160S. In one example, the plurality of first electrode pads 161 are arranged in the X direction. The plurality of second electrode pads 162 are disposed at the end of the chip front surface 160S in the Y direction that is closer to the insulating chip 80. The plurality of second electrode pads 162 are arranged in the X direction. The plurality of third electrode pads 163 are disposed at both ends of the chip front surface 160S in the X direction.

The second circuit chip 170 has a rectangular shape having a short side and a long side in plan view. The second circuit chip 170 is mounted on the second die pad 121 such that the long side extends along the X direction and the short side extends along the Y direction in plan view.

As shown in FIG. 3, the second circuit chip 170 includes a chip front surface 170S and a chip back surface 170R, which face in opposite directions in the Z direction. The chip back surface 170R is bonded to the second die pad 121 by a conductive bonding material SD.

As shown in FIG. 2, the chip front surface 170S of the second circuit chip 170 is provided with a plurality of first electrode pads 171, a plurality of second electrode pads 172, and a plurality of third electrode pads 173. At least one of the plurality of first electrode pads 171, at least one of the plurality of second electrode pads 172, and at least one of the plurality of third electrode pads 173 are each electrically connected to the second circuit 30 shown in FIG. 1.

The plurality of first electrode pads 171 are disposed at the end of the chip front surface 170S in the Y direction that is closer to the insulating chip 80. The plurality of first electrode pads 171 are arranged in the X direction. The plurality of second electrode pads 172 are disposed at the end of the chip front surface 170S in the Y direction that is farther from the insulating chip 80. That is, the plurality of second electrode pads 172 are disposed at the end of the chip front surface 170S in the Y direction that is closer to the second lead terminals 122. The plurality of second electrode pads 172 are arranged in the X direction. The plurality of third electrode pads 173 are disposed at both ends of the chip front surface 170S in the X direction.

The insulating chip 80 has a rectangular shape having a short side and a long side in plan view. The insulating chip 80 is mounted on the first die pad 111 such that the long side extends along the X direction and the short side extends along the Y direction. In one example, the dimension of the insulating chip 80 in the X direction is smaller than the dimension of the first circuit chip 160 in the X direction. In one example, the dimension of the insulating chip 80 in the X direction is smaller than the dimension of the second circuit chip 170 in the X direction. The dimension of the insulating chip 80 in the X direction can be arbitrarily changed. In one example, the dimension of the insulating chip 80 in the X direction may be changed according to the number of transformers.

The insulating chip 80 is a semiconductor chip in which the transformers 40A and 40B are integrated on a single chip. That is, the insulating chip 80 is provided as a semiconductor chip different from the first circuit chip 160 and the second circuit chip 170. The insulating chip 80 is disposed adjacent to the first circuit chip 160 in the Y direction.

As shown in FIG. 3, the insulating chip 80 includes a chip front surface 80S and a chip back surface 80R, which face in opposite directions in the Z direction. The chip back surface 80R is bonded to the first die pad 111 by a conductive bonding material SD.

As shown in FIG. 2, the insulating chip 80 includes a plurality of first electrode pads 81 and a plurality of second electrode pads 82. The plurality of first electrode pads 81 and the plurality of second electrode pads 82 are provided on the chip front surface 80S of the insulating chip 80. The plurality of first electrode pads 81 are disposed at the end of the chip front surface 80S in the Y direction that is closer to the first circuit chip 160. The plurality of first electrode pads 81 are arranged in the X direction. The plurality of second electrode pads 82 are disposed near the center of the chip front surface 80S in the Y direction. The plurality of second electrode pads 82 are arranged in the X direction.

In order to achieve a predetermined insulation withstand voltage for the signal transmission device 10, it is necessary to separate the first die pad 111 and the second die pad 121, which are the closest parts between the first support member 110 and the second support member 120. Therefore, the insulating chip 80 is disposed closer to the second circuit chip 170 than to the first circuit chip 160. That is, the distance in the Y direction between the insulating chip 80 and the second circuit chip 170 is greater than the distance in the Y direction between the insulating chip 80 and the first circuit chip 160.

A plurality of wires W1 to W4 are connected to each of the first circuit chip 160, the insulating chip 80, and the second circuit chip 170. Each of the wires W1 to W4 is a bonding wire formed by a wire bonding device. Each of the wires W1 to W4 is made of a conductive material containing, for example, Au (gold), Al, or Cu.

The first circuit chip 160 is electrically connected to the first lead terminal 112 by the wire W1. More specifically, the plurality of first electrode pads 161 are individually and electrically connected to the plurality of first lead terminals 112 by the plurality of wires W1. The plurality of third electrode pads 163 are individually and electrically connected to the two first lead terminals 112 integrated with the first die pad 111 by the plurality of wires W1. As a result, the first circuit 20 shown in FIG. 1 is electrically connected to the plurality of first lead terminals 112. The first lead terminals 112 integrated with the first die pad 111 constitute ground terminals, and the first circuit 20 is electrically connected to the first die pad 111 by the wire W1. Therefore, the first ground GND1 of the first circuit 20 shown in FIG. 1 has the same potential as the first die pad 111.

The second circuit chip 170 is electrically connected to the second lead terminal 122 by the wire W4. More specifically, the plurality of second electrode pads 172 and the plurality of third electrode pads 173 are individually and electrically connected to the plurality of second lead terminals 122 by the plurality of wires W4. A portion of the plurality of third electrode pads 173 is individually and electrically connected to the two second lead terminals 122 integrated with the second die pad 121 by the plurality of wires W4. As a result, the second circuit 30 shown in FIG. 1 is electrically connected to the plurality of second lead terminals 122. The second lead terminals 122 integrated with the second die pad 121 constitute ground terminals, and the second circuit 30 is electrically connected to the second die pad 121 by the wire W4. Therefore, the second ground GND2 of the second circuit 30 shown in FIG. 1 has the same potential as the second die pad 121.

The insulating chip 80 is connected to the first circuit chip 160 by the wire W2. The insulating chip 80 is also connected to the second circuit chip 170 by the wire W3. More specifically, the plurality of first electrode pads 81 of the insulating chip 80 are individually and electrically connected to the plurality of second electrode pads 162 of the first circuit chip 160 by the plurality of wires W2. The plurality of second electrode pads 82 of the insulating chip 80 are individually and electrically connected to the plurality of first electrode pads 171 of the second circuit chip 170 by the plurality of wires W3.

Both of the first coils 41 of the transformers 40A and 40B shown in FIG. 1 are electrically connected to the first ground GND1 of the first circuit chip 160 by the wire W1. Both of the second coils 42 of the transformers 40A and 40B shown in FIG. 1 are electrically connected to the second ground GND2 of the second circuit chip 170 by the wire W4.

The configuration of the signal transmission device 10 shown in FIG. 1 is one example, and the circuit configuration included in the first circuit chip 160 and the second circuit chip 170 may be appropriately changed. In one example, the first circuit 20 may include an analog-to-digital conversion circuit. In this case, the signal transmission device 10 is configured as an isolated A/D conversion device. In one example, the second circuit 30 may include a driver circuit that drives the gate of a switching element. The driver circuit may be connected to a terminal of the signal transmission device 10. In one example, the driver circuit may be electrically connected to the second lead terminal 122. In this case, the signal transmission device 10 is configured as an isolated gate driver that drives the switching element. As the switching element, a power semiconductor device such as a SiMOSFET (Si Metal-Oxide-Semiconductor Field-Effect Transistor), a SiC MOSFET, or an IGBT (Insulated Gate Bipolar Transistor) may be used. The switching element is used in a motor driver circuit in an inverter device. As the driver circuit, a half-bridge circuit in which a low-side switching element and a high-side switching element are connected in a totem pole configuration is generally used.

The signal transmission device 10 used as an isolated gate driver applies a drive voltage signal to the control terminal of a switching element. In this case, the first circuit 20 converts a control signal input from a control device, for example, into a pulse signal. The driver circuit of the second circuit 30 outputs a drive voltage signal to the control terminal of the switching element in accordance with the signal received through the transformers 40A and 40B. The first circuit 20 and the second circuit 30 may be used to transmit detection signals, such as a temperature sensor located near a motor, to the control device.

As described above, in the signal transmission device 10 used as an isolated gate driver, the first voltage V1 of the first circuit 20 that receives a signal from the control device is 5 V, 3.3 V, or the like, based on the ground potential. On the other hand, in the case of the second circuit 30 connected to the high-side switching element, a voltage equivalent to the voltage applied to the drain of the high-side switching element (for example, 600 V or more) is transiently applied. Therefore, the insulation withstand voltage of the signal transmission device 10 is between 2500 Vrms and 7500 Vrms. The specific value of the insulation withstand voltage of the signal transmission device 10 is not limited to this range and may be arbitrarily set.

### [Structure of Insulating Chip]

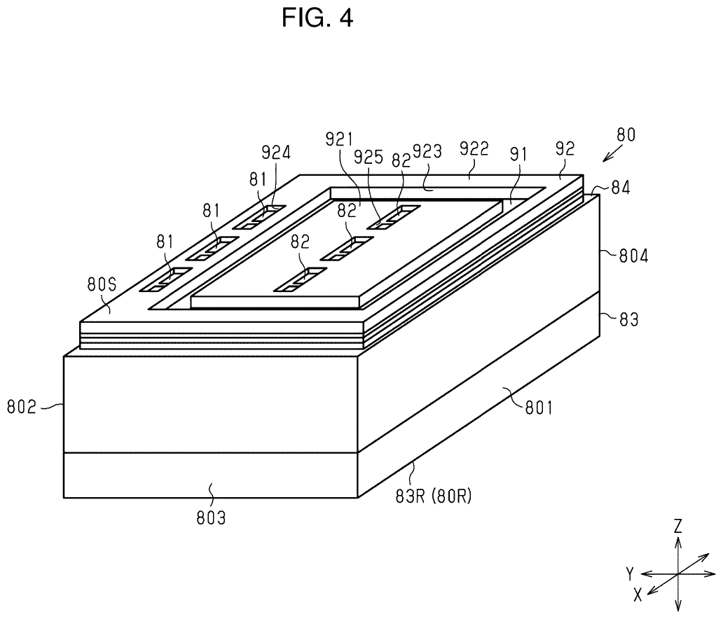

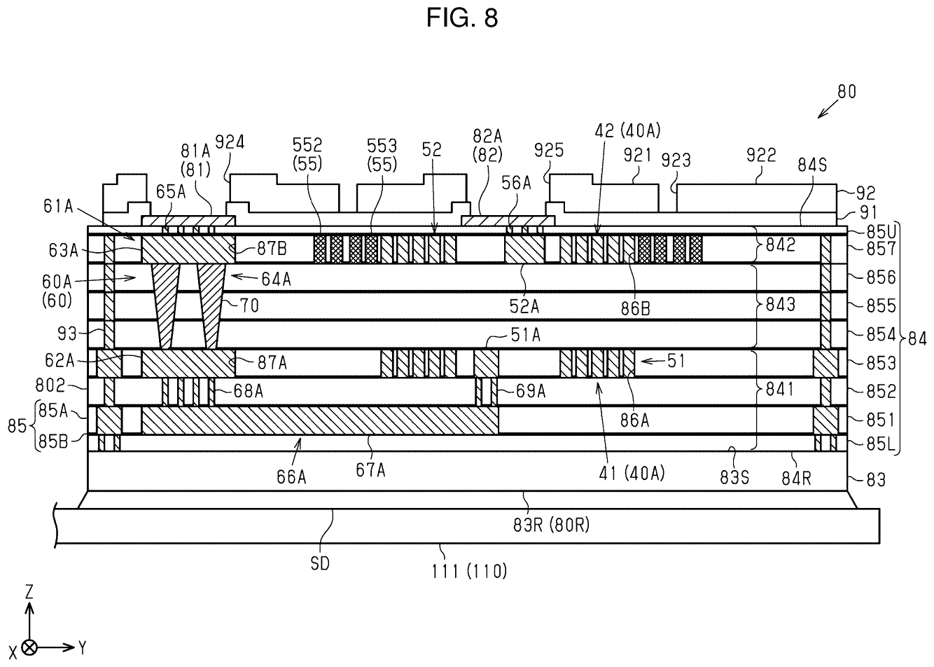

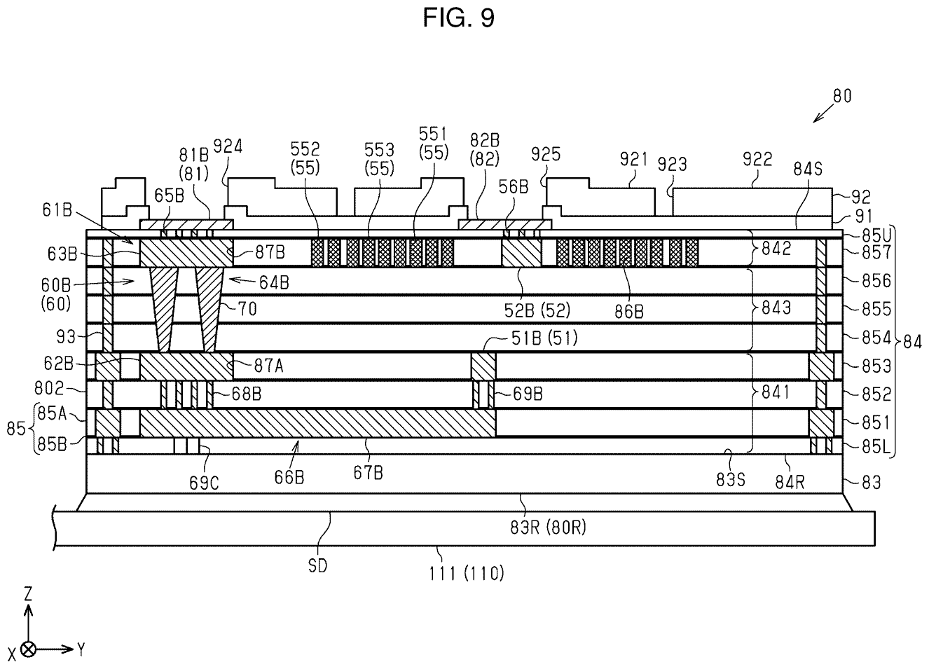

The overall structure of the insulating chip 80 will be described with reference to FIGS. 4 to 9. In the following description, the direction from the chip back surface 80R to the chip front surface 80S in the insulating chip 80 shown in FIGS. 8 and 9 is referred to as upward, and the direction from the chip front surface 80S to the chip back surface 80R is referred to as downward.

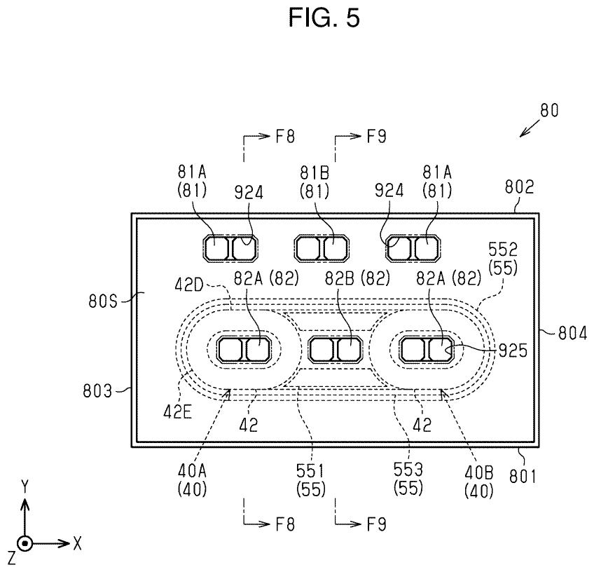

FIG. 4 schematically shows the perspective structure of the insulating chip 80. FIG. 5 schematically shows the planar structure of the insulating chip 80. In FIG. 5, for convenience of explanation, the transformers 40A and 40B and a dummy pattern 55 described later are shown with broken lines. In addition, in FIG. 5, the first electrode pads 81 and the second electrode pads 82 are shown with two-dot chain lines, and the resin openings of the resin layer 92 described later are shown with solid lines.

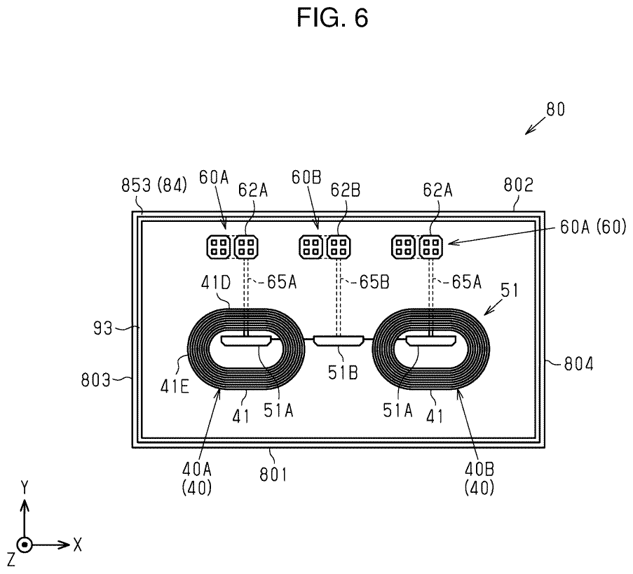

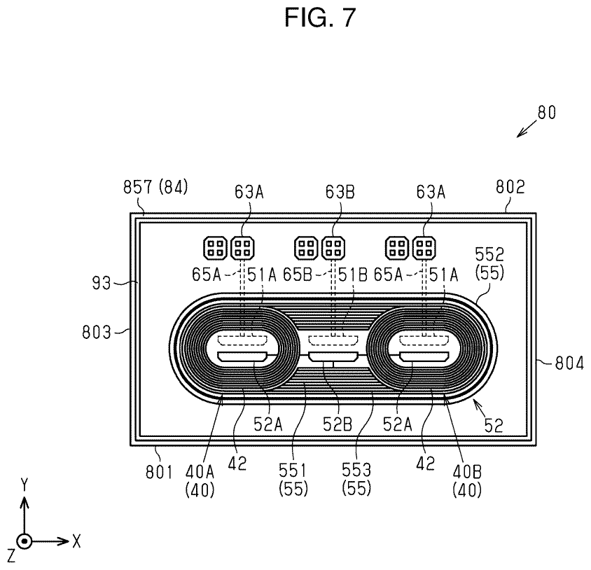

FIG. 6 schematically shows a cross-sectional structure cut in the XY plane at the Z-directional position where the first coil 41 of the insulating chip 80 in FIG. 5 is disposed. FIG. 6 mainly shows the connection relationships of the first coil 41. FIG. 7 schematically shows a cross-sectional structure cut in the XY plane at the Z-directional position where the second coil 42 of the insulating chip 80 in FIG. 5 is disposed. FIG. 7 mainly shows the connection relationships of the second coil 42. In FIGS. 6 and 7, hatching lines are omitted for convenience.

FIG. 8 schematically shows a cross-sectional structure of the insulating chip 80 cut along the line F8-F8 in FIG. 5. FIG. 8 schematically shows the cross-sectional structure of the insulator 84, the first coil 41, the second coil 42, the dummy pattern 55, the first electrode pads 81, the second electrode pads 82, and a first connection wiring 60A described later. FIG. 9 schematically shows a cross-sectional structure of the insulating chip 80 cut along the line F9-F9 in FIG. 5. FIG. 9 schematically shows the cross-sectional structure of the insulator 84, the dummy pattern 55, the first electrode pads 81, the second electrode pads 82, and a second connection wiring 60B described later. In FIGS. 8 and 9, the detailed shapes of a first conductor 51, a second conductor 52, and the first connection wiring 60A are omitted.

As shown in FIG. 5, the transformers 40A and 40B are disposed near the center in the Y direction of the chip front surface 80S in plan view. In one example, the plurality of first electrode pads 81 and the transformers 40A and 40B are disposed at positions that do not overlap each other in plan view. The first electrode pads 81 and the second electrode pads 82 are each electrically connected to the transformers 40A and 40B.

As shown in FIGS. 4 and 5, the insulating chip 80 includes four chip side surfaces 801 to 804 that connect the chip front surface 80S and the chip back surface 80R. The chip side surfaces 801 and 802 form both end surfaces of the insulating chip 80 in the Y direction. The chip side surfaces 803 and 804 form both end surfaces of the insulating chip 80 in the X direction. In plan view, the chip side surfaces 801 and 802 constitute the long sides of the insulating chip 80, and the chip side surfaces 803 and 804 constitute the short sides of the insulating chip 80. As shown in FIG. 2, the chip side surface 801 is the chip side surface closer to the second circuit chip 170 than the chip side surface 802. The chip side surface 802 is the chip side surface closer to the first circuit chip 160 than the chip side surface 801.

As shown in FIGS. 4, 8, and 9, the insulating chip 80 includes a substrate 83 and an insulator 84. The substrate 83 is made of, for example, a semiconductor substrate. The substrate 83 is a substrate made of a material containing Si (silicon). In one example, the substrate 83 is a Si substrate. Examples of the Si substrate used for the substrate 83 include a semiconductor substrate composed of intrinsic single-crystal semiconductor material, a p-type semiconductor substrate containing an acceptor-type impurity, and an n-type semiconductor substrate containing a donor-type impurity.

The substrate 83, as a semiconductor substrate, may also be a wide bandgap semiconductor or a compound semiconductor. As an alternative to the semiconductor substrate, the substrate 83 may be an insulating substrate made of a material containing glass. A wide bandgap semiconductor is a semiconductor substrate having a bandgap of 2.0 eV or more. The wide bandgap semiconductor may be SiC (silicon carbide), GaN (gallium nitride), Ga₂O₃ (gallium oxide), or the like. The compound semiconductor may be a III-V group compound semiconductor. The compound semiconductor may include at least one of AlN (aluminum nitride), InN (indium nitride), GaN, and GaAs (gallium arsenide).

The substrate 83 is a flat plate having the Z direction as the thickness direction. The substrate 83 includes a substrate upper surface 83S and a substrate lower surface 83R, which face in opposite directions in the Z direction. In one example, the substrate lower surface 83R constitutes the chip back surface 80R of the insulating chip 80. In plan view, the substrate 83 has a rectangular shape. In one example, the substrate 83 has a rectangular shape in which the X direction is the long side and the Y direction is the short side in plan view.

As shown in FIGS. 8 and 9, the insulator 84 is provided on the substrate upper surface 83S of the substrate 83. The insulator 84 includes an insulating upper surface 84S and an insulating lower surface 84R that is opposite to the insulating upper surface 84S. In one example, the insulating lower surface 84R is in contact with the substrate upper surface 83S.

The insulator 84 includes a plurality of insulating layers 85 disposed from the substrate upper surface 83S of the substrate 83 in the Z direction. The plurality of insulating layers 85 are laminated on the substrate upper surface 83S of the substrate 83. The insulator 84 can be said to include the plurality of insulating layers 85 laminated in the Z direction from the substrate upper surface 83S. The Z direction can be said to be the thickness direction of the insulator 84. The Z direction can also be said to be the laminating direction of the insulating layers 85.

The plurality of insulating layers 85 include a plurality of thick insulating layers 85A and a plurality of thin insulating layers 85B. The insulator 84 is configured as an insulating laminate in which one thick insulating layer 85A and one thin insulating layer 85B are alternately laminated. The lowermost insulating layer 85L among the plurality of insulating layers 85 is formed of the thick insulating layer 85A. The uppermost insulating layer 85U is formed of the thin insulating layer 85B and the thick insulating layer 85A laminated on the thin insulating layer 85B.

The thick insulating layer 85A is, for example, an interlayer insulating film. The thick insulating layer 85A is made of a material having a smaller linear expansion coefficient than each of a first conductor 51 and a second conductor 52 described later. In other words, the thick insulating layer 85A is made of a material having a smaller linear expansion coefficient than the linear expansion coefficients of the first conductor 51 and the second conductor 52. The thick insulating layer 85A is made of a material containing SiO (silicon oxide). In one example, the thick insulating layer 85A is made of a material containing SiO₂. In one example, the thick insulating layer 85A is a SiO₂ film.

The thin insulating layer 85B is a thin film and is, for example, an etching stopper layer. The thin insulating layer 85B is made of a material having a greater thermal expansion coefficient than the thick insulating layer 85A and a smaller thermal expansion coefficient than each of the first conductor 51 and the second conductor 52. In other words, the thin insulating layer 85B is made of a material having a linear expansion coefficient greater than that of the thick insulating layer 85A and smaller than the linear expansion coefficients of each of the first conductor 51 and the second conductor 52. The thin insulating layer 85B is made of a material including SiN (silicon nitride), SiC, SiCN (silicon carbon nitride), or the like. The thin insulating layer 85B is made of a material including SiN. In one example, the thin insulating layer 85B is a SiN film.

The thickness of the thick insulating layer 85A may be 1000 nm or more and 3000 nm or less. In one example, the thickness of the thick insulating layer 85A is approximately 2300 nm. The thickness of the thin insulating layer 85B may be 100 nm or more and less than 1000 nm. In one example, the thickness of the thin insulating layer 85B is approximately 300 nm.

The lower surface of the lowermost insulating layer 85L constitutes the insulating lower surface 84R of the insulator 84. The upper surface of the uppermost insulating layer 85U constitutes the insulating upper surface 84S. In one example, the thicknesses of both the lowermost insulating layer 85L and the uppermost insulating layer 85U may be equal to or greater than the thickness of the thin insulating layer 85B and equal to or less than the thickness of the thick insulating layer 85A. The thicknesses of both the lowermost insulating layer 85L and the uppermost insulating layer 85U can be arbitrarily changed. In one example, the thicknesses of both the lowermost insulating layer 85L and the uppermost insulating layer 85U may be greater than the thickness of the thick insulating layer 85A and may be greater than the total thickness of the insulating layer 85 composed of the thick insulating layer 85A and the thin insulating layer 85B.

As shown in FIGS. 6 to 9, the insulating chip 80 includes a first conductor 51 and a second conductor 52 that form the transformers 40A and 40B. In the first embodiment, both the first conductor 51 and the second conductor 52 are coils. The first conductor 51 and the second conductor 52 are embedded in the insulator 84. The first conductor 51 and the second conductor 52 are provided in different insulating layers 85 within the insulator 84. The first conductor 51 and the second conductor 52 face each other in the Z direction.

In the first embodiment, the plurality of insulating layers 85 include insulating layers 851 to 857 provided between the lowermost insulating layer 85L and the uppermost insulating layer 85U. Each of the insulating layers 851 to 857 is composed of a thin insulating layer 85B and a thick insulating layer 85A laminated on the thin insulating layer 85B. The insulating layer 851 is in contact with the lowermost insulating layer 85L. The insulating layer 857 is in contact with the uppermost insulating layer 85U.

As shown in FIGS. 8 and 9, the first conductor 51 of the transformers 40A and 40B is configured as a conductive layer embedded in one of the insulating layers 85 included in the insulator 84. The first conductor 51 is embedded in the insulating layer 853, which is closer to the insulating lower surface 84R among the plurality of insulating layers 85 forming the insulator 84. The insulating layer 853 includes a first groove 86A that penetrates both the thick insulating layer 85A and the thin insulating layer 85B in the Z direction. The first conductor 51 is embedded in the first groove 86A of the insulating layer 853. The first conductor 51 and the insulating layer 853 are covered by the insulating layer 854.

As shown in FIGS. 6, 8, and 9, the first conductor 51 includes a first coil 41, a first inner end wiring 51A, and a first outer end wiring 51B. Each of the first coil 41, the first inner end wiring 51A, and the first outer end wiring 51B is made of a material including one or more selected as appropriate from among Ti (titanium), TiN (titanium nitride), Au, Ag, Cu, Al, and W (tungsten). In one example, the first coil 41, the first inner end wiring 51A, and the first outer end wiring 51B may be made of the same material. In another example, the first coil 41, the first inner end wiring 51A, and the first outer end wiring 51B may be made of different materials.

As shown in FIG. 6, the first coil 41 has a spiral shape in plan view. In one example, the first coil 41 has an elliptical shape in plan view. The first coil 41 of the transformers 40A and 40B includes a first end and a second end opposite to the first end. The first end is the inner end of the first coil 41, and the second end is the outer end of the first coil 41. The first ends of the first coil 41 of the transformers 40A and 40B are individually and electrically connected to the first inner end wiring 51A. The second ends of the first coil 41 of the transformers 40A and 40B are electrically connected to the first outer end wiring 51B.

The first inner end wiring 51A is disposed inside each of the first coils 41 of the transformers 40A and 40B. In the first embodiment, two first inner end wirings 51A are provided corresponding to the two first coils 41. The first outer end wiring 51B is disposed outside the first coils 41. The first outer end wiring 51B is disposed between the first coil 41 of the transformer 40A and the first coil 41 of the transformer 40B. The first outer end wiring 51B is configured as a common end wiring for the first coils 41 of the transformers 40A and 40B. The configuration may also be such that a separate first outer end wiring 51B is provided for each of the first coils 41 of the transformers 40A and 40B.

As shown in FIGS. 8 and 9, the second conductor 52 is configured as a conductive layer embedded in one of the insulating layers 85 included in the insulator 84. The second conductor 52 is embedded in the insulating layer 857 near the insulating upper surface 84S among the insulating layers 851 to 857 forming the insulator 84. Therefore, the second conductor 52 is disposed closer to the insulating upper surface 84S than the first conductor 51 within the insulator 84. The insulating layer 857 includes a second groove 86B that penetrates both the thick insulating layer 85A and the thin insulating layer 85B in the Z direction. The second conductor 52 is embedded in the second groove 86B of the insulating layer 857. The second conductor 52 and the insulating layer 857 are covered by the insulating layer 85U.

As shown in FIGS. 7 to 9, the second conductor 52 includes a second coil 42, a second inner end wiring 52A, and a second outer end wiring 52B. Each of the second coil 42, the second inner end wiring 52A, and the second outer end wiring 52B is made of a material including one or more selected as appropriate from among Ti, TiN, Au, Ag, Cu, Al, and W. In one example, the second coil 42, the second inner end wiring 52A, and the second outer end wiring 52B may be made of the same material. In another example, the second coil 42, the second inner end wiring 52A, and the second outer end wiring 52B may be made of different materials. In one example, the first coil 41 and the second coil 42 may be made of the same material. In another example, the first coil 41 and the second coil 42 may be made of different materials.

As shown in FIG. 7, the second coil 42 has a spiral shape in plan view. In one example, the second coil 42 has an elliptical shape in plan view. In one example, the size and number of turns of the second coil 42 are the same as those of the first coil 41. The second coil 42 of the transformers 40A and 40B includes a first end and a second end opposite to the first end. The first end is the inner end of the second coil 42, and the second end is the outer end of the second coil 42. The first ends of the second coil 42 of the transformers 40A and 40B are individually and electrically connected to the second inner end wiring 52A. The second ends of the second coil 42 of the transformers 40A and 40B are electrically connected to the second outer end wiring 52B.

The second inner end wiring 52A is disposed inside each of the second coils 42 of the transformers 40A and 40B. In the first embodiment, two second inner end wirings 52A are provided corresponding to the two second coils 42. The second outer end wiring 52B is disposed outside the second coils 42. The second outer end wiring 52B is disposed between the second coil 42 of transformer 40A and the second coil 42 of transformer 40B. The second outer end wiring 52B is configured as a common end wiring for the second coils 42 of the transformers 40A and 40B. The configuration may also be such that a separate second outer end wiring 52B is provided for each of the second coils 42 of the transformers 40A and 40B.

As shown in FIG. 8, a plurality of insulating layers 85 are interposed between the first conductor 51 and the second conductor 52. In the insulating chip 80 of the first embodiment, three insulating layers 854 to 856 are interposed between the first conductor 51 and the second conductor 52. Therefore, the insulating chip 80 of the first embodiment includes a first insulator 841 including the insulating layer 853 in which the first conductor 51 is embedded, a second insulator 842 including the insulating layer 857 in which the second conductor 52 is embedded, and a third insulator 843 including the insulating layers 854 to 856 disposed in the Z direction between the first insulator 841 and the second insulator 842. The first conductor 51 embedded in the first insulator 841 is covered by the third insulator 843. The second conductor 52 is provided on the third insulator 843 covering the first conductor 51. In the first embodiment, the first insulator 841 includes the lowermost insulating layer 85L and insulating layers 851 to 853. The second insulator 842 includes the insulating layer 857 and the uppermost insulating layer 85U.

As shown in FIGS. 8 and 9, the first electrode pad 81 is provided on the insulating upper surface 84S of the insulator 84. As shown in FIG. 5, the first electrode pad 81 is disposed closer to the chip side surface 802 on the insulating upper surface 84S. The first electrode pad 81 is made of a material including one or more selected as appropriate from among Cu, Al, Ni (nickel), Pd (palladium), and W.

As shown in FIGS. 5, 8, and 9, the first electrode pad 81 includes a first pad 81A and a second pad 81B. The first electrode pad 81 includes two first pads 81A electrically connected to the first coil 41 of transformer 40A and two first pads 81A electrically connected to the first coil 41 of transformer 40B. The first electrode pad 81 includes two second pads 81B common to the first coils 41 of the transformers 40A and 40B. The two first pads 81A are arranged side by side in the X direction. The two second pads 81B are arranged side by side in the X direction.

As shown in FIGS. 8 and 9, the first electrode pad 81 is electrically connected to the first conductor 51. More specifically, the insulating chip 80 includes a connection wiring 60 that connects the first conductor 51 and the first electrode pad 81. The connection wiring 60 is provided within the insulator 84. The connection wiring 60 includes a first connection wiring 60A shown in FIG. 8 and a second connection wiring 60B shown in FIG. 9.

As shown in FIG. 8, the first pad 81A is electrically connected to the first inner end wiring 51A of the first conductor 51 by the first connection wiring 60A. As shown in FIG. 9, the second pad 81B is electrically connected to the first outer end wiring 51B of the first conductor 51 by the second connection wiring 60B. The detailed explanation of the first connection wiring 60A and the second connection wiring 60B will be given later.

As shown in FIGS. 5, 8, and 9, a second electrode pad 82 is provided on the insulating upper surface 84S of the insulator 84. The second electrode pad 82 is made of a material including one or more appropriately selected from Cu, Al, Ni, Pd, and W. In one example, the second electrode pad 82 is made of the same material as the first electrode pad 81.

As shown in FIGS. 5 and 8, the second electrode pad 82 includes a third pad 82A and a fourth pad 82B. The second electrode pad 82 includes two third pads 82A electrically connected to the second coil 42 of transformer 40A and two third pads 82A electrically connected to the second coil 42 of transformer 40B. The second electrode pad 82 includes two fourth pads 82B that are common to the second coils 42 of the transformers 40A and 40B. The two third pads 82A are arranged side by side in the X direction. The two fourth pads 82B are arranged side by side in the X direction. The two third pads 82A are disposed inside the second coil 42 of the second conductor 52 in plan view. As shown in FIG. 8, the third pads 82A are disposed so as to overlap with the second inner end wiring 52A of the second conductor 52 in plan view. As shown in FIG. 5, the two fourth pads 82B are disposed outside the second coils 42 of the transformers 40A and 40B in plan view. The two fourth pads 82B are disposed between the second coil 42 of transformer 40A and the second coil 42 of transformer 40B. As shown in FIG. 9, the two fourth pads 82B are disposed so as to overlap with the second outer end wiring 52B of the second conductor 52 in plan view.

As shown in FIGS. 8 and 9, the second electrode pad 82 is electrically connected to the second conductor 52. More specifically, the third pad 82A of the second electrode pad 82 is electrically connected to the second inner end wiring 52A of the second conductor 52 by a via wiring 56A that penetrates the uppermost insulating layer 85U. As shown in FIG. 9, the fourth pad 82B of the second electrode pad 82 is electrically connected to the second outer end wiring 52B of the second conductor 52 by a via wiring 56B that penetrates the uppermost insulating layer 85U. The via wirings 56A and 56B are made of a material including one or more appropriately selected from Ti, TiN, Au, Ag, Cu, Al, and W.

The insulating chip 80 may include a passivation film 91. The passivation film 91 is a surface protection film for the insulating chip 80. The passivation film 91 is made of a material including, for example, SiO₂ or SiN.

The first electrode pad 81 and the second electrode pad 82 are covered by the passivation film 91. The passivation film 91 has openings that expose part of each of the first electrode pad 81 and the second electrode pad 82. As a result, the first electrode pad 81 has an exposed surface for connection with the wire W2 shown in FIG. 2. The second electrode pad 82 has an exposed surface for connection with the wire W3 shown in FIG. 2.

The insulating chip 80 may include a resin layer 92 provided on the passivation film 91. The resin layer 92 may be made of a material including PI (polyimide), for example. The resin layer 92 is separated into an inner resin layer 921 and an outer resin layer 922 by a separation groove 923. As shown in FIG. 4, the separation groove 923 is provided so as to surround the transformers 40A and 40B. The resin layer 92 includes a first resin opening 924 that exposes the first electrode pad 81 and a second resin opening 925 that exposes the second electrode pad 82. The first resin opening 924 and the second resin opening 925 are in communication with the openings in the passivation film 91.

As shown in FIGS. 5 and 7 to 9, the insulating chip 80 includes a dummy pattern 55 provided around the second coil 42 of the transformers 40A and 40B. The dummy pattern 55 may be omitted. As shown in FIGS. 8 and 9, the dummy pattern 55 is embedded in the insulating layer 857 of the insulator 84, similarly to the second conductor 52.

As shown in FIGS. 5 and 7, the dummy pattern 55 includes a first dummy pattern 551, a second dummy pattern 552, and a third dummy pattern 553. Each of the first dummy pattern 551, the second dummy pattern 552, and the third dummy pattern 553 is made of a material including one or more appropriately selected from Ti, TiN, Au, Ag, Cu, Al, and W.

As shown in FIGS. 5 and 7, the first dummy pattern 551 is provided in the region between the second coil 42 of transformer 40A and the second coil 42 of transformer 40B in the X direction in plan view. The first dummy pattern 551 is formed in a pattern different from that of the second coil 42. The first dummy pattern 551 is electrically connected to the second outer end wiring 52B. The first dummy pattern 551 may be electrically connected to at least one of the two second outer end wirings 52B. In this manner, the first dummy pattern 551 has the same potential as the second coil 42. Therefore, when the voltage of the second reference potential of the second coil 42 changes, the voltage of the first dummy pattern 551 may become higher than that of the first coil 41, similarly to the second coil 42.

Although not shown in the drawings, the first dummy pattern 551 is disposed at the same position as the second coil 42 in the Z direction. In other words, the first dummy pattern 551 is disposed farther from the substrate 83 than the first coil 41. That is, the dummy pattern 55 is provided around the coil of the transformers 40A and 40B that is closer to the chip upper surface 80S of the insulating chip 80.

By setting the voltage of the first dummy pattern 551 to be the same as that of the second coil 42, voltage drop between the second coil 42 and the first dummy pattern 551 can be suppressed. Therefore, electric field concentration on the second coil 42 can be suppressed.

As shown in FIG. 7, the third dummy pattern 553 surrounds the second coil 42 of the transformers 40A and 40B in plan view. The third dummy pattern 553 is electrically connected to the first dummy pattern 551. Therefore, similarly to the first dummy pattern 551, the voltage of the third dummy pattern 553 may become higher than that of the first coil 41 due to displacement of the second reference potential of the second coil 42.

As shown in FIGS. 8 and 9, the third dummy pattern 553 is disposed at the same position as the second coil 42 in the Z direction. In other words, the third dummy pattern 553 is disposed farther from the substrate 83 than the first coil 41. Thus, the dummy patterns 551 to 553 are disposed at the same position in the Z direction.

By setting the voltage of the third dummy pattern 553 to be the same as that of the second coil 42, voltage drop between the second coil 42 and the third dummy pattern 553 can be suppressed. Therefore, electric field concentration on the second coil 42 can be suppressed.

As shown in FIG. 7, the second dummy pattern 552 surrounds the third dummy pattern 553 in plan view. The second dummy pattern 552 is independent of the second coil 42. In other words, the second dummy pattern 552 is not electrically connected to the second coil 42.

As shown in FIGS. 8 and 9, the second dummy pattern 552 is disposed at the same position as the second coil 42 in the Z direction. The second dummy pattern 552 is also disposed farther from the substrate 83 than the first coil 41. The second dummy pattern 552 suppresses an increase in electric field intensity around the second coil 42 and can suppress electric field concentration on the second electrode pad 82 (third pad 82A and fourth pad 82B).

As shown in FIGS. 6 to 9, the insulating chip 80 includes a seal portion 93. The seal portion 93 is provided on the outer periphery of the insulator 84 in plan view. The seal portion 93 has a rectangular frame shape in plan view. The seal portion 93 surrounds the plurality of first electrode pads 81 and the plurality of second electrode pads 82, the transformers 40A and 40B, and the first connection wiring 60A and the second connection wiring 60B in plan view.

As shown in FIGS. 8 and 9, the seal portion 93 extends in the Z direction within the insulator 84 so as to surround the transformers 40A and 40B and the first connection wiring 60A and the second connection wiring 60B. The seal portion 93 functions to suppress the ingress of moisture or other foreign substances from outside the insulating chip 80. The seal portion 93 is made of a material including one or more appropriately selected from Ti, TiN, Au, Ag, Cu, Al, and W.

### [Configuration of Connection Wiring]

As shown in FIG. 8, the first connection wiring 60A includes a first wiring section 61A extending in the Z direction so as to penetrate a plurality of insulating layers 85 and a second wiring section 66A extending in the Y direction.

The first wiring section 61A is disposed at a position overlapping with the first pad 81A in plan view. The first wiring section 61A is connected to the first pad 81A. The first wiring section 61A penetrates from the uppermost insulating layer 85U to the insulating layer 853 near the lowermost insulating layer 85L among the plurality of insulating layers 85.

The first wiring section 61A includes a first-layer wiring 62A, a second-layer wiring 63A, a through-wiring 64A, and a surface-side via wiring 65A. Each of the first-layer wiring 62A, the second-layer wiring 63A, the through-wiring 64A, and the surface-side via wiring 65A is made of a material including one or more appropriately selected from Ti, TiN, Au, Ag, Cu, Al, and W. In one example, the first-layer wiring 62A, the second-layer wiring 63A, and the through-wiring 64A may be made of the same material. In another example, the first-layer wiring 62A, the second-layer wiring 63A, the through-wiring 64A, and the surface-side via wiring 65A may be made of different materials. In one example, the first-layer wiring 62A may be made of the same material as the first conductor 51. In one example, the second-layer wiring 63A may be made of the same material as the second conductor 52. In one example, the surface-side via wiring 65A may be made of the same material as the via wirings 56A and 56B.

The first-layer wiring 62A is disposed near the insulating lower surface 84R within the insulator 84. In one example, the first-layer wiring 62A is disposed at the same position in the Z direction as the first conductor 51. The first-layer wiring 62A is embedded in the insulating layer 853. More specifically, the first-layer wiring 62A is embedded in a through-hole 87A penetrating the insulating layer 853 in the Z direction. The first-layer wiring 62A is covered by the insulating layer 854.

The second-layer wiring 63A is disposed near the insulating upper surface 84S within the insulator 84. In one example, the second-layer wiring 63A is disposed at the same position in the Z direction as the second conductor 52. The second-layer wiring 63A faces the first-layer wiring 62A in the Z direction. The second-layer wiring 63A is embedded in the insulating layer 857. More specifically, the second-layer wiring 63A is embedded in a through-hole 87B penetrating the insulating layer 857 in the Z direction. The second-layer wiring 63A is covered by the uppermost insulating layer 85U.

The through-wiring 64A connects the first-layer wiring 62A and the second-layer wiring 63A. In one example, the through-wiring 64A penetrates the three insulating layers 854 to 856 interposed between the first-layer wiring 62A and the second-layer wiring 63A. Multiple through-wirings 64A are provided with spacing in the X and Y directions. The through-wiring 64A is formed by vias 70. In one example, the via 70 penetrates the three insulating layers 854 to 856. The via 70 is tapered, narrowing from the second-layer wiring 63A toward the first-layer wiring 62A. The configuration of the through-wiring 64A can be arbitrarily changed. In one example, the through-wiring 64A may be formed by a stacked structure of multiple vias 70.

The surface-side via wiring 65A connects the second-layer wiring 63A and the first electrode pad 81. More specifically, the first pad 81A of the first electrode pad 81 is electrically connected to the second-layer wiring 63A by the surface-side via wiring 65A penetrating the uppermost insulating layer 85U. In one example, multiple surface-side via wirings 65A are provided with spacing in the X and Y directions.

The second wiring section 66A is electrically connected to the first conductor 51. The second wiring section 66A extends outward of the first conductor 51 in plan view. In one example, the second wiring section 66A extends from the first conductor 51 toward the chip side surface 802 of the insulating chip 80 in plan view.

The second wiring section 66A includes an extraction wiring 67A, a first back-side via wiring 68A, and a second back-side via wiring 69A. Each of the extraction wiring 67A, the first back-side via wiring 68A, and the second back-side via wiring 69A is made of a material including one or more appropriately selected from Ti, TiN, Au, Ag, Cu, Al, and W. In one example, the extraction wiring 67A, the first back-side via wiring 68A, and the second back-side via wiring 69A are made of the same material. In another example, the extraction wiring 67A, the first back-side via wiring 68A, and the second back-side via wiring 69A are made of different materials. In one example, the extraction wiring 67A may be made of the same material as the first conductor 51. In one example, the extraction wiring 67A may be made of the same material as the second conductor 52.

The extraction wiring 67A is provided closer to the substrate 83 than the first wiring section 61A in the Z direction. The extraction wiring 67A is provided closer to the substrate 83 than the first conductor 51 in the Z direction. In one example, the extraction wiring 67A is provided in the insulating layer 851, which is one layer above the lowermost insulating layer 85L among the plurality of insulating layers 85. Of the two end portions of the extraction wiring 67A in the X direction, the first end portion closer to the chip side surface 802 of the insulating chip 80 is provided at a position overlapping with the first wiring section 61A in plan view. The first end portion of the extraction wiring 67A is connected to the first-layer wiring 62A by multiple first back-side via wirings 68A. The second end portion of the extraction wiring 67A, which is opposite to the first end portion, is provided at a position overlapping with the first inner end wiring 51A of the first conductor 51 in plan view. The second end portion of the extraction wiring 67A is connected to the first inner end wiring 51A by multiple second back-side via wirings 69A.

As shown in FIG. 9, the second connection wiring 60B includes a first wiring section 61B and a second wiring section 66B, similarly to the first connection wiring 60A shown in FIG. 8. The first wiring section 61B includes a first-layer wiring 62B, a second-layer wiring 63B, a through-wiring 64B, and a surface-side via wiring 65B, similarly to the first wiring section 61A of the first connection wiring 60A. Each of the first-layer wiring 62B, the second-layer wiring 63B, the through-wiring 64B, and the surface-side via wiring 65B is made of a material including one or more appropriately selected from Ti, TiN, Au, Ag, Cu, Al, and W. In one example, the first-layer wiring 62B, the second-layer wiring 63B, the through-wiring 64B, and the surface-side via wiring 65B are made of the same material as the first-layer wiring 62A, the second-layer wiring 63A, the through-wiring 64A, and the surface-side via wiring 65A shown in FIG. 8.

The first-layer wiring 62B is provided at the same position in the Z direction as the first-layer wiring 62A. The second-layer wiring 63B is provided at the same position in the Z direction as the second-layer wiring 63A. The configurations of the first-layer wiring 62B, second-layer wiring 63B, through-wiring 64B, and surface-side via wiring 65B are the same as those of the first-layer wiring 62A, second-layer wiring 63A, through-wiring 64A, and surface-side via wiring 65A.

The second wiring section 66B connects the first outer end wiring 51B of the first conductor 51 and the first-layer wiring 62B. The second wiring section 66B extends outward of the first conductor 51 in plan view. The second wiring section 66B includes an extraction wiring 67B, a first back-side via wiring 68B, and a second back-side via wiring 69B, similar to the second wiring section 66A shown in FIG. 8. Each of the extraction wiring 67B, first back-side via wiring 68B, and second back-side via wiring 69B is made of a material including one or more appropriately selected from Ti, TiN, Au, Ag, Cu, Al, and W. In one example, the extraction wiring 67B, first back-side via wiring 68B, and second back-side via wiring 69B are made of the same material as the extraction wiring 67A, first back-side via wiring 68A, and second back-side via wiring 69A shown in FIG. 8.

The extraction wiring 67B is provided at the same position in the Z direction as the extraction wiring 67A. The first end of the extraction wiring 67B is provided at a position overlapping the second pad 81B of the first electrode pad 81 in plan view. The first end of the extraction wiring 67B is connected to the first-layer wiring 62B by the first back-side via wiring 68B. The second end of the extraction wiring 67B is provided at a position overlapping the first outer end wiring 51B of the first conductor 51 in plan view. The second end of the extraction wiring 67B is connected to the first outer end wiring 51B by the second back-side via wiring 69B. The configurations of the first back-side via wiring 68B and second back-side via wiring 69B are the same as those of the first back-side via wiring 68A and second back-side via wiring 69A.

The second wiring section 66B includes a third back-side via wiring 69C that connects the extraction wiring 67B and the substrate 83. As a result, the second connection wiring 60B is electrically connected to the substrate 83. The third back-side via wiring 69C penetrates the lowermost insulating layer 85L. The third back-side via wiring 69C is made of a material including one or more appropriately selected from Ti, TiN, Au, Ag, Cu, Al, and W.

### [Structure of First Conductor and Second Conductor]

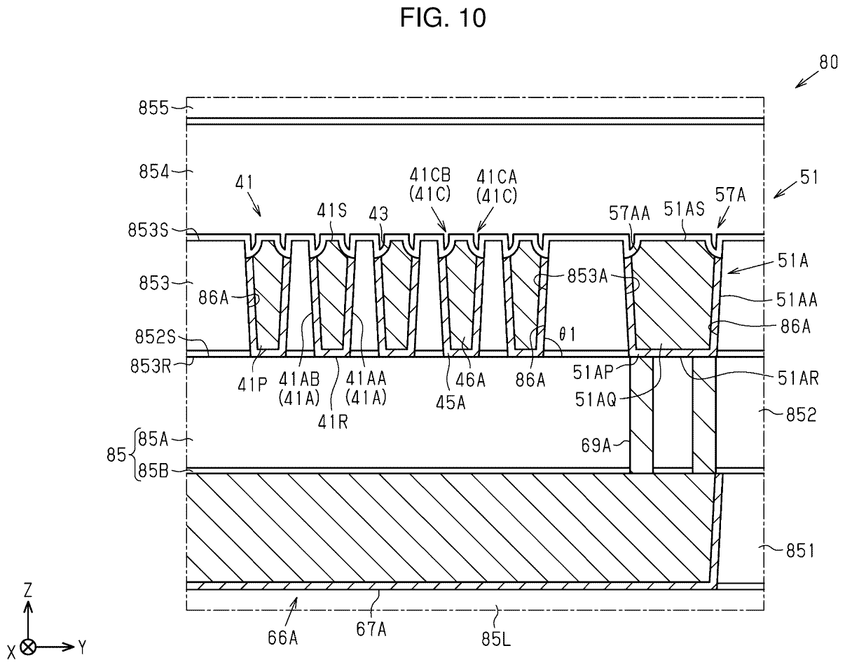

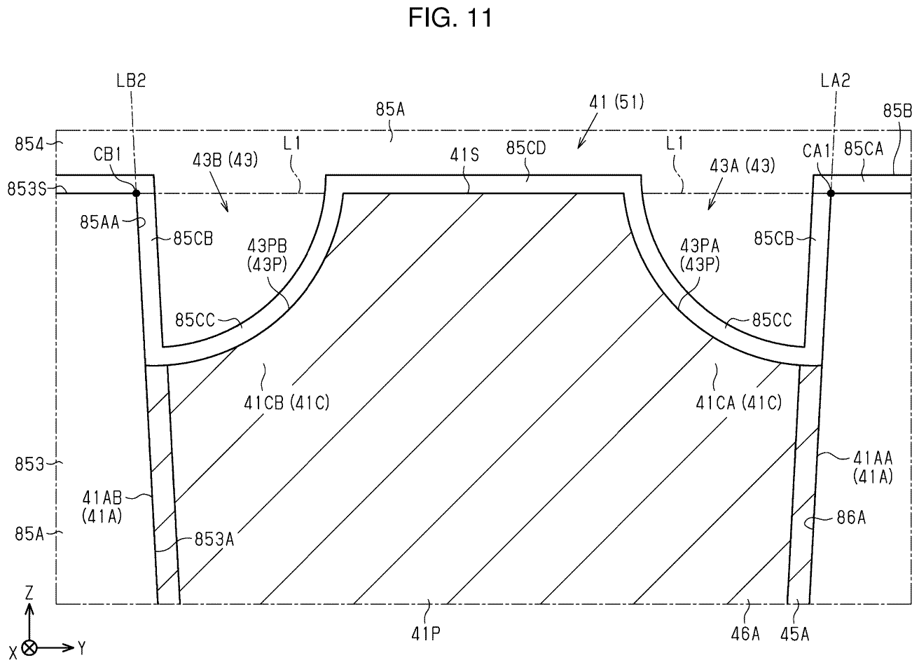

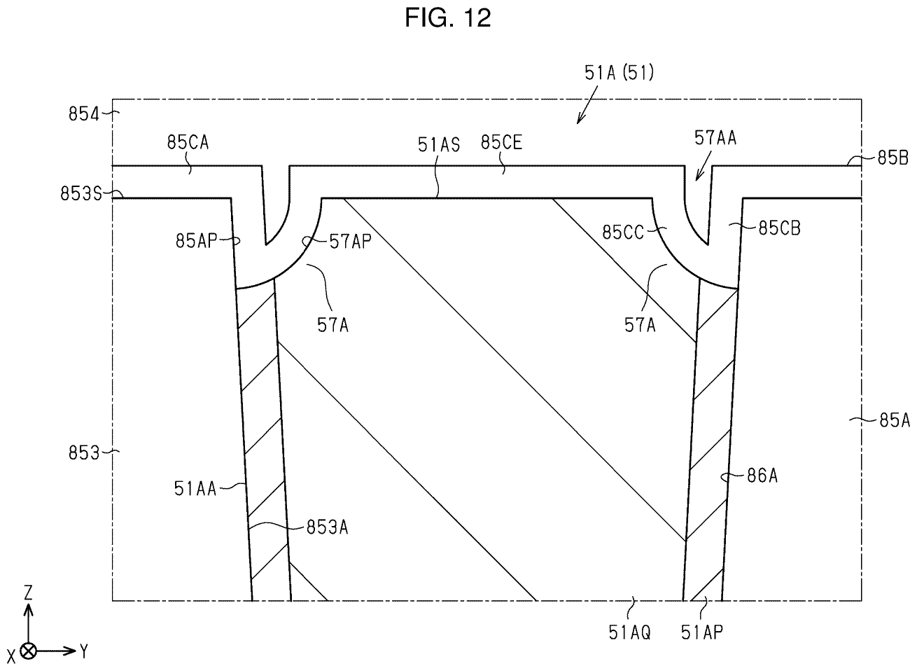

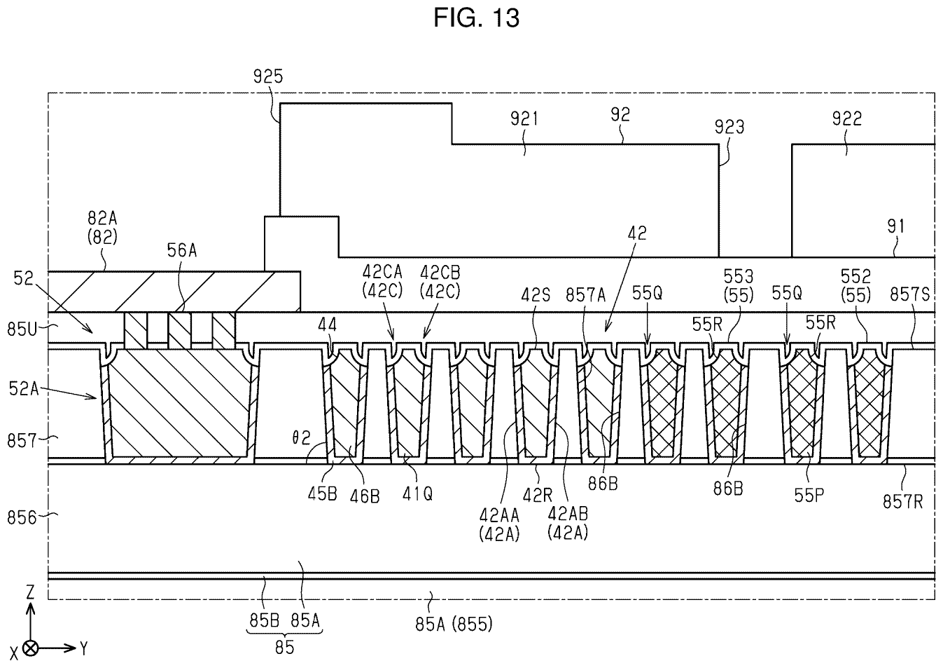

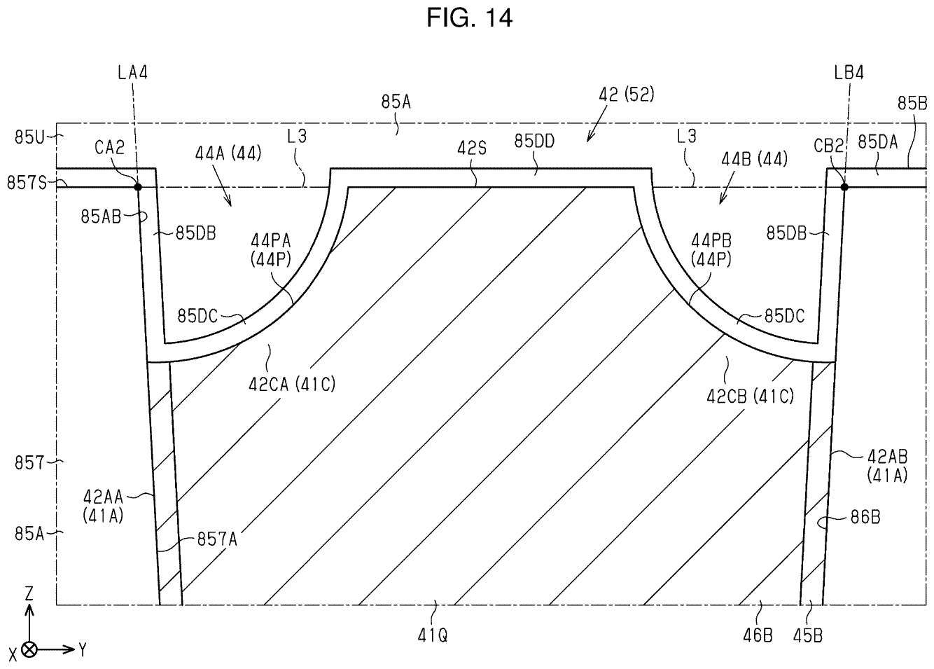

With reference to FIGS. 10 to 14, the detailed structure of the first conductor 51 and the second conductor 52 will be described. FIG. 10 shows an enlarged cross-sectional structure of a portion of the first conductor 51 in FIG. 8. FIG. 11 shows a further enlarged cross-sectional structure of a portion of the first coil 41 of the first conductor 51 in FIG. 10. FIG. 12 shows an enlarged cross-sectional structure of a portion of the first inner end wiring 51A of the first conductor 51 in FIG. 10. FIG. 13 shows an enlarged cross-sectional structure of a portion of the second conductor 52 in FIG. 8. FIG. 14 shows a further enlarged cross-sectional structure of a portion of the second conductor 52 in FIG. 13.

### (First Conductor)

As shown in FIG. 10, the first coil 41 of the first conductor 51 is provided in the insulating layer 853 among the insulating layers 851 to 857 of the insulating body 84, as described above. The first coil 41 penetrates the insulating layer 853 in the Z direction. The first coil 41 is sandwiched between the insulating layers 852 and 854. Here, the insulating layer 853 corresponds to the “first insulating layer,” and the insulating layer 854 corresponds to the “second insulating layer.”

Since the first groove 86A formed in the insulating layer 853 penetrates the insulating layer 853 in the Z direction, the thick insulating layer 85A of the insulating layer 852 is exposed. Therefore, the first conductor 51 embedded in the first groove 86A is in contact with the thick insulating layer 85A of the insulating layer 852. In one example, the first groove 86A tapers from the upper surface 853S toward the lower surface 853R of the insulating layer 853. The angle θ1 of the side surface 853A of the insulating layer 853 is between 80° and 90°. In one example, the angle θ1 is 85°. Here, the side surface 853A of the insulating layer 853 is the surface forming the first groove 86A. The angle θ1 can be defined as the angle between the lower surface 853R and the side surface 853A of the insulating layer 853.

The first coil 41 of the first conductor 51 is composed of a coil wiring 41P having a predetermined width. The first coil 41 includes a first upper surface 41S, a first lower surface 41R, and a first side surface 41A. The first upper surface 41S is positioned near the insulating upper surface 84S of the insulating body 84. The first lower surface 41R constitutes the surface opposite to the first upper surface 41S. The first lower surface 41R is positioned near the insulating lower surface 84R of the insulating body 84. The first side surface 41A is provided between the first upper surface 41S and the first lower surface 41R in the Z direction.

In the first embodiment, the first upper surface 41S is positioned at the same level in the Z direction as the upper surface 853S of the insulating layer 853. Here, the upper surface 853S of the insulating layer 853 is formed by the upper surface of the thick insulating layer 85A. The position of the first upper surface 41S in the Z direction can be arbitrarily changed. In one example, the first upper surface 41S may be positioned closer to the lower surface 853R of the insulating layer 853 than the upper surface 853S in the Z direction.

The first side surface 41A includes a first inner side surface 41AA and a first outer side surface 41AB. The first inner side surface 41AA is provided on the inner side in the width direction of the first conductor 51. That is, the first inner side surface 41AA constitutes the inner side in the width direction of the coil wiring 41P forming the first coil 41. The first outer side surface 41AB is provided on the outer side in the width direction of the first conductor 51. That is, the first outer side surface 41AB constitutes the outer side in the width direction of the coil wiring 41P forming the first coil 41.

In one example, the first conductor 51 is tapered such that the first side surface 41A inclines toward the first lower surface 41R from the first upper surface 41S. That is, the coil wiring 41P forming the first coil 41 is tapered such that the first side surface 41A inclines toward the first lower surface 41R from the first upper surface 41S. Therefore, the first inner side surface 41AA and the first outer side surface 41AB are inclined toward each other from the first upper surface 41S to the first lower surface 41R.

The first coil 41 includes a seed layer 45A and a plating layer 46A formed on the seed layer 45A. The seed layer 45A is formed on the side surface (the side surface 853A of the insulating layer 853) forming the first groove 86A and the upper surface 852S of the insulating layer 852 exposed by the first groove 86A. Therefore, both the first lower surface 41R and the first side surface 41A are formed by the seed layer 45A. The first upper surface 41S is formed by the plating layer 46A. The seed layer 45A is a sputtered film formed by sputtering, for example. The seed layer 45A may have a laminated structure of a Ti film and a Cu film, for example. The plating layer 46A is made of a material including Cu, for example.

The first coil 41 includes a first corner portion 41C between the first side surface 41A and the first upper surface 41S. The first corner portion 41C includes a first inner corner portion 41CA and a first outer corner portion 41CB. The first inner corner portion 41CA is a portion between the first inner side surface 41AA and the first upper surface 41S. The first outer corner portion 41CB is a portion between the first outer side surface 41AB and the first upper surface 41S.

As shown in FIG. 11, the first corner portion 41C includes a first recess 43. The first recess 43 includes a first curved surface 43P. The first recess 43 is recessed so as to be convex inward of the first coil 41. In the cross-sectional view shown in FIG. 11, the first curved surface 43P has an arcuate shape. The first recess 43 is formed in an arc centered at the intersection of a first virtual line L1 along the first upper surface 41S and a second virtual line LA2 (or LB2) along the first side surface 41A. The first recess 43 spans both the seed layer 45A and the plating layer 46A.

The first recess 43 extends over the entire length direction of the coil wiring 41P. Specifically, as shown in FIG. 6, the first coil 41 includes a pair of first straight portions 41D and a pair of first curved portions 41E that connect the ends of the pair of first straight portions 41D. The first recess 43 shown in FIG. 11 is continuously formed in both the pair of first straight portions 41D and the pair of first curved portions 41E.

As shown in FIG. 11, the first recess 43 includes a first inner recess 43A including a first inner curved surface 43PA, and a first outer recess 43B including a first outer curved surface 43PB. The first inner recess 43A is formed in the first inner corner portion 41CA. The first outer recess 43B is formed in the first outer corner portion 41CB.

In the cross-sectional view shown in FIG. 11, the first inner curved surface 43PA has an arcuate shape. That is, the cross-sectional shape of the first inner curved surface 43PA is an arc centered on a first inner curvature center CA1. The first inner curvature center CA1 is located outside the coil wiring 41P. In one example, the first inner curvature center CA1 is the intersection of the first virtual line L1 along the first upper surface 41S and the second virtual line LA2 along the first inner side surface 41AA.

In the cross-sectional view shown in FIG. 11, the first outer curved surface 43PB has an arcuate shape. That is, the cross-sectional shape of the first outer curved surface 43PB is an arc centered on a first outer curvature center CB1. The first outer curvature center CB1 of the first outer curved surface 43PB is located outside the coil wiring 41P. In one example, the first outer curvature center CB1 is the intersection of the first virtual line L1 along the first upper surface 41S and the second virtual line LB2 along the first outer side surface 41AB.

In one example, the arc length of the cross-sectional shape of the first inner curved surface 43PA is equal to the arc length of the cross-sectional shape of the first outer curved surface 43PB. The radius of curvature of the first inner curved surface 43PA may be equal to the radius of curvature of the first outer curved surface 43PB. Each of the radii of curvature of the first inner curved surface 43PA and the first outer curved surface 43PB is larger than the film thickness of the thin insulating layer 85B and smaller than the film thickness of the thick insulating layer 85A. In one example, the radii of curvature of the first inner curved surface 43PA and the first outer curved surface 43PB are each 1 μm.

The thick insulating layer 85A of the insulating layer 853 includes a first exposed side surface 85AA, which is exposed from the first side surface 41A of the first coil 41 by the first recess 43. The first exposed side surface 85AA is a portion of the side surface 853A of the insulating layer 853 located between the upper edge of the first side surface 41A and the upper surface 853S of the insulating layer 853. The first exposed side surface 85AA faces the first curved surface 43P of the first recess 43 in a direction orthogonal to the Z direction. In one example, the length of the first exposed side surface 85AA is equal to the radius of curvature of the first curved surface 43P (e.g., the radius of curvature of the first inner curved surface 43PA). Here, the length of the first exposed side surface 85AA can be defined by the distance between the upper edge of the first side surface 41A and the upper surface 853S of the insulating layer 853.

The first coil 41 is covered by the thin insulating layer 85B of the insulating layer 854. The thin insulating layer 85B of the insulating layer 854 includes a first upper surface portion 85CA, a first side surface portion 85CB, a first curved portion 85CC, and a first coil upper surface portion 85CD. The first upper surface portion 85CA, the first side surface portion 85CB, the first curved portion 85CC, and the first coil upper surface portion 85CD are integrated. Here, the first coil upper surface portion 85CD is an example of a “first conductive body upper surface portion.”

The first upper surface portion 85CA covers the upper surface 853S of the insulating layer 853. The first side surface portion 85CB is provided along the first exposed side surface 85AA. The first upper surface portion 85CA is connected to the first side surface portion 85CB. The first curved portion 85CC is in contact along the first curved surface 43P. The first curved portion 85CC is in contact with the first inner curved surface 43PA and the first outer curved surface 43PB. The first coil upper surface portion 85CD covers the first upper surface 41S of the first coil 41. The first coil upper surface portion 85CD is positioned between and connected to the first curved portions 85CC that contact the first inner curved surface 43PA and the first outer curved surface 43PB.

The thick insulating layer 85A of the insulating layer 854 is embedded in the first recess 43. More specifically, the thick insulating layer 85A of the insulating layer 854 is embedded in the recessed space formed by the first side surface portion 85CB and the first curved portion 85CC of the thin insulating layer 85B of the insulating layer 854. In this way, it can be said that the insulating layer 854 is embedded in the first recess 43. More specifically, the thick insulating layer 85A of the insulating layer 854 is embedded in the inner recessed space formed by the first side surface portion 85CB and the first curved portion 85CC of the thin insulating layer 85B corresponding to the first inner recess 43A. In addition, the thick insulating layer 85A of the insulating layer 854 is embedded in the outer recessed space formed by the first side surface portion 85CB and the first curved portion 85CC of the thin insulating layer 85B corresponding to the first outer recess 43B.

As shown in FIG. 10, the first inner terminal wiring 51A of the first conductor 51 is embedded in the first groove 86A of the insulating layer 853. The first inner terminal wiring 51A penetrates the insulating layer 853 in the Z direction and is in contact with the thick insulating layer 85A of the insulating layer 852.

The first inner terminal wiring 51A includes a first inner upper surface 51AS, a first inner lower surface 51AR, and a first inner side surface 51AA. The first inner upper surface 51AS is positioned near the insulating upper surface 84S of the insulating body 84. The first inner lower surface 51AR is on the opposite side of the first inner upper surface 51AS. The first inner lower surface 51AR is positioned near the insulating lower surface 84R (see FIG. 8) of the insulating body 84. The first inner side surface 51AA is provided between the first inner upper surface 51AS and the first inner lower surface 51AR in the Z direction.

The first inner upper surface 51AS is positioned at the same height in the Z direction as the upper surface 853S of the insulating layer 853. Therefore, the first inner upper surface 51AS is said to be positioned at the same Z-directional height as the first upper surface 41S of the first coil 41. Note that the Z-directional position of the first inner upper surface 51AS can be arbitrarily changed. In one example, the first inner upper surface 51AS may be positioned closer to the lower surface 853R of the insulating layer 853 than the upper surface 853S in the Z direction.

In one example, the first inner terminal wiring 51A is tapered such that it becomes narrower from the first inner upper surface 51AS toward the first inner lower surface 51AR. As a result, the pair of opposing first inner side surfaces 51AA are inclined so as to approach each other from the first inner upper surface 51AS toward the first inner lower surface 51AR.

The first inner terminal wiring 51A includes a seed layer 51AP and a plating layer 51AQ provided on the seed layer 51AP. The seed layer 51AP is provided on the side surface (the side surface 853A of the insulating layer 853) forming the first groove 86A and on the upper surface of the insulating layer 852 exposed by the first groove 86A. Accordingly, both the first inner lower surface 51AR and the first inner side surface 51AA are formed by the seed layer 51AP, while the first inner upper surface 51AS is formed by the plating layer 51AQ. The seed layer 51AP is a sputtered film formed by sputtering, and may be, for example, a laminated structure of a Ti film and a Cu film. The plating layer 51AQ may be made of a material containing Cu. The seed layer 51AP may be made of the same material as the seed layer 45A of the first coil 41. The plating layer 51AQ may be made of the same material as the plating layer 46A of the first coil 41.

As shown in FIG. 12, the first inner terminal wiring 51A includes a first inner corner portion 57A between the first inner side surface 51AA and the first inner upper surface 51AS. The first inner corner portion 57A includes a first inner recess 57AA. The first inner recess 57AA includes a first inner curved surface 57AP and is recessed inwardly of the first inner terminal wiring 51A so as to be convex in that direction. The first inner recess 57AA is provided around the entire periphery of the first inner terminal wiring 51A in plan view. The cross-sectional shape of the first inner curved surface 57AP as shown in FIG. 12 is arcuate. The first inner curved surface 57AP is arcuate about the intersection of a virtual line along the first inner upper surface 51AS and a virtual line along the first inner side surface 51AA. The first inner recess 57AA spans both the seed layer 51AP and the plating layer 51AQ.

In one example, the arc length of the cross-sectional shape of the first inner curved surface 57AP is equal to the arc length of the cross-sectional shape of the first curved surface 43P of the first recess 43 of the first coil 41. The radius of curvature of the first inner curved surface 57AP is also equal to the radius of curvature of the first curved surface 43P. Thus, the radius of curvature of the first inner curved surface 57AP is, for example, 1 μm.

The thick insulating layer 85A of the insulating layer 853 includes an inner exposed side surface 85AP that is exposed from the first inner side surface 51AA of the first inner terminal wiring 51A by the first inner recess 57AA. The inner exposed side surface 85AP is a portion of the side surface 853A of the insulating layer 853 between the upper edge of the first inner side surface 51AA and the upper surface 853S of the insulating layer 853. The inner exposed side surface 85AP faces the first inner recess 57AA in a direction perpendicular to the Z direction. In one example, the length of the inner exposed side surface 85AP is equal to the radius of curvature of the first inner curved surface 57AP. In another example, the length of the inner exposed side surface 85AP is equal to the length of the first exposed side surface 85AA corresponding to the first coil 41 (see FIG. 11). The length of the inner exposed side surface 85AP is defined by the distance between the upper edge of the first inner side surface 51AA and the upper surface 853S of the insulating layer 853.

The first inner terminal wiring 51A is covered by the thin insulating layer 85B of the insulating layer 854. The portion of the thin insulating layer 85B of the insulating layer 854 corresponding to the first inner terminal wiring 51A includes a wiring upper surface portion 85CE. The portion of the thin insulating layer 85B covering the first inner recess 57AA includes the first side surface portion 85CB and the first curved portion 85CC. The first side surface portion 85CB is provided along the inner exposed side surface 85AP. The first curved portion 85CC is in contact along the first inner curved surface 57AP. Here, the wiring upper surface portion 85CE is one example of a “first conductive body upper surface portion.”

The thick insulating layer 85A of the insulating layer 854 is embedded in the first inner recess 57AA. More specifically, the thick insulating layer 85A of the insulating layer 854 is embedded in the recessed space formed by the first side surface portion 85CB and the first curved portion 85CC of the thin insulating layer 85B of the insulating layer 854. In this way, it can be said that the insulating layer 854 is embedded in the first inner recess 57AA.

Although not shown in the drawings, the first outer terminal wiring 51B of the first conductor 51 has the same structure as the first inner terminal wiring 51A. The thin insulating layer 85B of the insulating layer 854 covers the first outer terminal wiring 51B in the same manner as the first inner terminal wiring 51A. The thick insulating layer 85A of the insulating layer 854 is embedded in a first outer recess provided in the first outer terminal wiring 51B in the same manner as for the first inner terminal wiring 51A.

(Second Conductor) As shown in FIG. 13, the second coil 42 of the second conductor 52 is provided in the insulating layer 857 among the insulating layers 851 to 857 of the insulator 84 as described above. The second coil 42 penetrates the insulating layer 857 in the Z direction and is sandwiched between the insulating layer 856 and the uppermost insulating layer 85U. Here, the insulating layer 857 corresponds to the “third insulating layer,” and the uppermost insulating layer 85U corresponds to the “fourth insulating layer.”

Since the second groove 86B formed in the insulating layer 857 penetrates the insulating layer 857 in the Z direction, the thick insulating layer 85A of the insulating layer 856 is exposed. Accordingly, the second conductor 52 embedded in the second groove 86B is in contact with the thick insulating layer 85A of the insulating layer 856. In one example, the second groove 86B tapers from the upper surface 857S to the lower surface 857R of the insulating layer 857. The angle θ2 of the side surface 857A of the insulating layer 857 is between 80° and 90°. In one example, angle θ2 is 85°. Here, the side surface 857A of the insulating layer 857 is a surface forming the second groove 86B, and angle θ2 can be defined as the angle between the lower surface 857R and the side surface 857A of the insulating layer 857.

The second coil 42 of the second conductor 52 is formed by a coil wiring 41Q having a predetermined width. The second coil 42 includes a second upper surface 42S, a second lower surface 42R, and a second side surface 42A. The second upper surface 42S is located on the side of the second coil 42 near the insulating upper surface 84S of the insulator 84. The second lower surface 42R is the surface opposite the second upper surface 42S and is located on the side of the second coil 42 near the insulating lower surface 84R (see FIG. 8) of the insulator 84. The second side surface 42A is formed between the second upper surface 42S and the second lower surface 42R in the Z direction.

In the first embodiment, the second upper surface 42S is located at the same position in the Z direction as the upper surface 857S of the insulating layer 857. Here, the upper surface 857S of the insulating layer 857 is formed by the upper surface of the thick insulating layer 85A of the insulating layer 857. Note that the Z-direction position of the second upper surface 42S can be arbitrarily changed. In one example, the second upper surface 42S may be located closer to the lower surface 857R of the insulating layer 857 than the upper surface 857S in the Z direction.

The second side surface 42A includes a second inner side surface 42AA and a second outer side surface 42AB. The second inner side surface 42AA is provided on the inner side in the width direction of the second conductor 52, meaning it forms the inner widthwise portion of the coil wiring 41Q that constitutes the second coil 42. The second outer side surface 42AB is provided on the outer side in the width direction of the second conductor 52, meaning it forms the outer widthwise portion of the coil wiring 41Q that constitutes the second coil 42.

In one example, the second conductor 52 has a tapered shape in which the second side surface 42A is inclined so as to narrow from the second upper surface 42S toward the second lower surface 42R. That is, the coil wiring 41Q that constitutes the second coil 42 has a tapered shape in which the second side surface 42A is inclined so as to narrow from the second upper surface 42S toward the second lower surface 42R. Accordingly, the second inner side surface 42AA and the second outer side surface 42AB are inclined so as to approach each other from the second upper surface 42S toward the second lower surface 42R. In the first embodiment, the shape of the coil wiring 41Q is the same as the shape of the coil wiring 41P.

The second coil 42 includes a seed layer 45B and a plating layer 46B provided on the seed layer 45B. The seed layer 45B is provided on the side surfaces forming the second groove 86B (i.e., the side surfaces 857A of the insulating layer 857) and on the upper surface of the insulating layer 856 exposed through the second groove 86B. Accordingly, both the second lower surface 42R and the second side surface 42A are formed of the seed layer 45B. The second upper surface 42S is formed of the plating layer 46B. The seed layer 45B has the same structure as the seed layer 45A, and the plating layer 46B has the same structure as the plating layer 46A.

The second coil 42 includes a second corner portion 42C located between the second side surface 42A and the second upper surface 42S. The second corner portion 42C includes a second inner corner portion 42CA and a second outer corner portion 42CB. The second inner corner portion 42CA is the region between the second inner side surface 42AA and the second upper surface 42S. The second outer corner portion 42CB is the region between the second outer side surface 42AB and the second upper surface 42S.

As shown in FIG. 14, a second recess 44 is provided in the second corner portion 42C. The second recess 44 includes a second curved surface 44P. The second recess 44 is recessed so as to be convex toward the inside of the second coil 42. The cross-sectional shape of the second curved surface 44P in the sectional view shown in FIG. 14 is arcuate. The second recess 44 is arcuate about the intersection of a third imaginary line L3 along the second upper surface 42S and a fourth imaginary line LA4 (or LB4) along the second side surface 42A. The second recess 44 extends over both the seed layer 45B and the plating layer 46B.

The second recess 44 extends over the entire length direction of the coil wiring 41Q. Specifically, as shown in FIG. 5, the second coil 42 includes a pair of second straight portions 42D and a pair of second curved portions 42E that connect both ends of the pair of second straight portions 42D. The second recess 44 shown in FIG. 14 is continuously provided over both the pair of second straight portions 42D and the pair of second curved portions 42E.

As shown in FIG. 14, the second recess 44 includes a second inner recess 44A including a second inner curved surface 44PA, and a second outer recess 44B including a second outer curved surface 44PB. The second inner recess 44A is provided in the second inner corner portion 42CA. The second outer recess 44B is provided in the second outer corner portion 42CB.

The cross-sectional shape of the second inner curved surface 44PA in the sectional view shown in FIG. 14 is arcuate. That is, the cross-sectional shape of the second inner curved surface 44PA is an arc centered on a second inner curvature center CA2. The second inner curvature center CA2 of the second inner curved surface 44PA is located outside the coil wiring 41Q. In one example, the second inner curvature center CA2 is the intersection of the third imaginary line L3 along the second upper surface 42S and the fourth imaginary line LA4 along the second inner side surface 42AA.

The cross-sectional shape of the second outer curved surface 44PB in the sectional view shown in FIG. 14 is arcuate. That is, the cross-sectional shape of the second outer curved surface 44PB is an arc centered on a second outer curvature center CB2. The second outer curvature center CB2 of the second outer curved surface 44PB is located outside the coil wiring 41Q. In one example, the second outer curvature center CB2 is the intersection of the third imaginary line L3 along the second upper surface 42S and the fourth imaginary line LB4 along the second outer side surface 42AB.

In one example, the arc length of the cross-sectional shape of the second inner curved surface 44PA is equal to that of the second outer curved surface 44PB. It can also be said that the radius of curvature of the second inner curved surface 44PA is equal to that of the second outer curved surface 44PB. Each of the radii of curvature of the second inner curved surface 44PA and the second outer curved surface 44PB is greater than the thickness of the thin insulating layer 85B and smaller than the thickness of the thick insulating layer 85A. In one example, the arc length of the cross-sectional shape of the second inner curved surface 44PA is equal to that of the first inner curved surface 43PA shown in FIG. 11. Similarly, the arc length of the second outer curved surface 44PB is equal to that of the first outer curved surface 43PB shown in FIG. 11. The radius of curvature of the second inner curved surface 44PA and that of the second outer curved surface 44PB are, for example, 1 μm. Thus, the arc length of the cross-sectional shape of the second curved surface 44P is equal to that of the first curved surface 43P shown in FIG. 11.

The thick insulating layer 85A of the insulating layer 857 includes a second exposed side surface 85AB, which is exposed from the second side surface 42A of the second coil 42 by the second recess 44. The second exposed side surface 85AB is a portion of the side surface 857A of the insulating layer 857 between the upper edge of the second side surface 42A and the upper surface 857S of the insulating layer 857. The second exposed side surface 85AB faces the second curved surface 44P of the second recess 44 in a direction orthogonal to the Z-direction. In one example, the length of the second exposed side surface 85AB is equal to the radius of curvature of the second curved surface 44P (for example, the radius of curvature of the second inner curved surface 44PA). Here, the length of the second exposed side surface 85AB can be defined as the distance between the upper edge of the second side surface 42A and the upper surface 857S of the insulating layer 857.

The second coil 42 is covered by the thin insulating layer 85B of the top insulating layer 85U. The thin insulating layer 85B of the top insulating layer 85U includes a second upper surface portion 85DA, a second side surface portion 85DB, a second curved portion 85DC, and a second coil upper surface portion 85DD. The second upper surface portion 85DA, the second side surface portion 85DB, the second curved portion 85DC, and the second coil upper surface portion 85DD are integrated. Here, the second coil upper surface portion 85DD is an example of a “second conductive member upper surface portion.”

The second upper surface portion 85DA covers the upper surface 857S of the insulating layer 857. The second side surface portion 85DB is provided along the second exposed side surface 85AB. The second upper surface portion 85DA is connected to the second side surface portion 85DB. The second curved portion 85DC is in contact along the second curved surface 44P. The second curved portion 85DC is in contact with both the second inner curved surface 44PA and the second outer curved surface 44PB. The second coil upper surface portion 85DD covers the second upper surface 42S of the second coil 42. The second coil upper surface portion 85DD is located between the second curved portions 85DC that are in contact with the second inner curved surface 44PA and the second outer curved surface 44PB, and is connected to these second curved portions 85DC.

The thick insulating layer 85A of the top insulating layer 85U is embedded in the second recess 44. More specifically, the thick insulating layer 85A of the top insulating layer 85U is embedded in the recessed space formed by the second side surface portion 85DB and the second curved portion 85DC of the thin insulating layer 85B in the top insulating layer 85U. Thus, it can be said that the second recess 44 is filled with the top insulating layer 85U. Further, the thick insulating layer 85A of the top insulating layer 85U is embedded in the inner recessed space formed by the second side surface portion 85DB and the second curved portion 85DC of the thin insulating layer 85B in the top insulating layer 85U corresponding to the second inner recess 44A. The thick insulating layer 85A of the top insulating layer 85U is also embedded in the outer recessed space formed by the second side surface portion 85DB and the second curved portion 85DC of the thin insulating layer 85B in the top insulating layer 85U corresponding to the second outer recess 44B.

As shown in FIG. 13, the second inner end wiring 52A of the second conductive member 52 is embedded in the second groove 86B of the insulating layer 857. The second inner end wiring 52A penetrates through the insulating layer 857 in the Z-direction and is in contact with the thick insulating layer 85A of the insulating layer 856. The structure of the second inner end wiring 52A is the same as that of the first inner end wiring 51A shown in FIG. 12. Therefore, a detailed description of the second inner end wiring 52A is omitted.

Although not illustrated, the second outer end wiring 52B of the second conductive member 52 has the same structure as the second inner end wiring 52A. The thin insulating layer 85B of the top insulating layer 85U covers both the second inner end wiring 52A and the second outer end wiring 52B. The thick insulating layer 85A of the top insulating layer 85U is embedded in the second inner recess provided on the second inner end wiring 52A and in the second outer recess provided on the second outer end wiring 52B.

### (Dummy Pattern)

As shown in FIG. 13, the dummy pattern 55 is embedded in the second groove 86B similarly to the second coil 42. The cross-sectional shape of the dummy wiring 55P that constitutes the dummy pattern 55 is the same as the cross-sectional shape of the coil wiring 41Q that constitutes the second coil 42. That is, the dummy wiring 55P is provided with a recess 55Q that includes a curved surface 55R.

The thin insulating layer 85B of the top insulating layer 85U covers the dummy pattern 55 in the same manner as the second coil 42. Therefore, the thin insulating layer 85B is provided so as to contact the curved surface 55R. The thick insulating layer 85A of the top insulating layer 85U is embedded in the recess 55Q.

### (Method of Manufacturing the Insulating Chip)

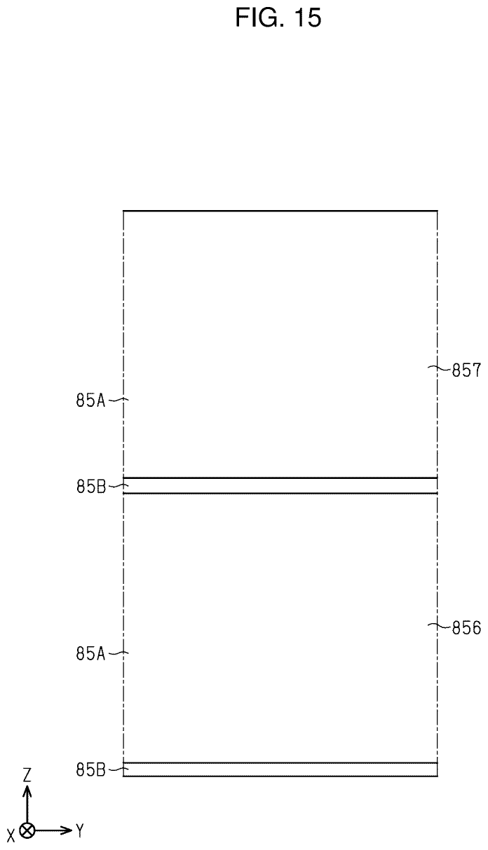

With reference to FIGS. 15 to 22, an example of a method of manufacturing the insulating chip 80 will be described. FIGS. 15 to 22 are schematic cross-sectional views illustrating an exemplary method for manufacturing the second coil 42 of the second conductive member 52 of the insulating chip 80. These figures schematically show a portion of the cross-sectional structure of the second coil 42, shown in FIG. 13, which is a partial portion of the insulating chip 80 shown in FIG. 8. Therefore, components other than the insulating layers 85 around the second coil 42 are omitted in FIGS. 15 to 22. For symbols not shown in the drawings, refer to FIGS. 8 to 13. Additionally, in FIGS. 15 to 22, for ease of understanding, reference numerals from FIGS. 8 to 13 are partially shown in parentheses for members or corresponding members that are final structural components of the insulating chip 80.

As shown in FIG. 15, the method of manufacturing the insulating chip 80 includes a step of forming the insulating layers 856 and 857. In one example, the insulating layers 856 and 857 are formed on the insulating layer 855 (see FIG. 8) by chemical vapor deposition (CVD). In one example, the insulating layers 856 and 857 are formed by alternately laminating the thick insulating layer 85A and the thin insulating layer 85B in repetition. The insulating layers 856 and 857 are formed by repeating the lamination of the thin insulating layer 85B and the thick insulating layer 85A alternately.

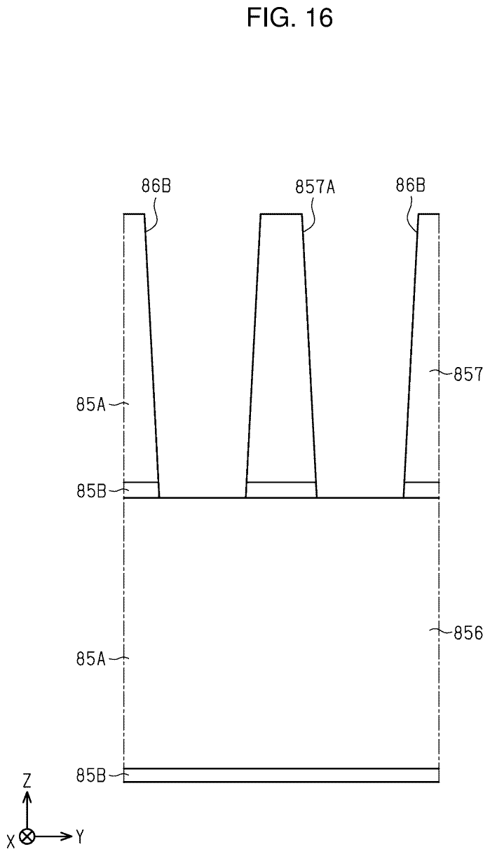

As shown in FIG. 16, the method of manufacturing the insulating chip 80 includes a step of forming the second groove 86B. In one example, by selectively and partially etching the insulating layer 857, the second groove 86B is formed in the insulating layer 857 so that a part of the upper surface of the insulating layer 856 is exposed. As a result, the side surface 857A of the insulating layer 857 is formed.

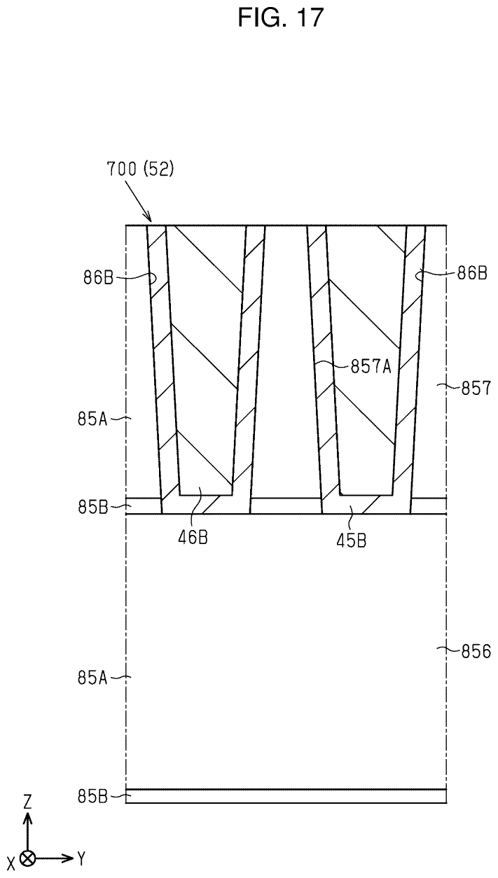

As shown in FIGS. 17 to 20, the method of manufacturing the insulating chip 80 includes a step of forming the second conductive member 52. As shown in FIG. 17, the step of forming the second conductive member 52 includes a step of forming a conductive layer 700. In this step, for example by electroplating, a conductive layer 700 is formed on the side surface of the second groove 86B and on the exposed upper surface of the insulating layer 856 caused by the second groove 86B. The conductive layer 700 may include a seed layer 45B and a plating layer 46B. In one example, a seed layer 45B is formed by sputtering so as to cover the side surface of the second groove 86B and the upper surface of the insulating layer 856 exposed by the second groove 86B. Subsequently, a conductive material including Cu is grown from the seed layer 45B by plating to form the conductive layer 700. The conductive layer 700 is formed so as to fill the second groove 86B.

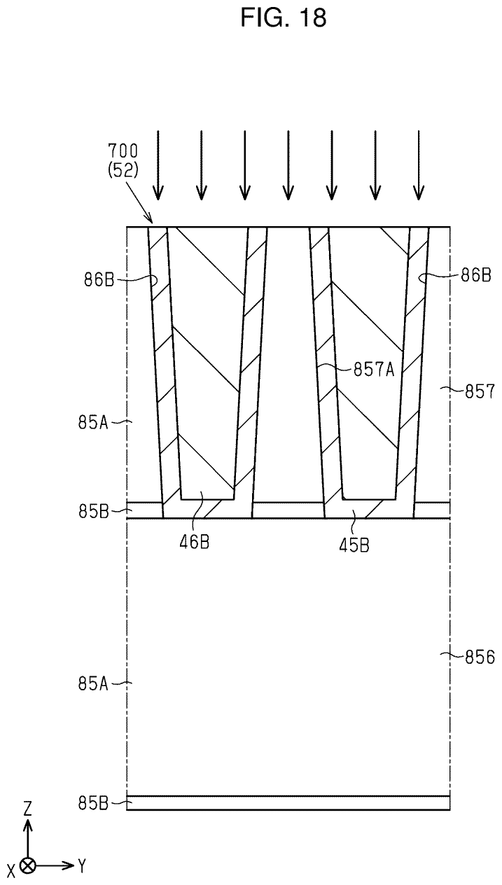

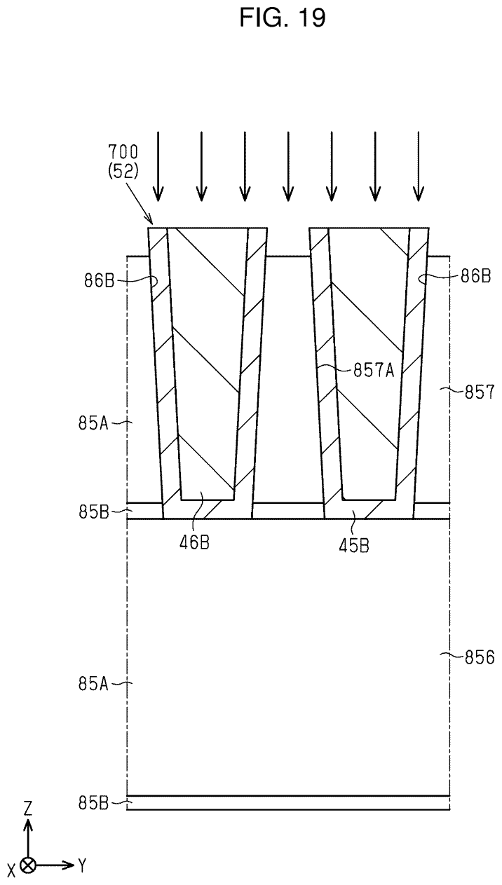

As shown in FIG. 18, the step of forming the second conductive member 52 includes a step of thinning the insulating layer 857. In this step, for example, the thick insulating layer 85A of the insulating layer 857 is partially removed by dry etching so that its thickness is reduced. As a result, as shown in FIG. 19, the conductive layer 700 protrudes from the thick insulating layer 85A of the insulating layer 857.

Subsequently, as shown in FIG. 19, the step of forming the second conductive member 52 includes a step of partially removing the conductive layer 700. In this step, for example, the portion of the conductive layer 700 that protrudes beyond the thick insulating layer 85A of the insulating layer 857 is removed by wet etching (isotropic etching).

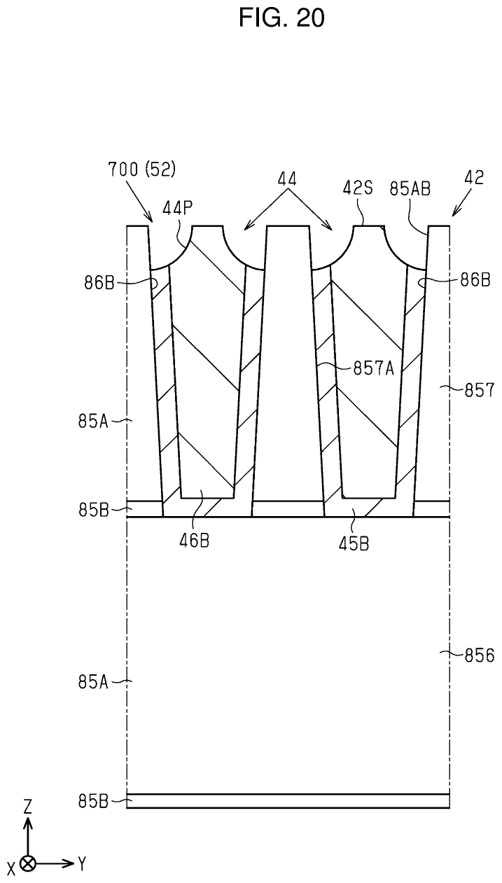

Then, as shown in FIG. 20, the step of forming the second conductive member 52 includes a step of forming the second recess 44. In this step, the second recess 44 is formed, for example, by wet etching (isotropic etching). By forming the second recess 44, the second upper surface 42S and the second side surface 42A are defined. Although not illustrated, the second inner end wiring 52A (see FIG. 10) and the second outer end wiring 52B (see FIG. 13) are formed in the steps shown in FIGS. 17 to 20. Through the above steps, the second conductive member 52 is formed. Additionally, by forming the second recess 44, the second exposed side surface 85AB is formed in the insulating layer 857.

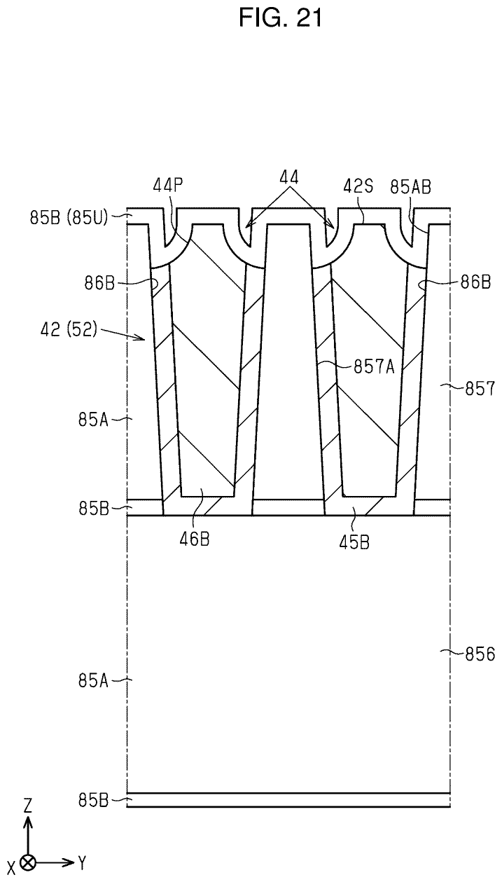

As shown in FIG. 21, the method for manufacturing the insulating chip 80 includes a step of forming the thin insulating layer 85B of the top insulating layer 85U. In this step, the thin insulating layer 85B is formed so as to cover the top surface of the thick insulating layer 85A of the insulating layer 857, the second exposed side surface 85AB, the second curved surface 44P of the second recess 44, and the second upper surface 42S.

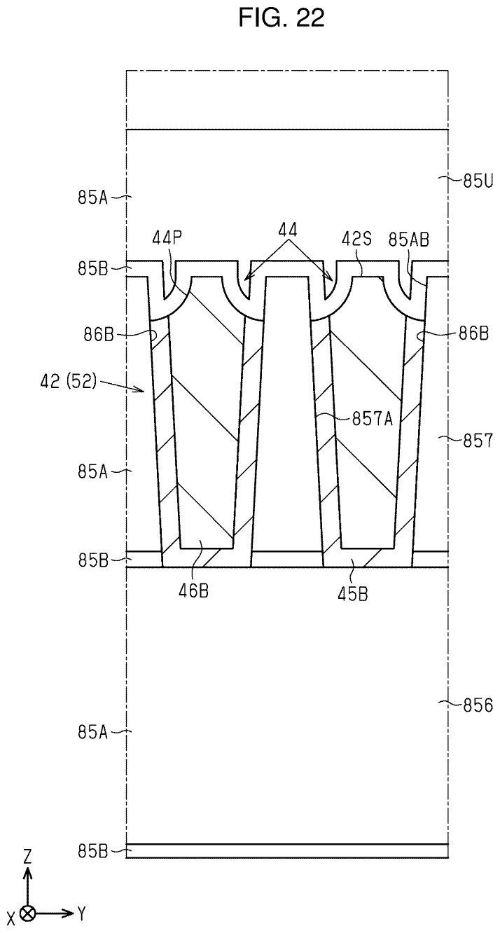

As shown in FIG. 22, the method for manufacturing the insulating chip 80 includes a step of forming the thick insulating layer 85A of the top insulating layer 85U. In this step, the thick insulating layer 85A is formed, for example, by a CVD method. Here, the thick insulating layer 85A is formed so as to be embedded in the second recess 44 of the top insulating layer 85U. Through the above steps, the second conductive member 52 is completed.

### Operations of First Embodiment

The operation of the first embodiment is described below.

The second coil 42 of the second conductive member 52 includes the second corner portion 42C located between the second side surface 42A and the second upper surface 42S. The second corner portion 42C is provided with the second recess 44 including the second curved surface 44P, which is concave inward with respect to the second conductive member 52 (the coil wiring 41Q of the second coil 42). Accordingly, the second corner portion 42C does not have a sharp edge where the second side surface 42A and the second upper surface 42S directly connect. In addition, since the second corner portion 42C is rounded by the second recess 44 including the second curved surface 44P, the electric field concentration at the second corner portion 42C of the second coil 42 can be alleviated.

### Advantages of First Embodiment

According to the first embodiment, the following advantages are obtained:

(1-1) The insulating chip 80 includes an insulating top surface 84S and an insulating bottom surface 84R opposite to the insulating top surface 84S, and includes an insulator 84 formed of a plurality of insulating layers 85 stacked in the Z direction, a first conductive member 51 disposed near the insulating bottom surface 84R within the insulator 84, and a second conductive member 52 disposed within the insulator 84 closer to the insulating top surface 84S than the first conductive member 51 and facing the first conductive member 51 in the Z direction. The second coil 42 as the second conductive member 52 includes a second upper surface 42S disposed closer to the insulating top surface 84S, a second lower surface 42R opposite to the second upper surface 42S, a second side surface 42A provided between the second upper surface 42S and the second lower surface 42R in the Z direction, and a second corner portion 42C located between the second side surface 42A and the second upper surface 42S. The second corner portion 42C is provided with a second recess 44 including a second curved surface 44P recessed so as to protrude inward with respect to the second coil 42 as the second conductive member 52.

According to this structure, because an edge is not formed at the second corner portion 42C of the second coil 42 due to the second recess 44, electric field concentration at the second corner portion 42C can be mitigated. Therefore, a reduction in the breakdown voltage of the insulating chip 80 caused by electric field concentration at the second corner portion 42C can be suppressed.

In addition, because the second recess 44 forms a reverse-tapered shape from the second upper surface 42S toward the second side surface 42A, the stress generated in the second recess 44 is directed inward toward the second coil 42. That is, stress is less likely to be applied from the second recess 44 to the insulating layer 85. Accordingly, the occurrence of cracks in the insulating layer 85 can be suppressed.

(1-2) The cross-sectional shape of the second curved surface 44P is an arc.

According to this structure, because the second recess 44 forms a reverse-tapered curved shape from the second upper surface 42S toward the second side surface 42A, the stress generated in the second recess 44 is directed inward toward the second coil 42. In other words, stress is less likely to be applied from the second recess 44 to the insulating layer 85. Therefore, cracking of the insulating layer 85 can be prevented.

(1-3) The second coil 42 as the second conductive member 52 has a predetermined width. The second side surface 42A includes a second inner side surface 42AA on the inner side in the X-direction as the width direction of the second conductive member 52, and a second outer side surface 42AB on the outer side in the X-direction. The second corner portion 42C includes a second inner corner portion 42CA between the second inner side surface 42AA and the second upper surface 42S, and a second outer corner portion 42CB between the second outer side surface 42AB and the second upper surface 42S. The second recess 44 includes a second inner recess 44A having a second inner curved surface 44PA formed at the second inner corner portion 42CA, and a second outer recess 44B having a second outer curved surface 44PB formed at the second outer corner portion 42CB.

According to this structure, because recesses are provided on both the inner and outer sides of the second coil 42—in other words, edges are not formed on either side—electric field concentration at both the inner and outer corner portions of the second coil 42 can be mitigated. Therefore, a reduction in breakdown voltage of the insulating chip 80 caused by such electric field concentration can be suppressed.

In addition, because the second inner recess 44A and the second outer recess 44B form reverse-tapered shapes from the second upper surface 42S toward the second inner side surface 42AA and the second outer side surface 42AB, respectively, the stresses generated in both the second inner recess 44A and the second outer recess 44B are directed inward toward the second coil 42. That is, the stresses generated in the recesses on both the inner and outer sides of the second coil 42 act inwardly on the second coil 42. Accordingly, stress is less likely to be applied to the insulating layer 85 from both the second inner recess 44A and the second outer recess 44B. Thus, cracking of the insulating layer 85 can be prevented.

(1-4) The arc length of the cross-sectional shape of the second inner curved surface 44PA is equal to the arc length of the cross-sectional shape of the second outer curved surface 44PB.

According to this structure, electric field concentration at one of the second inner corner portion 42CA or the second outer corner portion 42CB due to a size difference between the second inner curved surface 44PA and the second outer curved surface 44PB can be prevented.

(1-5) The second coil 42 as the second conductive member 52 has a tapered shape in which the second side surface 42A is inclined so as to narrow from the second upper surface 42S toward the second lower surface 42R.

According to this structure, when the second side surface 42A is inclined, an edge is likely to form at the second corner portion 42C if the second side surface 42A and the second upper surface 42S are directly connected. However, since the second corner portion 42C is provided with the second recess 44, such an edge is eliminated, and even if the second coil 42 has a tapered shape, electric field concentration at the second corner portion 42C can be mitigated.

(1-6) The first coil 41 as the first conductive member 51 includes a first upper surface 41S, a first lower surface 41R opposite to the first upper surface 41S, a first side surface 41A provided between the first upper surface 41S and the first lower surface 41R in the Z direction, and a first corner portion 41C between the first side surface 41A and the first upper surface 41S. The first corner portion 41C is provided with a first recess 43 including a first curved surface 43P that is concave inward toward the first coil 41 as the first conductive member 51.

According to this structure, the first recess 43 prevents the formation of an edge at the first corner portion 41C of the first coil 41, thereby mitigating electric field concentration at the first corner portion 41C. Therefore, a reduction in breakdown voltage of the insulating chip 80 due to electric field concentration at the first corner portion 41C can be suppressed.

In addition, since the first recess 43 forms a reverse-tapered shape from the first upper surface 41S toward the first side surface 41A, the stress generated in the first recess 43 acts inwardly toward the first coil 41. That is, stress is less likely to be transmitted from the first recess 43 to the insulating layer 85. Accordingly, cracks in the insulating layer 85 can be prevented.

(1-7) The cross-sectional shape of the first curved surface 43P is an arc.

According to this structure, since the first recess 43 forms a reverse-tapered curved shape from the first upper surface 41S toward the first side surface 41A, the stress generated in the first recess 43 acts inwardly toward the first coil 41. That is, stress is less likely to be transmitted from the first recess 43 to the insulating layer 85. Accordingly, cracks in the insulating layer 85 can be prevented.

(1-8) The first coil 41 as the first conductive member 51 has a predetermined width. The first side surface 41A includes a first inner side surface 41AA on the inner side in the X direction as the width direction of the first conductive member 51, and a first outer side surface 41AB on the outer side in the X direction. The first corner portion 41C includes a first inner corner portion 41CA between the first inner side surface 41AA and the first upper surface 41S, and a first outer corner portion 41CB between the first outer side surface 41AB and the first upper surface 41S. The first recess 43 includes a first inner recess 43A having a first inner curved surface 43PA formed at the first inner corner portion 41CA, and a first outer recess 43B having a first outer curved surface 43PB formed at the first outer corner portion 41CB.

According to this structure, because recesses are formed on both the inner and outer sides of the first coil 41-in other words, no edges are formed on either side-electric field concentration at both the inner and outer corner portions of the first coil 41 can be mitigated. Therefore, a reduction in breakdown voltage of the insulating chip 80 caused by such electric field concentration can be suppressed.

(1-9) The arc length of the cross-sectional shape of the first inner curved surface 43PA is equal to that of the first outer curved surface 43PB.

According to this structure, it is possible to prevent electric field concentration at either the first inner corner portion 41CA or the first outer corner portion 41CB due to differences in size between the first inner curved surface 43PA and the first outer curved surface 43PB.

(1-10) The first coil 41 as the first conductive member 51 has a tapered shape such that the first side surface 41A narrows from the first upper surface 41S toward the first lower surface 41R. According to this structure, when the first side surface 41A is inclined, an edge tends to form at the first corner portion 41C if the first side surface 41A and the first upper surface 41S are directly connected. However, since the first corner portion 41C is provided with the first recess 43, no such edge is formed, and electric field concentration at the first corner portion 41C can be mitigated even if the first coil 41 is tapered.

### Second Embodiment

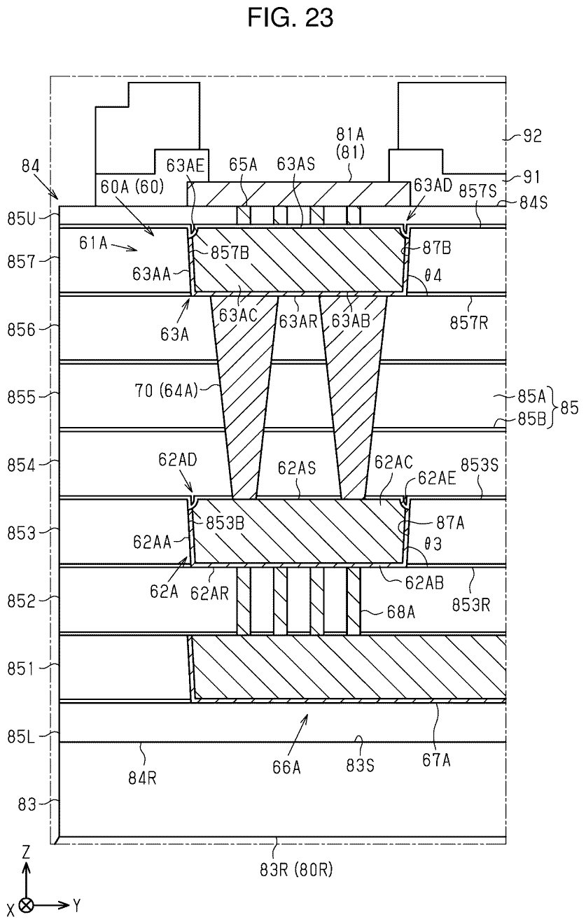

With reference to FIGS. 23 to 25, the insulating chip 80 of the second embodiment will be described.

In the insulating chip 80 of the second embodiment, the configuration of the connection wiring 60 differs primarily from that in the insulating chip 80 of the first embodiment.

In the following, components common to the first embodiment are denoted by the same reference numerals and their descriptions are omitted.

FIG. 23 shows an enlarged sectional structure of a portion of the first connection wiring 60A.

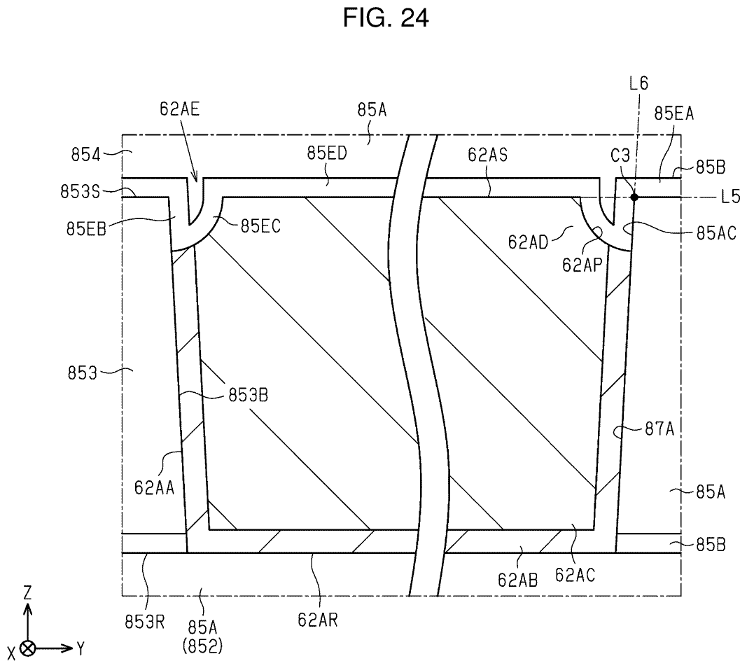

FIG. 24 shows an enlarged sectional structure of a portion of the first layer wiring 62A of the first connection wiring 60A.

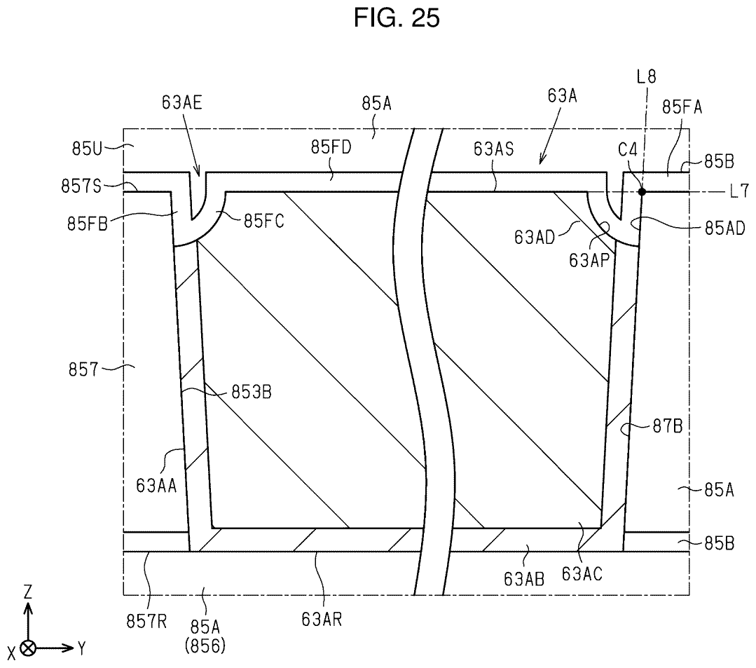

FIG. 25 shows an enlarged sectional structure of a portion of the second layer wiring 63A of the first connection wiring 60A.

### [First Layer Wiring]

With reference to FIGS. 23 and 24, the configuration of the first layer wiring 62A will be described.

As shown in FIGS. 23 and 24, the first layer wiring 62A is provided in the insulating layer 853 among the insulating layers 851-857 of the insulator 84. The first layer wiring 62A penetrates through the insulating layer 853 in the Z direction. The first layer wiring 62A is sandwiched between the insulating layers 852 and 854.

Since the through-hole 87A formed in the insulating layer 853 penetrates through the insulating layer 853 in the Z direction, it exposes the thick insulating layer 85A of the insulating layer 852. Accordingly, the first layer wiring 62A embedded in the through-hole 87A is in contact with the thick insulating layer 85A of the insulating layer 852.

In one example, the through-hole 87A has a tapered shape narrowing from the upper surface 853S of the insulating layer 853 toward the lower surface 853R. The angle θ3 of the side surface 853B of the insulating layer 853 that constitutes the through-hole 87A is between 80° and 90°. In one example, the angle θ3 is 85°. Here, the angle θ3 is defined as the angle between the lower surface 853R and the side surface 853B of the insulating layer 853.

The first layer wiring 62A, for example, has a rectangular shape in plan view. The first layer wiring 62A includes a first wiring upper surface 62AS, a first wiring lower surface 62AR, and a first wiring side surface 62AA.

The first wiring upper surface 62AS is disposed toward the insulating upper surface 84S of the insulator 84.

The first wiring lower surface 62AR is on the opposite side from the upper surface 62AS and is located toward the insulating lower surface 84R of the insulator 84.

The first wiring side surface 62AA is disposed between the first wiring upper surface 62AS and the first wiring lower surface 62AR in the Z direction.

In the second embodiment, the first wiring upper surface 62AS is located at the same position in the Z direction as the upper surface 853S of the insulating layer 853. Here, the upper surface 853S of the insulating layer 853 is constituted by the upper surface of the thick insulating layer 85A of the insulating layer 853.

Note that the Z-direction position of the first wiring upper surface 62AS can be changed as appropriate.

In one example, the first wiring upper surface 62AS may be located closer to the lower surface 853R of the insulating layer 853 than to the upper surface 853S in the Z direction.

The first layer wiring 62A embedded in the through-hole 87A is tapered such that the first wiring side surface 62AA is inclined to narrow from the first wiring upper surface 62AS toward the first wiring lower surface 62AR.

That is, the opposing first wiring side surfaces 62AA incline toward each other from the first wiring upper surface 62AS to the lower surface 62AR.

The first layer wiring 62A includes a seed layer 62AB and a plating layer 62AC provided on the seed layer 62AB.

The seed layer 62AB is provided on the side surface (side surface 853B of the insulating layer 853) that constitutes the through-hole 87A and on the upper surface of the insulating layer 852 exposed by the through-hole 87A.

Accordingly, both the lower surface 62AR and side surface 62AA of the first wiring are formed from the seed layer 62AB.

The upper surface 62AS of the first wiring is formed from the plating layer 62AC.

In one example, the seed layer 62AB has the same configuration as the seed layer 45A shown in FIG. 11, and the plating layer 62AC has the same configuration as the plating layer 46A shown in FIG. 11.

As shown in FIG. 24, the first layer wiring 62A includes a first wiring corner portion 62AD between the first wiring side surface 62AA and the first wiring upper surface 62AS.

The first wiring corner portion 62AD is provided with a third recess 62AE.

The third recess 62AE includes a third curved surface 62AP and is recessed inward so as to protrude inwardly into the first layer wiring 62A.

In the cross-sectional view shown in FIG. 24, the third curved surface 62AP has an arc shape. The third recess 62AE is arc-shaped about a third curvature center C3, which is the intersection of a fifth imaginary line L5 extending along the first wiring upper surface 62AS and a sixth imaginary line L6 extending along the first wiring side surface 62AA.

The third curvature center C3 is located outward of the first layer wiring 62A.

The third recess 62AE extends across both the seed layer 62AB and the plating layer 62AC.

In one example, the third recess 62AE is provided around the entire periphery of the first layer wiring 62A in plan view.

The arc length of the cross-sectional shape of the third curved surface 62AP is equal to that of the first curved surface 43P of the first recess 43 shown in FIG. 11.

The radius of curvature of the third curved surface 62AP is also equal to that of the first curved surface 43P.

The arc length of the cross-sectional shape of the third curved surface 62AP is equal to that of the second curved surface 44P of the second recess 44 shown in FIG. 14.

The radius of curvature of the third curved surface 62AP is also equal to that of the second curved surface 44P.

For example, the radius of curvature of the third curved surface 62AP is 1 μm.

The thick insulating layer 85A of the insulating layer 853 includes a third exposed side surface 85AC that is exposed from the first wiring side surface 62AA due to the third recess 62AE. The third exposed side surface 85AC is a portion of the side surface 853B of the insulating layer 853 between the upper edge of the first wiring side surface 62AA and the upper surface 853S of the insulating layer 853.

The third exposed side surface 85AC faces the third curved surface 62AP of the third recess 62AE in a direction orthogonal to the Z direction.

In one example, the length of the third exposed side surface 85AC is equal to the radius of curvature of the third curved surface 62AP.

Here, the length of the third exposed side surface 85AC can be defined as the distance between the upper edge of the first wiring side surface 62AA and the upper surface 853S of the insulating layer 853.

The first layer wiring 62A is covered by the thin insulating layer 85B of the insulating layer 854. The portion of the thin insulating layer 85B of the insulating layer 854 corresponding to the first layer wiring 62A includes a third upper surface portion 85EA, a third side surface portion 85EB, a third curved portion 85EC, and a first wiring upper surface portion 85ED.

The third upper surface portion 85EA, third side surface portion 85EB, third curved portion 85EC, and first wiring upper surface portion 85ED are integrated.

The third upper surface portion 85EA covers the upper surface 853S of the insulating layer 853 and is in contact with it.

The third upper surface portion 85EA may be integrated with the first upper surface portion 85CA shown in FIG. 11.

The third side surface portion 85EB is provided along the third exposed side surface 85AC and is connected to the third upper surface portion 85EA.

The third curved portion 85EC is in contact with the third curved surface 62AP and is connected to the third side surface portion 85EB.

The first wiring upper surface portion 85ED covers the first wiring upper surface 62AS and is in contact with it.

The first wiring upper surface portion 85ED is connected to the third curved portion 85EC.

The thick insulating layer 85A of the insulating layer 854 is embedded in the third recess 62AE. More specifically, the thick insulating layer 85A of the insulating layer 854 is embedded in a recess space formed by the third side portion 85EB and the third curved portion 85EC of the thin insulating layer 85B of the insulating layer 854. In this manner, it can be said that the third recess 62AE is filled with the insulating layer 854.

### [Second Layer Wiring]

With reference to FIGS. 23 and 25, the configuration of the second layer wiring 63A will be explained. As shown in FIGS. 23 and 25, the second layer wiring 63A is provided in the insulating layer 857 among the insulating layers 851-857 of the insulator 84. The second layer wiring 63A penetrates through the insulating layer 857 in the Z-direction. The second layer wiring 63A is sandwiched between the insulating layer 856 and the topmost insulating layer 85U.

The through-hole 87B formed in the insulating layer 857 penetrates through the insulating layer 857 in the Z-direction and thus exposes the thick insulating layer 85A of the insulating layer 856. Accordingly, the second layer wiring 63A embedded in the through-hole 87B is in contact with the thick insulating layer 85A of the insulating layer 856. In one example, the through-hole 87B has a tapered shape narrowing from the upper surface 857S toward the lower surface 857R of the insulating layer 857. The angle θ4 of the side surface 857B of the insulating layer 857 forming the through-hole 87B is between 80° and 90°. In one example, the angle θ4 is 85°. Here, the angle θ4 can be defined as the angle between the lower surface 857R and the side surface 857B of the insulating layer 857.

The second layer wiring 63A may have a rectangular shape in plan view. The second layer wiring 63A includes a second wiring upper surface 63AS, a second wiring lower surface 63AR, and a second wiring side surface 63AA. The second wiring upper surface 63AS is positioned closer to the insulating upper surface 84S of the insulator 84. The second wiring lower surface 63AR is the surface opposite the second wiring upper surface 63AS and is located closer to the insulating lower surface 84R (see FIG. 8) of the insulator 84. The second wiring side surface 63AA is formed between the second wiring upper surface 63AS and the second wiring lower surface 63AR in the Z-direction.

In the second embodiment, the second wiring upper surface 63AS is located at the same height in the Z-direction as the upper surface 857S of the insulating layer 857. The upper surface 857S of the insulating layer 857 is formed by the upper surface of the thick insulating layer 85A of the insulating layer 857. It should be noted that the Z-direction position of the second wiring upper surface 63AS may be arbitrarily changed. In one example, the second wiring upper surface 63AS may be located closer to the lower surface 857R of the insulating layer 857 than the upper surface 857S in the Z-direction. The second layer wiring 63A embedded in the through-hole 87B has a tapered shape in which the second wiring side surface 63AA narrows from the second wiring upper surface 63AS toward the second wiring lower surface 63AR. That is, the opposing second wiring side surfaces 63AA are inclined such that they approach each other from the second wiring upper surface 63AS toward the second wiring lower surface 63AR.

The second layer wiring 63A includes a seed layer 63AB and a plating layer 63AC formed on the seed layer 63AB. The seed layer 63AB is provided on the side surface forming the through-hole 87B (the side surface 857B of the insulating layer 857) and the upper surface of the insulating layer 856 exposed through the through-hole 87B. Accordingly, both the second wiring lower surface 63AR and the second wiring side surface 63AA are formed by the seed layer 63AB. The second wiring upper surface 63AS is formed by the plating layer 63AC. In one example, the seed layer 63AB has the same configuration as the seed layer 45B shown in FIG. 14, and the plating layer 63AC has the same configuration as the plating layer 46B shown in FIG. 14.

As shown in FIG. 25, the second layer wiring 63A includes a second wiring corner portion 63AD between the second wiring side surface 63AA and the second wiring upper surface 63AS. A fourth recess 63AE is provided in the second wiring corner portion 63AD. The fourth recess 63AE includes a fourth curved surface 63AP. The fourth recess 63AE is recessed in a manner convex inwardly toward the inside of the second layer wiring 63A. The cross-sectional shape of the fourth curved surface 63AP, as shown in FIG. 25, is arcuate. The fourth recess 63AE is arcuate centered at a fourth curvature center C4, which is the intersection point of a seventh virtual line L7 extending along the second wiring upper surface 63AS and an eighth virtual line L8 extending along the second wiring side surface 63AA. The fourth curvature center C4 is located outside the second layer wiring 63A. The fourth recess 63AE extends across both the seed layer 63AB and the plating layer 63AC. In one example, the fourth recess 63AE is provided around the entire periphery of the second layer wiring 63A in plan view.

The arc length of the cross-sectional shape of the fourth curved surface 63AP is equal to the arc length of the cross-sectional shape of the second curved surface 44P of the second recess 44 shown in FIG. 14. The radius of curvature of the fourth curved surface 63AP is also equal to the radius of curvature of the second curved surface 44P. The arc length of the fourth curved surface 63AP is also equal to the arc length of the third curved surface 62AP of the third recess 62AE shown in FIG. 24. The radius of curvature of the fourth curved surface 63AP is also equal to that of the third curved surface 62AP. The radius of curvature of the fourth curved surface 63AP is, for example, 1 μm.

The thick insulating layer 85A of the insulating layer 857 includes a fourth exposed surface 85AD that is exposed from the second wiring side surface 63AA of the second layer wiring 63A due to the fourth recess 63AE. The fourth exposed surface 85AD is the portion between the upper end edge of the second wiring side surface 63AA and the upper surface 857S of the insulating layer 857 on the side surface 857B of the insulating layer 857. The fourth exposed surface 85AD faces the fourth curved surface 63AP of the fourth recess 63AE in a direction orthogonal to the Z-direction. In one example, the length of the fourth exposed surface 85AD is equal to the radius of curvature of the fourth curved surface 63AP. Here, the length of the fourth exposed surface 85AD can be defined as the distance between the upper end edge of the second wiring side surface 63AA and the upper surface 857S of the insulating layer 857.

The second layer wiring 63A is covered by the thin insulating layer 85B of the topmost insulating layer 85U. The portion of the thin insulating layer 85B of the topmost insulating layer 85U corresponding to the second layer wiring 63A includes a fourth upper surface portion 85FA, a fourth side surface portion 85FB, a fourth curved portion 85FC, and a second wiring upper surface portion 85FD. The fourth upper surface portion 85FA, the fourth side surface portion 85FB, the fourth curved portion 85FC, and the second wiring upper surface portion 85FD are integrated. The fourth upper surface portion 85FA covers the upper surface 857S of the insulating layer 857. The fourth upper surface portion 85FA is in contact with the upper surface 857S of the insulating layer 857. The fourth upper surface portion 85FA may be integrated with the second upper surface portion 85DA, for example. The fourth side surface portion 85FB covers the fourth exposed surface 85AD. The fourth side surface portion 85FB is provided along the fourth exposed surface 85AD. The fourth side surface portion 85FB is connected to the fourth upper surface portion 85FA. The fourth side surface portion 85FB is in contact with the fourth exposed surface 85AD. The fourth curved portion 85FC covers the fourth curved surface 63AP. The fourth curved portion 85FC is in contact with the fourth curved surface 63AP along its surface. The fourth curved portion 85FC is connected to the fourth side surface portion 85FB. The second wiring upper surface portion 85FD covers the second wiring upper surface 63AS of the second layer wiring 63A. The second wiring upper surface portion 85FD is in contact with the second wiring upper surface 63AS. The second wiring upper surface portion 85FD is connected to the fourth curved portion 85FC.

The thick insulating layer 85A of the top insulating layer 85U is embedded in the fourth recess 63AE of the second layer wiring 63A. More specifically, the thick insulating layer 85A of the top insulating layer 85U is embedded in a recess space formed by the fourth side portion 85FB and the fourth curved portion 85FC of the thin insulating layer 85B in the top insulating layer 85U. In this manner, it can be said that the fourth recess 63AE is filled with the top insulating layer 85U.

[Method of Manufacturing the Insulating Chip] The method for manufacturing the insulating chip 80, in particular the method for manufacturing the second layer wiring 63A, will be described. The method for manufacturing the second layer wiring 63A includes a step of forming the through-hole 87B. The step of forming the through-hole 87B may be a common step with the step of forming the second groove 86B of the first embodiment. In other words, the second groove 86B and the through-hole 87B may be formed simultaneously.

The method for manufacturing the second layer wiring 63A includes a step of forming a conductive layer 700 (see FIG. 17) such that the conductive layer 700 is embedded in the through-hole 87B. The step of forming the conductive layer 700 in the through-hole 87B may be a common step with the step of embedding the conductive layer 700 in the second groove 86B of the first embodiment. In other words, the conductive layer 700 is simultaneously embedded in both the through-hole 87B and the second groove 86B.

The method for manufacturing the second layer wiring 63A includes steps of thinning the insulating layer 857 and partially removing the conductive layer 700. These steps are common with those of the first embodiment; therefore, the conductive layer 700 embedded in the through-hole 87B and the conductive layer 700 embedded in the second groove 86B are simultaneously partially removed.

The method for manufacturing the second layer wiring 63A includes a step of forming the fourth recess 63AE. Forming the fourth recess 63AE may be a common step with the step of forming the second recess 44 of the first embodiment. In other words, the fourth recess 63AE and the second recess 44 may be formed simultaneously. Through the above steps, the second layer wiring 63A is formed, and in this way, the second layer wiring 63A may be formed simultaneously with the second conductive member 52. Similarly, the first layer wiring 62A may be formed simultaneously with the first conductive member 51.

[Effects of the Second Embodiment] According to the second embodiment, the following effects are obtained. (2-1) The insulating chip 80 includes a first electrode pad 81 electrically connected to the first conductive member 51 and a second electrode pad 82 electrically connected to the second conductive member 52 and a connection wiring 60 provided within the insulator 84 that connects the first conductive member 51 and the first electrode pad 81. The connection wiring 60 includes a first wiring section 61A extending in the Z direction and connected to the first electrode pad 81 and a second wiring section 66A extending outward in plan view from the first conductive member 51 and electrically connected thereto. The first wiring section 61A is provided at the same position in the Z direction as the first conductive member 51, and includes the first layer wiring 62A which is electrically connected to the second wiring section 66A, the second layer wiring 63A provided at the same position in the Z direction as the second conductive member 52, the through-wiring 64A provided between the first layer wiring 62A and the second layer wiring 63A in the Z direction, and the surface-side via wiring 65A connecting the second layer wiring 63A and the first electrode pad 81. The second layer wiring 63A includes the second wiring upper surface 63AS, the second wiring lower surface 63AR opposite to the second wiring upper surface 63AS, and the second wiring side surface 63AA connecting the second wiring upper surface 63AS and the second wiring lower surface 63AR. The second wiring corner portion 63AD, provided between the second wiring upper surface 63AS and the second wiring side surface 63AA, is provided with a fourth recess 63AE including a fourth curved surface 63AP recessed so as to be convex inwardly.

According to this structure, because the fourth recess 63AE prevents the formation of an edge at the second wiring corner portion 63AD of the second layer wiring 63A, electric field concentration at the second wiring corner portion 63AD can be mitigated, and therefore the reduction in breakdown voltage of the insulating chip 80 caused by such electric field concentration can be suppressed.

Additionally, since the fourth recess 63AE forms a reverse tapered shape from the second wiring upper surface 63AS toward the second wiring side surface 63AA, the stress generated in the fourth recess 63AE is applied inwardly to the second layer wiring 63A. In other words, stress is less likely to be applied from the fourth recess 63AE to the insulating layer 85. Therefore, the occurrence of cracks in the insulating layer 85 can be suppressed.

(2-2) The cross-sectional shape of the fourth curved surface 63AP is arcuate. According to this structure, since the fourth recess 63AE forms a reverse tapered curved shape from the second wiring upper surface 63AS toward the second wiring side surface 63AA, the stress generated in the fourth recess 63AE is applied inwardly to the second layer wiring 63A. In other words, stress is less likely to be applied from the fourth recess 63AE to the insulating layer 85. Therefore, the occurrence of cracks in the insulating layer 85 can be suppressed.

(2-3) The second layer wiring 63A is tapered such that the second wiring side surface 63AA is inclined inwardly from the second wiring upper surface 63AS toward the second wiring lower surface 63AR. According to this structure, when the second wiring side surface 63AA is inclined and directly connected to the second wiring upper surface 63AS, an edge tends to be formed at the second wiring corner portion 63AD. However, since the fourth recess 63AE is provided in the second wiring corner portion 63AD, no edge is formed, and even if the second layer wiring 63A is tapered, concentration of electric fields at the second wiring corner portion 63AD can be alleviated.

(2-4) The first layer wiring 62A includes a first wiring upper surface 62AS, a first wiring lower surface 62AR opposite to the first wiring upper surface 62AS, a first wiring side surface 62AA provided between the first wiring upper surface 62AS and the first wiring lower surface 62AR in the Z direction, and a first wiring corner portion 62AD between the first wiring side surface 62AA and the first wiring upper surface 62AS. The first wiring corner portion 62AD is provided with a third recess 62AE including a third curved surface 62AP that is recessed in a convex manner toward the interior of the first layer wiring 62A.

According to this structure, since the third recess 62AE eliminates the formation of an edge in the first wiring corner portion 62AD of the first layer wiring 62A, the electric field concentration at the first wiring corner portion 62AD can be alleviated. Therefore, a reduction in the withstand voltage of the insulating chip 80 due to electric field concentration at the first wiring corner portion 62AD can be suppressed.

Additionally, since the third recess 62AE forms a reverse tapered shape from the first wiring upper surface 62AS toward the first wiring side surface 62AA, the stress generated in the third recess 62AE is applied inwardly to the first layer wiring 62A. In other words, stress is less likely to be applied from the third recess 62AE to the insulating layer 85. Therefore, the occurrence of cracks in the insulating layer 85 can be suppressed.

(2-5) The cross-sectional shape of the third curved surface 62AP is arcuate. According to this structure, since the third recess 62AE forms a reverse tapered curved shape from the first wiring upper surface 62AS toward the first wiring side surface 62AA, the stress generated in the third recess 62AE is applied inwardly to the first layer wiring 62A. In other words, stress is less likely to be applied from the third recess 62AE to the insulating layer 85. Therefore, the occurrence of cracks in the insulating layer 85 can be suppressed.

(2-6) The first layer wiring 62A is tapered such that the first wiring side surface 62AA is inclined inwardly from the first wiring upper surface 62AS toward the first wiring lower surface 62AR. According to this structure, when the first wiring side surface 62AA is inclined and directly connected to the first wiring upper surface 62AS, an edge tends to be formed at the first wiring corner portion 62AD. However, since the third recess 62AE is provided in the first wiring corner portion 62AD, no edge is formed, and even if the first layer wiring 62A is tapered, concentration of electric fields at the first wiring corner portion 62AD can be alleviated.

### Third Embodiment

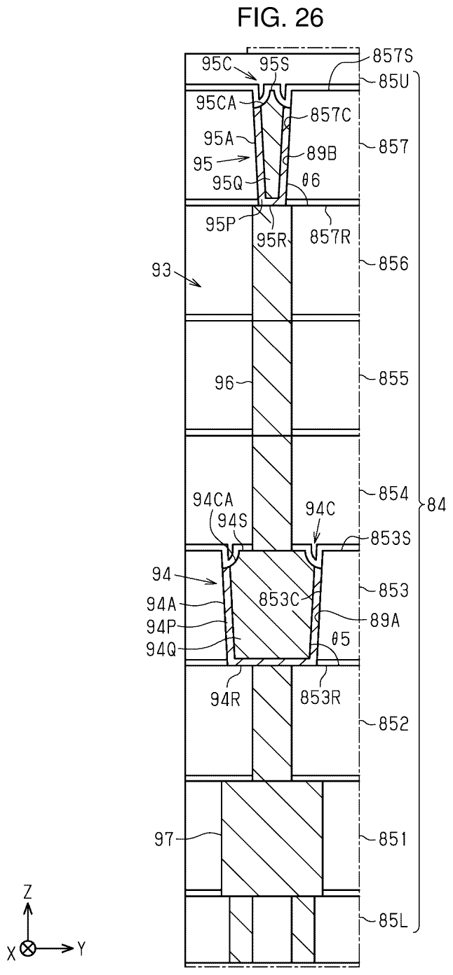

A third embodiment of the insulation chip 80 will be described with reference to FIGS. 26 to 28. In the insulation chip 80 of the third embodiment, the structure of the sealing portion 93 is mainly different from that of the first embodiment. In the following, the components common to the first embodiment are denoted by the same reference numerals, and their explanation will be omitted.

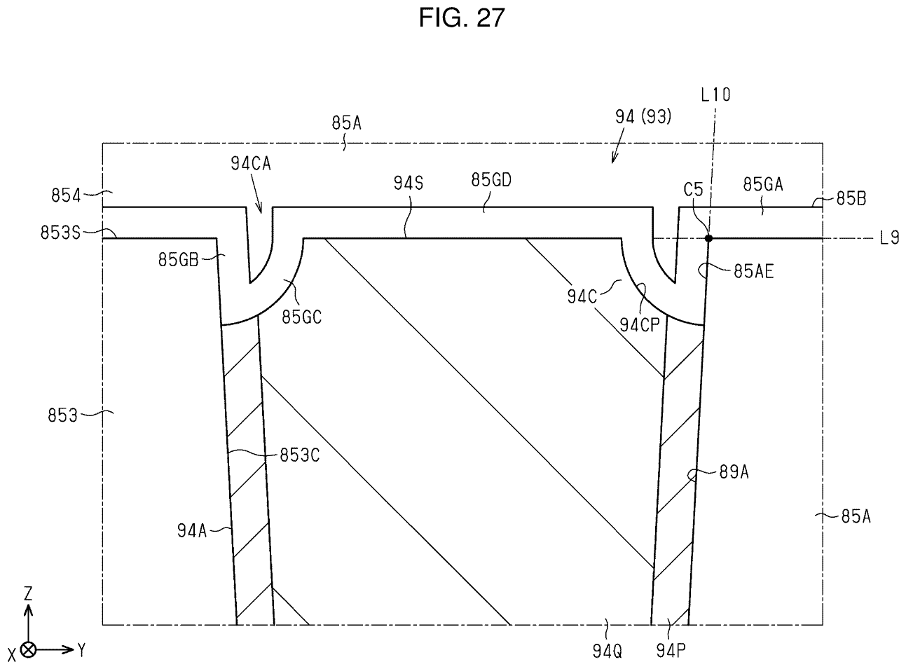

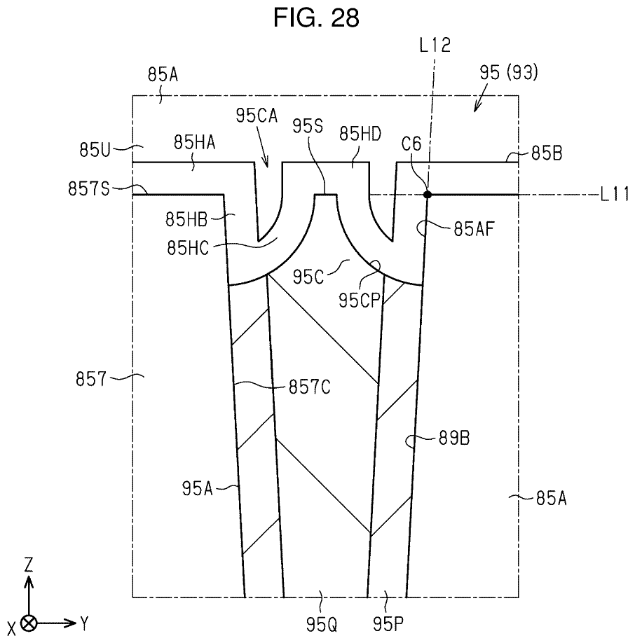

FIG. 26 is an enlarged cross-sectional view showing part of the sealing portion 93. FIG. 27 is an enlarged cross-sectional view showing part of the first sealing portion 94, which will be described later, of the sealing portion 93. FIG. 28 is an enlarged cross-sectional view showing part of the second sealing portion 95, which will be described later, of the sealing portion 93.

As shown in FIG. 26, the sealing portion 93 includes a first sealing portion 94, a second sealing portion 95, a first connection sealing portion 96, and a second connection sealing portion 97. The first sealing portion 94 is disposed at the same position in the Z direction as the first conductor 51 (see FIG. 8). That is, the first sealing portion 94 is provided in the insulating layer 853. The second sealing portion 95 is disposed at the same position in the Z direction as the second conductor 52 (see FIG. 8). That is, the second sealing portion 95 is provided in the insulating layer 857. The first connection sealing portion 96 is provided between the first sealing portion 94 and the second sealing portion 95 in the Z direction. The first connection sealing portion 96 connects the first sealing portion 94 and the second sealing portion 95. The first connection sealing portion 96 penetrates the insulating layers 854 to 856 in the Z direction. The second connection sealing portion 97 connects the first sealing portion 94 and the substrate 83 (see FIG. 8). The detailed structure of the first sealing portion 94 and the second sealing portion 95 will be described below.

[First Sealing Portion] As shown in FIGS. 26 and 27, a through-hole 89A is provided in the insulating layer 853. The first sealing portion 94 is embedded in the through-hole 89A.

Since the through-hole 89A penetrates the insulating layer 853 in the Z direction, it exposes the thick insulating layer 85A of the insulating layer 852. Therefore, the first sealing portion 94 embedded in the through-hole 89A is in contact with the thick insulating layer 85A of the insulating layer 852. In one example, the through-hole 89A is tapered, narrowing from the upper surface 853S to the lower surface 853R of the insulating layer 853. The angle θ5 of the side surface 853C of the insulating layer 853, which constitutes the through-hole 89A, is 80° or more and 90° or less. In one example, the angle θ5 is 85°. Here, the angle θ5 can be defined as the angle between the lower surface 853R and the side surface 853C of the insulating layer 853.

The first sealing portion 94 is, for example, rectangular in plan view. The first sealing portion 94 includes a first sealing upper surface 94S, a first sealing lower surface 94R, and a first sealing side surface 94A. The first sealing upper surface 94S is disposed closer to the insulating upper surface 84S of the insulator 84. The first sealing lower surface 94R constitutes a surface opposite to the first sealing upper surface 94S. The first sealing lower surface 94R is disposed closer to the insulating lower surface 84R of the insulator 84. The first sealing side surface 94A is provided between the first sealing upper surface 94S and the first sealing lower surface 94R in the Z direction.

In the third embodiment, the first sealing upper surface 94S is disposed at the same position in the Z direction as the upper surface 853S of the insulating layer 853. Note that the position of the first sealing upper surface 94S in the Z direction can be changed arbitrarily. In one example, the first sealing upper surface 94S may be disposed closer to the lower surface 853R of the insulating layer 853 than the upper surface 853S in the Z direction. The first sealing portion 94 embedded in the through-hole 89A is tapered such that the first sealing side surface 94A narrows from the first sealing upper surface 94S toward the first sealing lower surface 94R. In other words, the opposing first sealing side surfaces 94A are inclined toward each other from the first sealing upper surface 94S toward the first sealing lower surface 94R.

The first sealing portion 94 includes a seed layer 94P and a plating layer 94Q provided on the seed layer 94P. The seed layer 94P is provided on the side surface (side surface 853C of the insulating layer 853) that constitutes the through-hole 89A, and on the upper surface of the insulating layer 852 exposed by the through-hole 89A. Therefore, both the first sealing lower surface 94R and the first sealing side surface 94A are formed by the seed layer 94P. The first sealing upper surface 94S is formed by the plating layer 94Q. In one example, the seed layer 94P has the same structure as the seed layer 45A shown in FIG. 11, and the plating layer 94Q has the same structure as the plating layer 46A shown in FIG. 11.

As shown in FIG. 27, the first sealing portion 94 includes a first sealing corner portion 94C between the first sealing side surface 94A and the first sealing upper surface 94S. A fifth recessed portion 94CA is provided in the first sealing corner portion 94C. The fifth recessed portion 94CA includes a fifth curved surface 94CP. The fifth recessed portion 94CA is recessed so as to be convex toward the inside of the first sealing portion 94. In the cross-sectional view shown in FIG. 27, the cross-sectional shape of the fifth curved surface 94CP is arcuate. The fifth recessed portion 94CA is arcuate with the fifth curvature center C5, which is the intersection of the ninth virtual line L9 along the first sealing upper surface 94S and the tenth virtual line L10 along the first sealing side surface 94A, as the center. The fifth curvature center C5 is located outside the first sealing portion 94. The fifth recessed portion 94CA is formed across both the seed layer 94P and the plating layer 94Q. In one example, the fifth recessed portion 94CA is provided over the entire periphery of the first sealing portion 94 in plan view.

The arc length of the cross-sectional shape of the fifth curved surface 94CP is equal to the arc length of the cross-sectional shape of the first curved surface 43P of the first recessed portion 43 shown in FIG. 11. The radius of curvature of the fifth curved surface 94CP may also be equal to the radius of curvature of the first curved surface 43P. The arc length of the cross-sectional shape of the fifth curved surface 94CP is equal to the arc length of the cross-sectional shape of the second curved surface 44P of the second recessed portion 44 shown in FIG. 14. The radius of curvature of the fifth curved surface 94CP may also be equal to the radius of curvature of the second curved surface 44P. The radius of curvature of the fifth curved surface 94CP is, for example, 1 μm.

The thick insulating layer 85A of the insulating layer 853 includes a fifth exposed side surface 85AE that is exposed from the first sealing side surface 94A of the first sealing portion 94 by the fifth recessed portion 94CA. The fifth exposed side surface 85AE is the portion of the side surface 853C of the insulating layer 853 between the upper end edge of the first sealing side surface 94A and the upper surface 853S of the insulating layer 853. The fifth exposed side surface 85AE faces the fifth curved surface 94CP of the fifth recessed portion 94CA in a direction orthogonal to the Z direction. In one example, the length of the fifth exposed side surface 85AE is equal to the radius of curvature of the fifth curved surface 94CP. Here, the length of the fifth exposed side surface 85AE can be defined as the distance between the upper end edge of the first sealing side surface 94A and the upper surface 853S of the insulating layer 853.

The first sealing portion 94 is covered with the thin insulating layer 85B of the insulating layer 854. The portion of the thin insulating layer 85B of the insulating layer 854 corresponding to the first sealing portion 94 includes a fifth upper surface portion 85GA, a fifth side surface portion 85GB, a fifth curved portion 85GC, and a first sealing upper surface portion 85GD. The fifth upper surface portion 85GA, the fifth side surface portion 85GB, the fifth curved portion 85GC, and the first sealing upper surface portion 85GD are integrated. The fifth upper surface portion 85GA covers the upper surface 853S of the insulating layer 853. The fifth upper surface portion 85GA is in contact with the upper surface 853S of the insulating layer 853. The fifth upper surface portion 85GA may also be integrated with the third upper surface portion 85EA (see FIG. 24). The fifth side surface portion 85GB covers the fifth exposed side surface 85AE. The fifth side surface portion 85GB is provided along the fifth exposed side surface 85AE. The fifth side surface portion 85GB is connected to the fifth upper surface portion 85GA. The fifth curved portion 85GC covers the fifth curved surface 94CP. The fifth curved portion 85GC is in contact with and follows the fifth curved surface 94CP. The fifth curved portion 85GC is connected to the fifth side surface portion 85GB. The first sealing upper surface portion 85GD covers the first sealing upper surface 94S of the first sealing portion 94. The first sealing upper surface portion 85GD is in contact with the first sealing upper surface 94S and is connected to the fifth curved portion 85GC.

The thick insulating layer 85A of the insulating layer 854 is embedded in the fifth recessed portion 94CA. More specifically, the thick insulating layer 85A of the insulating layer 854 is embedded in a recess space formed by the fifth side surface portion 85GB and the fifth curved portion 85GC of the thin insulating layer 85B of the insulating layer 854. In this manner, it can be said that the insulating layer 854 is embedded in the fifth recessed portion 94CA.

### [Second Sealing Portion]

As shown in FIGS. 26 and 28, a through-hole 89B is provided in the insulating layer 857. The second sealing portion 95 is embedded in the through-hole 89B.

Since the through-hole 89B penetrates the insulating layer 857 in the Z direction, it exposes the thick insulating layer 85A of the insulating layer 856. Therefore, the second sealing portion 95 embedded in the through-hole 89B is in contact with the thick insulating layer 85A of the insulating layer 856. In one example, the through-hole 89B is tapered, narrowing from the upper surface 857S to the lower surface 857R of the insulating layer 857. The angle θ6 of the side surface 857C of the insulating layer 857 forming the through-hole 89B is between 80° and 90°. In one example, the angle θ6 is 85°. Here, the angle θ6 can be defined as the angle between the lower surface 857R and the side surface 857C of the insulating layer 857.

The second sealing portion 95 has a rectangular frame shape in plan view, for example. The width of the second sealing portion 95 is smaller than the width of the first sealing portion 94. Here, the width of the second sealing portion 95 refers to the dimension in the direction orthogonal to the direction in which the second sealing portion 95 extends in plan view. The width of the first sealing portion 94 refers to the dimension in the direction orthogonal to the direction in which the first sealing portion 94 extends in plan view.

The second sealing portion 95 includes a second sealing upper surface 95S, a second sealing lower surface 95R, and a second sealing side surface 95A. The second sealing upper surface 95S is positioned closer to the insulating upper surface 84S of the insulating body 84 within the second sealing portion 95. The second sealing lower surface 95R forms the surface opposite to the second sealing upper surface 95S. The second sealing lower surface 95R is located nearer the insulating lower surface 84R of the insulating body 84. The second sealing side surface 95A is provided between the second sealing upper surface 95S and the second sealing lower surface 95R in the Z direction.

In the third embodiment, the second sealing upper surface 95S is positioned at the same level in the Z direction as the upper surface 857S of the insulating layer 857. Note that the position of the second sealing upper surface 95S in the Z direction can be arbitrarily changed. In one example, the second sealing upper surface 95S may be positioned closer to the lower surface 857R of the insulating layer 857 than the upper surface 857S in the Z direction. The second sealing portion 95 embedded in the through-hole 89B has a tapered shape in which the second sealing side surface 95A narrows from the second sealing upper surface 95S to the second sealing lower surface 95R. In other words, the opposing second sealing side surfaces 95A incline toward each other from the second sealing upper surface 95S to the second sealing lower surface 95R.

The second sealing portion 95 includes a seed layer 95P and a plating layer 95Q formed on the seed layer 95P. The seed layer 95P is provided on the side surface (side surface 857C of the insulating layer 857) forming the through-hole 89B and on the upper surface of the insulating layer 856 exposed by the through-hole 89B. Therefore, both the second sealing lower surface 95R and the second sealing side surface 95A are formed by the seed layer 95P. The second sealing upper surface 95S is formed by the plating layer 95Q. In one example, the seed layer 95P has the same configuration as the seed layer 45B shown in FIG. 13, and the plating layer 95Q has the same configuration as the plating layer 46B shown in FIG. 13.

As shown in FIG. 28, the second sealing portion 95 includes a second sealing corner portion 95C located between the second sealing side surface 95A and the second sealing upper surface 95S. The second sealing corner portion 95C is provided with a sixth recessed portion 95CA. The sixth recessed portion 95CA includes a sixth curved surface 95CP. The sixth recessed portion 95CA is recessed such that it protrudes inward of the second sealing portion 95. In the cross-sectional view shown in FIG. 28, the cross-sectional shape of the sixth curved surface 95CP is arcuate. The sixth recessed portion 95CA has an arcuate shape centered at the sixth curvature center C6, which is the intersection point of the eleventh virtual line L11 along the second sealing upper surface 95S and the twelfth virtual line L12 along the second sealing side surface 95A. The sixth curvature center C6 is located outside the second sealing portion 95. The sixth recessed portion 95CA extends over both the seed layer 95P and the plating layer 95Q. In one example, the sixth recessed portion 95CA is provided over the entire periphery of the second sealing portion 95 in plan view.

In one example, the arc length of the cross-sectional shape of the sixth curved surface 95CP is equal to the arc length of the cross-sectional shape of the fifth curved surface 94CP shown in FIG. 27. The radius of curvature of the sixth curved surface 95CP is also considered to be equal to that of the fifth curved surface 94CP. Additionally, the arc length of the sixth curved surface 95CP is equal to that of the second curved surface 44P in the second recessed portion 44 shown in FIG. 14. The radius of curvature of the sixth curved surface 95CP is also considered equal to that of the second curved surface 44P. The radius of curvature of the sixth curved surface 95CP is, for example, 1 μm.

The thick insulating layer 85A of the insulating layer 857 includes a sixth exposed side surface 85AF, which is exposed from the second sealing side surface 95A due to the sixth recessed portion 95CA. The sixth exposed side surface 85AF is the portion between the upper edge of the second sealing side surface 95A and the upper surface 857S of the insulating layer 857, on the side surface 857C of the insulating layer 857. The sixth exposed side surface 85AF faces the sixth curved surface 95CP of the sixth recessed portion 95CA in a direction orthogonal to the Z direction. In one example, the length of the sixth exposed side surface 85AF is equal to the radius of curvature of the sixth curved surface 95CP. Here, the length of the sixth exposed side surface 85AF can be defined as the distance between the upper edge of the second sealing side surface 95A and the upper surface 857S of the insulating layer 857.

The second sealing portion 95 is covered by the thin insulating layer 85B of the topmost insulating layer 85U. The portion of the thin insulating layer 85B of the topmost insulating layer 85U corresponding to the second sealing portion 95 includes a sixth upper surface portion 85HA, a sixth side surface portion 85HB, a sixth curved portion 85HC, and a second sealing upper surface portion 85HD. The sixth upper surface portion 85HA, sixth side surface portion 85HB, sixth curved portion 85HC, and second sealing upper surface portion 85HD are integrated. The sixth upper surface portion 85HA covers the upper surface 857S of the insulating layer 857 and is in contact with it. The sixth upper surface portion 85HA may also be integrated with, for example, the fourth upper surface portion 85FA (see FIG. 25). The sixth side surface portion 85HB covers the sixth exposed side surface 85AF and is provided along it, being in contact with it and connected to the sixth upper surface portion 85HA. The sixth curved portion 85HC covers the sixth curved surface 95CP and is in contact with it along its shape, and connected to the sixth side surface portion 85HB. The second sealing upper surface portion 85HD covers the second sealing upper surface 95S of the second sealing portion 95, is in contact with it, and is connected to the sixth curved portion 85HC.

The thick insulating layer 85A of the topmost insulating layer 85U is embedded in the sixth recessed portion 95CA. More specifically, the thick insulating layer 85A of the topmost insulating layer 85U is embedded in a recessed space formed by the sixth side surface portion 85HB and the sixth curved portion 85HC of the thin insulating layer 85B of the topmost insulating layer 85U. In this manner, it can be said that the topmost insulating layer 85U is embedded in the sixth recessed portion 95CA.

### [First Connection Sealing Portion and Second Connection Sealing Portion]

As shown in FIG. 26, the first connection sealing portion 96 is formed by a laminated structure of vias provided in each of the insulating layers 854 to 856. Although not illustrated, each via of the first connection sealing portion 96 is configured with a seed layer and a plating layer, similar to the first sealing portion 94 and the second sealing portion 95.

The second connection sealing portion 97 is formed by a laminated structure of vias and layer wiring provided in each of the lowermost insulating layer 85 and the insulating layers 851 and 852. Vias are provided in the lowermost insulating layer 85 and the insulating layer 852. Layer wiring is provided in the insulating layer 851. Although not illustrated, each of the plurality of vias and layer wiring of the second connection sealing portion 97 is configured with a seed layer and a plating layer, similar to the first sealing portion 94 and the second sealing portion 95.

### [Manufacturing Method of the Chip Insulating Layer]

A method for manufacturing the second sealing portion 95 of the insulating chip 80 will be described. The manufacturing method of the second sealing portion 95 includes forming the through-hole 89B. The step of forming the through-hole 89B may be the same step as forming the second groove 86B of the first embodiment. That is, the second groove 86B and the through-hole 89B may be formed simultaneously.

The manufacturing method of the second sealing portion 95 includes forming a conductive layer 700 (see FIG. 17) to fill the through-hole 89B. The step of forming the conductive layer 700 in the through-hole 89B may be the same step as the one forming the conductive layer 700 in the second groove 86B in the first embodiment. That is, the conductive layer 700 may be embedded in the through-hole 89B and the second groove 86B at the same time.

The manufacturing method of the second sealing portion 95 includes thinning the insulating layer 857 and partially removing the conductive layer 700. These steps are common to those in the first embodiment. Therefore, the conductive layer 700 embedded in the through-hole 89B and the conductive layer 700 embedded in the second groove 86B are partially removed simultaneously.

The manufacturing method of the second sealing portion 95 includes forming the sixth recessed portion 95CA. The formation of the sixth recessed portion 95CA may be the same step as forming the second recessed portion 44 of the first embodiment. That is, the sixth recessed portion 95CA and the second recessed portion 44 may be formed simultaneously. Through the above steps, the second sealing portion 95 is formed. In this way, the second sealing portion 95 may be formed simultaneously with the second conductor 52. Similarly, the first sealing portion 94 may also be formed simultaneously with the first conductor 51.

### Effect of the Third Embodiment

According to the third embodiment, the following effects are obtained.

(3-1) The insulating chip 80 includes a sealing portion 93 provided at the outer peripheral portion of the insulator 84 and surrounding the first conductor 51 and the second conductor 52 in plan view. The sealing portion 93 includes a first sealing portion 94 provided at the same position as the first conductor 51 in the Z direction, a second sealing portion 95 provided at the same position as the second conductor 52 in the Z direction, and a first connection sealing portion 96 connecting the first sealing portion 94 and the second sealing portion 95 in the Z direction. The second sealing portion 95 includes a second sealing upper surface 95S, a second sealing lower surface 95R on the opposite side of the second sealing upper surface 95S, a second sealing side surface 95A connecting the second sealing upper surface 95S and the second sealing lower surface 95R, and a second sealing corner portion 95C located between the second sealing side surface 95A and the second sealing upper surface 95S. The second sealing corner portion 95C is provided with a sixth recessed portion 95CA including a sixth curved surface 95CP, recessed so as to protrude inward of the second sealing portion 95.

According to this configuration, since an edge is not formed at the second sealing corner portion 95C of the second sealing portion 95 due to the sixth recessed portion 95CA, it is possible to alleviate the electric field concentration at the second sealing corner portion 95C. Accordingly, it is possible to suppress a decrease in the breakdown voltage of the insulating chip 80 caused by the electric field concentration at the second sealing corner portion 95C.

In addition, since a reverse taper shape is formed from the second sealing upper surface 95S toward the second sealing side surface 95A due to the sixth recessed portion 95CA, the stress generated at the sixth recessed portion 95CA is applied inwardly of the second sealing portion 95. That is, stress is less likely to be applied from the sixth recessed portion 95CA to the insulating layer 85. Accordingly, it is possible to suppress the occurrence of cracks in the insulating layer 85.

(3-2) The cross-sectional shape of the sixth curved surface 95CP is arc-shaped.

According to this configuration, since a reverse-tapered curved shape is formed from the second sealing upper surface 95S toward the second sealing side surface 95A due to the sixth recessed portion 95CA, the stress generated at the sixth recessed portion 95CA is applied inwardly of the second sealing portion 95. That is, stress is less likely to be applied from the sixth recessed portion 95CA to the insulating layer 85. Accordingly, it is possible to suppress the occurrence of cracks in the insulating layer 85.

(3-3) The second sealing portion 95 is tapered such that the second sealing side surface 95A is inclined to become narrower from the second sealing upper surface 95S toward the second sealing lower surface 95R.

According to this configuration, when the second sealing side surface 95A is inclined, an edge is likely to be formed at the second sealing corner portion 95C in the case where the second sealing side surface 95A and the second sealing upper surface 95S are directly connected. In this respect, since the sixth recessed portion 95CA is provided in the second sealing corner portion 95C, an edge is not formed. Therefore, even if the second sealing portion 95 is tapered, it is possible to alleviate the electric field concentration at the second sealing corner portion 95C.

(3-4) The first sealing portion 94 includes a first sealing upper surface 94S, a first sealing lower surface 94R on the opposite side of the first sealing upper surface 94S, a first sealing side surface 94A provided between the first sealing upper surface 94S and the first sealing lower surface 94R in the Z-direction, and a first sealing corner portion 94C between the first sealing side surface 94A and the first sealing upper surface 94S. The first sealing corner portion 94C is provided with a fifth recessed portion 94CA including a fifth curved surface 94CP recessed so as to be convex inward of the first sealing portion 94.

According to this configuration, since an edge is not formed at the first sealing corner portion 94C of the first sealing portion 94 due to the fifth recessed portion 94CA, it is possible to alleviate the electric field concentration at the first sealing corner portion 94C. Accordingly, it is possible to suppress a decrease in the breakdown voltage of the insulating chip 80 caused by the electric field concentration at the first sealing corner portion 94C.

In addition, since a reverse taper shape is formed from the first sealing upper surface 94S toward the first sealing side surface 94A due to the fifth recessed portion 94CA, the stress generated at the fifth recessed portion 94CA is applied inwardly of the first sealing portion 94. That is, stress is less likely to be applied from the fifth recessed portion 94CA to the insulating layer 85. Accordingly, it is possible to suppress the occurrence of cracks in the insulating layer 85.

(3-5) The cross-sectional shape of the fifth curved surface 94CP is arc-shaped.

According to this configuration, since a reverse-tapered curved shape is formed from the first sealing upper surface 94S toward the first sealing side surface 94A due to the fifth recessed portion 94CA, the stress generated at the fifth recessed portion 94CA is applied inwardly of the first sealing portion 94. That is, stress is less likely to be applied from the fifth recessed portion 94CA to the insulating layer 85. Accordingly, it is possible to suppress the occurrence of cracks in the insulating layer 85.

(3-6) The first sealing portion 94 is tapered such that the first sealing side surface 94A inclines to become narrower from the first sealing upper surface 94S toward the first sealing lower surface 94R. According to this configuration, since an edge is likely to be formed at the first sealing corner portion 94C if the first sealing side surface 94A and the first sealing upper surface 94S are directly connected due to the inclination of the first sealing side surface 94A, the provision of the fifth recessed portion 94CA at the first sealing corner portion 94C prevents the formation of such an edge. Therefore, even if the first sealing portion 94 is tapered, the electric field concentration at the first sealing corner portion 94C can be alleviated.

### Fourth Embodiment

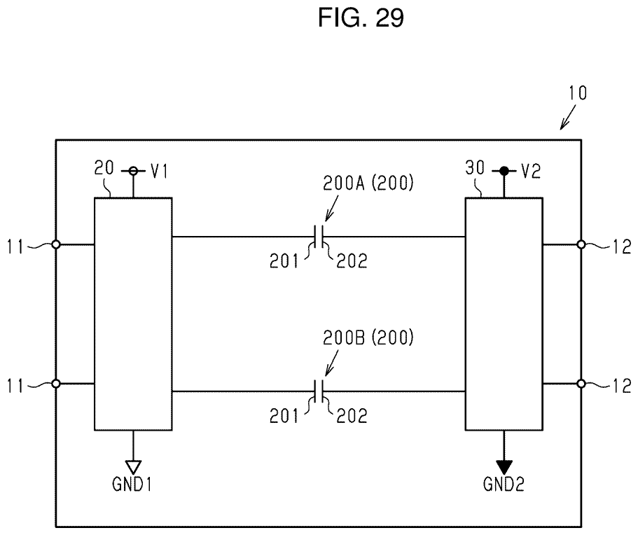

The fourth embodiment of the insulating chip 80 and the signal transmission device 10 will be described with reference to FIGS. 29 to 33. In the insulating chip 80 and the signal transmission device 10 of the fourth embodiment, the configurations of the first conductor 51 and the second conductor 52 of the insulating chip 80 mainly differ from those of the insulating chip 80 and the signal transmission device 10 of the first embodiment. Hereinafter, the same reference numerals are given to components common to the first embodiment, and a description thereof will be omitted.

[Configuration of the Signal Transmission Device] FIG. 29 schematically shows an example of the circuit configuration of the signal transmission device 10. The signal transmission device 10 includes a capacitor 200 instead of the transformers 40A and 40B shown in FIG. 1.

As shown in FIG. 29, the signal transmission device 10 includes a capacitor 200 connected between a first circuit 20 and a second circuit 30. The signal transmission device 10 includes two capacitors 200 corresponding to two signals transmitted between the first circuit 20 and the second circuit 30. When distinguishing between the two capacitors 200, they are referred to as the first capacitor 200A and the second capacitor 200B.

The first circuit 20 and the second circuit 30 are connected via the first capacitor 200A and the second capacitor 200B. The signal transmission device 10 is configured to transmit signals between the first circuit 20 and the second circuit 30 through the first capacitor 200A and the second capacitor 200B.

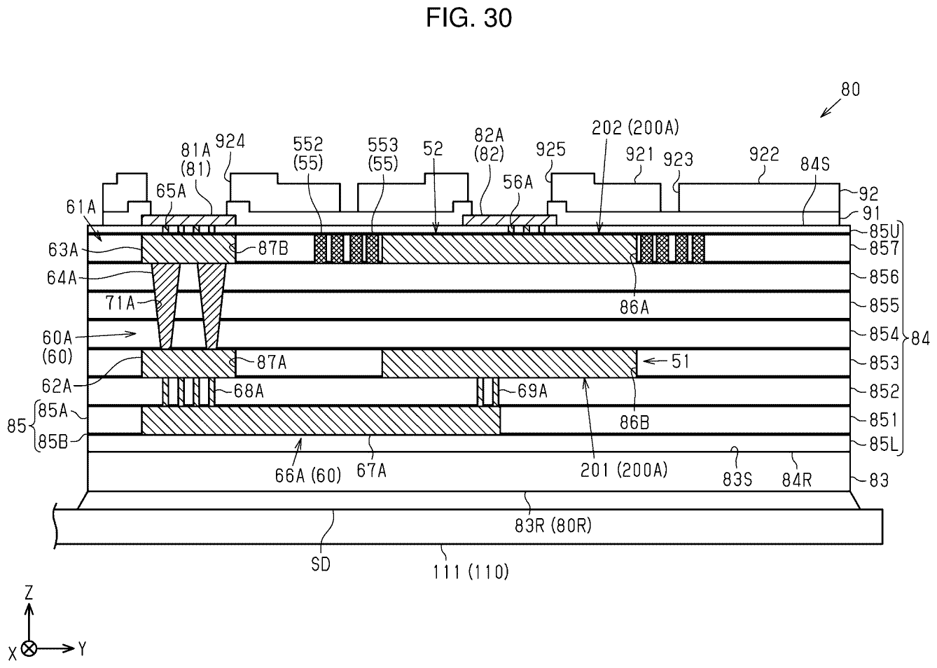

Both the first capacitor 200A and the second capacitor 200B include a first electrode plate 201 and a second electrode plate 202. The first electrode plate 201 is electrically connected to the first circuit 20. The second electrode plate 202 is electrically connected to the second circuit 30.

[Configuration of the Insulating Chip] FIG. 30 schematically shows a cross-sectional structure of the insulating chip 80 of the fourth embodiment. In the insulating chip 80 of the fourth embodiment, the main difference from the insulating chip 80 of the first embodiment is that the first coil 41 and the second coil 42 of the transformers 40A and 40B are replaced by the first electrode plate 201 and the second electrode plate 202.

The insulating chip 80 shown in FIG. 30 can be used in place of the insulating chip 80 shown in FIGS. 2 and 3. Therefore, the signal transmission device 10 including the insulating chip 80 of the fourth embodiment is configured to include the first circuit chip 160 and the second circuit chip 170 shown in FIG. 2.

As shown in FIG. 30, the first conductor 51 of the insulating chip 80 includes the first electrode plate 201. The second conductor 52 of the insulating chip 80 includes the second electrode plate 202. Each of the first electrode plate 201 and the second electrode plate 202 is made of a material that includes one or more of Ti, TiN, Au, Ag, Cu, Al, and W, appropriately selected. In one example, the first electrode plate 201 and the second electrode plate 202 are made of the same material. In another example, the first electrode plate 201 and the second electrode plate 202 may be made of different materials.

Let me know when you're ready for or further assistance.

Both the first electrode plate 201 and the second electrode plate 202 have an oval shape elongated in the X direction in a plan view. In one example, the first electrode plate 201 and the second electrode plate 202 are the same size in a plan view. In another example, the first electrode plate 201 and the second electrode plate 202 may be of different sizes in a plan view. The shapes of the first electrode plate 201 and the second electrode plate 202 in a plan view can be modified arbitrarily.

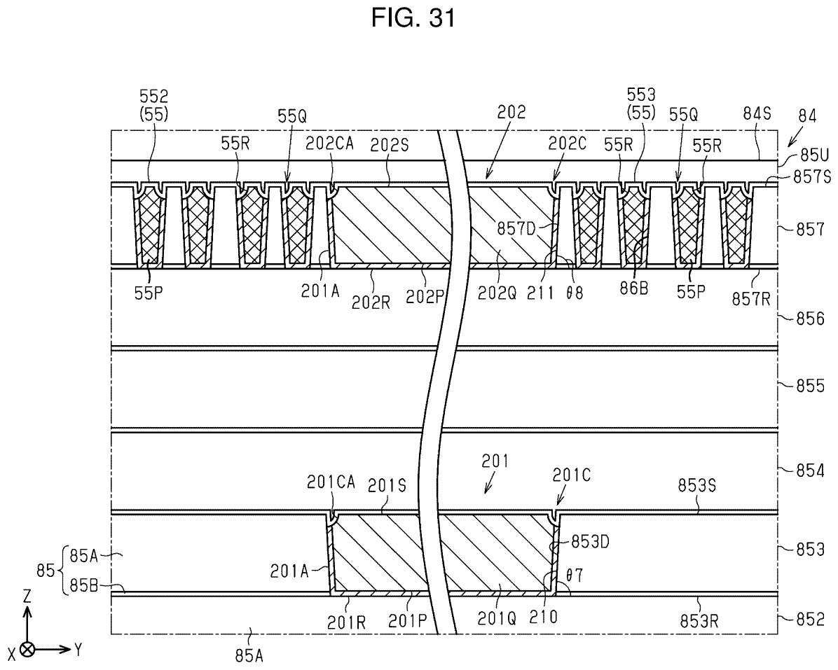

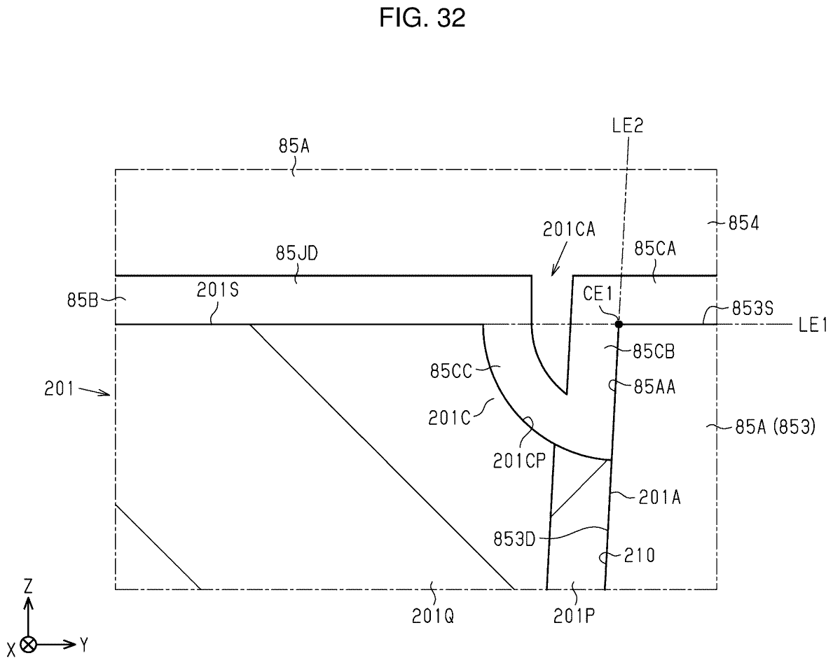

The first electrode plate 201 and the second electrode plate 202 face each other in the Z direction. The first electrode plate 201 is disposed on the insulating lower surface 84R side of the insulator 84. The second electrode plate 202 is disposed on the insulating upper surface 84S side of the insulator 84. A plurality of insulating layers 85 are interposed in the Z direction between the first electrode plate 201 and the second electrode plate 202. The first electrode plate 201 is electrically connected to the first electrode pad 81 by the first connection wiring 60A. Here, the configuration of the first connection wiring 60A in the third embodiment is the same as that of the first connection wiring 60A in the first embodiment. The second electrode plate 202 is electrically connected to the second electrode pad 82 by the via wiring 56A. The detailed configuration of the first electrode plate 201 and the second electrode plate 202 will be described below.

[First Electrode Plate] The configuration of the first electrode plate 201 will be described with reference to FIGS. 31 and 32. FIG. 31 is an enlarged view showing the cross-sectional structure of the first electrode plate 201 and its surroundings shown in FIG. 30. FIG. 32 is an enlarged view showing a portion of the cross-sectional structure of the first electrode plate 201 in FIG. 31.

As shown in FIG. 31, a through-hole 210 is provided in the insulating layer 853. The through-hole 210 is filled with the first electrode plate 201. Since the through-hole 210 penetrates the insulating layer 853 in the Z direction, it exposes the thick insulating layer 85A of the insulating layer 852. Therefore, the first electrode plate 201 embedded in the through-hole 210 is in contact with the thick insulating layer 85A of the insulating layer 852. In one example, the through-hole 210 is tapered, narrowing from the upper surface 853S to the lower surface 853R of the insulating layer 853. The angle θ7 of the side surface 853D of the insulating layer 853 forming the through-hole 210 is 80° or more and 90° or less. In one example, the angle θ7 is 85°. Here, the angle θ7 can be defined as the angle between the lower surface 853R and the side surface 853D of the insulating layer 853.

The first electrode plate 201 includes a first electrode upper surface 201S, a first electrode lower surface 201R, and a first electrode side surface 201A. The first electrode upper surface 201S is disposed on the insulating upper surface 84S side of the insulator 84. The first electrode lower surface 201R is on the opposite side of the first electrode upper surface 201S. The first electrode lower surface 201R is disposed on the insulating lower surface 84R side of the insulator 84. The first electrode side surface 201A is provided in the Z direction between the first electrode upper surface 201S and the first electrode lower surface 201R.

In the fourth embodiment, the first electrode upper surface 201S is disposed at the same position in the Z direction as the upper surface 853S of the insulating layer 853. The position of the first electrode upper surface 201S in the Z direction can be arbitrarily modified. In one example, the first electrode upper surface 201S may be positioned closer to the lower surface 853R of the insulating layer 853 than the upper surface 853S in the Z direction. The first electrode plate 201 embedded in the through-hole 210 has a tapered shape in which the first electrode side surface 201A inclines such that it becomes narrower from the first electrode upper surface 201S toward the first electrode lower surface 201R. That is, the opposing first electrode side surfaces 201A incline toward each other from the first electrode upper surface 201S to the first electrode lower surface 201R.

The first electrode plate 201 includes a seed layer 201P and a plating layer 201Q provided on the seed layer 201P. The seed layer 201P is provided on the side surface (side surface 853D of the insulating layer 853) forming the through-hole 210 and on the upper surface of the insulating layer 852 exposed by the through-hole 210. Therefore, both the first electrode lower surface 201R and the first electrode side surface 201A are formed by the seed layer 201P. The first electrode upper surface 201S is formed by the plating layer 201Q. In one example, the seed layer 201P has the same structure as the seed layer 45A shown in FIG. 11, and the plating layer 201Q has the same structure as the plating layer 46A shown in FIG. 11.

As shown in FIG. 32, the first electrode plate 201 includes a first electrode corner portion 201C located between the first electrode side surface 201A and the first electrode upper surface 201S. A first recess 201CA is provided in the first electrode corner portion 201C. The first recess 201CA includes a first curved surface 201CP. The first recess 201CA is recessed in a manner that protrudes inward of the first electrode plate 201. The cross-sectional shape of the first curved surface 201CP shown in FIG. 32 is arc-shaped. The first recess 201CA is arc-shaped about a first center of curvature CE1, which is the intersection of a first virtual line LE1 along the first electrode upper surface 201S and a second virtual line LE2 along the first electrode side surface 201A. The first center of curvature CE1 is located outside the first electrode plate 201. The first recess 201CA spans both the seed layer 201P and the plating layer 201Q. In one example, the first recess 201CA is provided along the entire periphery of the first electrode plate 201 in a plan view.

The thick insulating layer 85A of the insulating layer 853 includes a first exposed side surface 85AA that is exposed from the first electrode side surface 201A due to the first recess 201CA. The first exposed side surface 85AA is the portion of the side surface 853D of the insulating layer 853 located between the upper edge of the first electrode side surface 201A and the upper surface 853S of the insulating layer 853. The first exposed side surface 85AA faces the first curved surface 201CP of the first recess 201CA in a direction orthogonal to the Z direction. In one example, the length of the first exposed side surface 85AA is equal to the radius of curvature of the first curved surface 201CP. Here, the length of the first exposed side surface 85AA is defined as the distance between the upper edge of the first electrode side surface 201A and the upper surface 853S of the insulating layer 853.

The first electrode plate 201 is covered by the thin insulating layer 85B of the insulating layer 854. The portion of the thin insulating layer 85B of the insulating layer 854 that corresponds to the first electrode plate 201 includes a first upper surface portion 85CA, a first side surface portion 85CB, a first curved portion 85CC, and a first electrode upper surface portion 85JD. The first upper surface portion 85CA, the first side surface portion 85CB, the first curved portion 85CC, and the first electrode upper surface portion 85JD are integrated. The first upper surface portion 85CA covers the upper surface 853S of the insulating layer 853, as in the first embodiment. The first side surface portion 85CB contacts the first exposed side surface 85AA, as in the first embodiment. The first side surface portion 85CB is connected to the first upper surface portion 85CA. The first curved portion 85CC is in contact with and follows the first curved surface 201CP, as in the first embodiment. The first curved portion 85CC is connected to the first side surface portion 85CB. The first electrode upper surface portion 85JD covers the first electrode upper surface 201S of the first electrode plate 201. The first electrode upper surface portion 85JD is in contact with the first electrode upper surface 201S and is connected to the first curved portion 85CC.

The thick insulating layer 85A of the insulating layer 854 is embedded in the first recess 201CA. More specifically, the thick insulating layer 85A of the insulating layer 854 is embedded in a recessed space formed by the first side surface portion 85CB and the first curved portion 85CC in the thin insulating layer 85B of the insulating layer 854. Thus, it can be said that the insulating layer 854 is embedded in the first recess 201CA.

### [Second Electrode Plate]

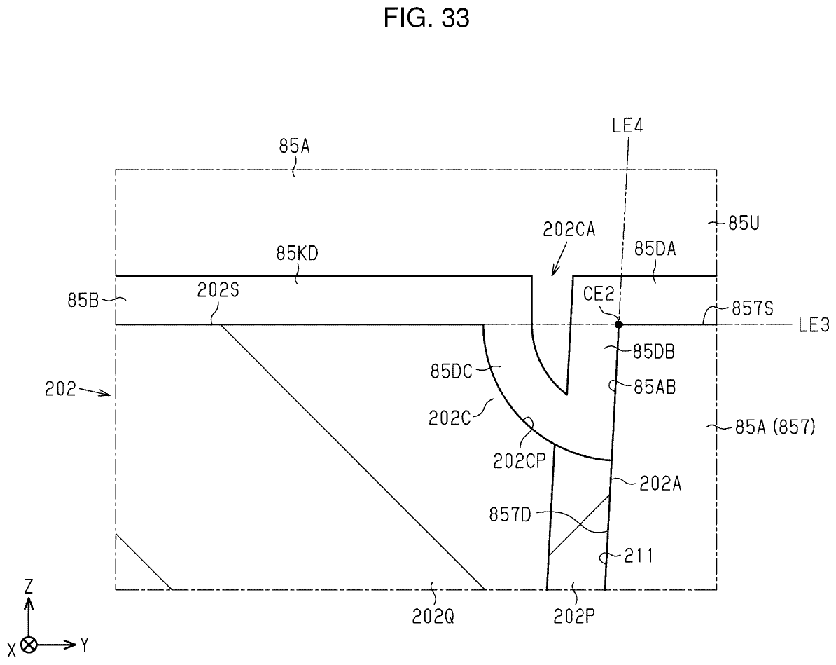

With reference to FIGS. 31 and 33, the structure of the second electrode plate 202 will be described. FIG. 33 is an enlarged cross-sectional view of the second electrode plate 202 and its surroundings shown in FIG. 31.

As shown in FIGS. 31 and 33, a through-hole 211 is provided in the insulating layer 857. The second electrode plate 202 is embedded in the through-hole 211.

Since the through-hole 211 penetrates the insulating layer 857 in the Z direction, it exposes the thick insulating layer 85A of the insulating layer 856. Therefore, the second electrode plate 202 embedded in the through-hole 211 is in contact with the thick insulating layer 85A of the insulating layer 856. In one example, the through-hole 211 is tapered, narrowing from the upper surface 857S to the lower surface 857R of the insulating layer 857. The angle θ8 of the side surface 857D of the insulating layer 857 that forms the through-hole 211 is between 80° and 90°. In one example, the angle θ8 is 85°. Here, the angle θ8 can be defined as the angle between the lower surface 857R and the side surface 857D of the insulating layer 857.

The second electrode plate 202 includes a second electrode upper surface 202S, a second electrode lower surface 202R, and a second electrode side surface 202A. The second electrode upper surface 202S is disposed near the insulating upper surface 84S of the insulator 84. The second electrode lower surface 202R constitutes the surface opposite to the second electrode upper surface 202S. The second electrode lower surface 202R is disposed near the insulating lower surface 84R of the insulator 84. The second electrode side surface 202A is disposed in the Z direction between the second electrode upper surface 202S and the second electrode lower surface 202R.

In the fourth embodiment, the second electrode upper surface 202S is disposed at the same position as the upper surface 857S of the insulating layer 857 in the Z direction. The position of the second electrode upper surface 202S in the Z direction can be arbitrarily changed. In one example, the second electrode upper surface 202S may be located closer to the lower surface 857R of the insulating layer 857 than to its upper surface 857S in the Z direction. The second electrode plate 202 embedded in the through-hole 211 has a tapered shape, such that the second electrode side surface 202A slopes inward from the second electrode upper surface 202S to the second electrode lower surface 202R. In other words, the opposing second electrode side surfaces 202A incline toward each other from top to bottom.

The second electrode plate 202 includes a seed layer 202P and a plating layer 202Q provided on the seed layer 202P. The seed layer 202P is provided on the side surface (side surface 857D of the insulating layer 857) forming the through-hole 211 and on the upper surface of the insulating layer 856 exposed by the through-hole 211. Therefore, both the second electrode lower surface 202R and the second electrode side surface 202A are formed by the seed layer 202P. The second electrode upper surface 202S is formed by the plating layer 202Q. In one example, the seed layer 202P has the same structure as the seed layer 45B shown in FIG. 13, and the plating layer 202Q has the same structure as the plating layer 46B shown in FIG. 13.

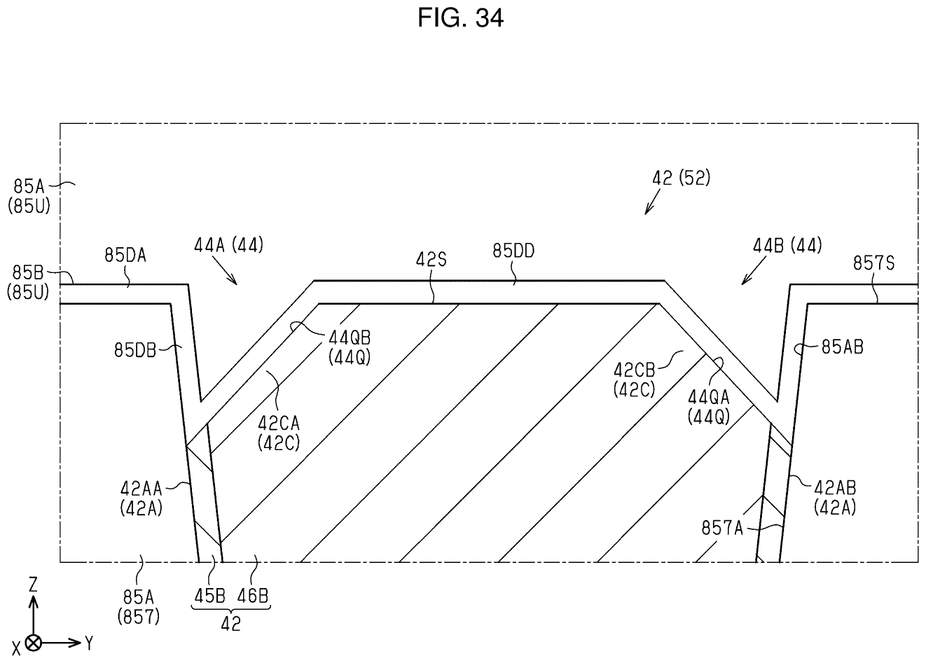

As shown in FIG. 33, the second electrode plate 202 includes a second electrode corner portion 202C between the second electrode side surface 202A and the second electrode upper surface 202S. A second recess 202CA is provided in the second electrode corner portion 202C. The second recess 202CA includes a second curved surface 202CP. The second recess 202CA is recessed so as to be convex inward of the second electrode plate 202. The cross-sectional shape of the second curved surface 202CP, as shown in FIG. 34, is arc-shaped. The second recess 202CA is arc-shaped about a second center of curvature CE2, which is the intersection of a third virtual line LE3 along the second electrode upper surface 202S and a fourth virtual line LE4 along the second electrode side surface 202A. The second center of curvature CE2 is located outside the second electrode plate 202. The second recess 202CA spans both the seed layer 202P and the plating layer 202Q. In one example, the second recess 202CA is provided along the entire periphery of the second electrode plate 202 in a plan view.

In one example, the arc length of the cross-sectional shape of the second curved surface 202CP is equal to the arc length of the cross-sectional shape of the first curved surface 201CP shown in FIG. 32. The radius of curvature of the second curved surface 202CP may also be considered equal to that of the first curved surface 201CP. The radius of curvature of the second curved surface 202CP is, for example, 1 μm.

The thick insulating layer 85A of the insulating layer 857 includes a second exposed side surface 85AB that is exposed from the second electrode side surface 202A of the second electrode plate 202 due to the second recess 202CA. The second exposed side surface 85AB is the portion of the side surface 857D of the insulating layer 857 between the upper edge of the second electrode side surface 202A and the upper surface 857S of the insulating layer 857. The second exposed side surface 85AB is opposed to the second curved surface 202CP of the second recess 202CA in a direction orthogonal to the Z direction. In one example, the length of the second exposed side surface 85AB is equal to the radius of curvature of the second curved surface 202CP. Here, the length of the second exposed side surface 85AB can be defined as the distance between the upper edge of the second electrode side surface 202A and the upper surface 857S of the insulating layer 857.

The second electrode plate 202 is covered by the thin insulating layer 85B of the uppermost insulating layer 85U. The portion of the thin insulating layer 85B corresponding to the second electrode plate 202 includes a second top portion 85DA, a second side portion 85DB, a second curved portion 85DC, and a second electrode top portion 85KD. The second top portion 85DA, second side portion 85DB, second curved portion 85DC, and second electrode top portion 85KD are integrated. The second top portion 85DA is in contact with the upper surface 857S of the insulating layer 857, as in the first embodiment. The second side portion 85DB is also in contact along the second exposed side surface 85AB, as in the first embodiment. The second side portion 85DB is connected to the second top portion 85DA. The second curved portion 85DC is in contact with the second curved surface 202CP, similar to the first embodiment. The second curved portion 85DC is connected to the second side portion 85DB. The second electrode top portion 85KD covers the second electrode upper surface 202S of the second electrode plate 202. The second electrode top portion 85KD is in contact with the second electrode upper surface 202S and is connected to the second curved portion 85DC.

The thick insulating layer 85A of the uppermost insulating layer 85U is embedded in the second recess 202CA. More specifically, the thick insulating layer 85A of the uppermost insulating layer 85U is embedded in a recessed space formed by the second side portion 85DB and the second curved portion 85DC of the thin insulating layer 85B of the uppermost insulating layer 85U. Thus, it can be said that the second recess 202CA is filled with the uppermost insulating layer 85U. According to the fourth embodiment, the same effects as in the first embodiment can be obtained.

### Modifications

The above embodiments can be modified as follows, for example. Unless technical inconsistencies arise, the above embodiments and the following modifications can be combined with each other. In the following modifications, elements common to the above embodiments are given the same reference numerals, and their descriptions are omitted.
The first through third embodiments can be combined with one another.
The fourth embodiment can be combined with the second and third embodiments.
In the second and third embodiments, the first recess 43 of the first coil 41 of the first conductor 51 may be omitted.
In the second and third embodiments, the first inner recess 57AA from the first inner terminal wiring 51A of the first conductor 51 may be omitted.
In the second and third embodiments, the first outer recess from the first outer terminal wiring 51B of the first conductor 51 may be omitted.
In the second and third embodiments, the second recess 44 of the second coil 42 of the second conductor 52 may be omitted.
In the second and third embodiments, the second inner recess from the second inner terminal wiring 52A of the second conductor 52 may be omitted.
In the second and third embodiments, the second outer recess from the second outer terminal wiring 52B of the second conductor 52 may be omitted.
In the first through third embodiments, the shape of the second recess 44 in the second coil 42 of the second conductor 52 may be arbitrarily modified. The cross-sectional shape of the second curved surface 44P of the second recess 44 may differ from an arc shape. In one example, as shown in FIG. 34, the second recess 44 includes a second inclined surface 44Q. More specifically, the second inner recess 44A includes a second inner inclined surface 44QA. The second outer recess 44B includes a second outer inclined surface 44QB. The second inner inclined surface 44QA connects the second inner side surface 42AA and the second upper surface 42S. The second outer inclined surface 44QB connects the second outer side surface 42AB and the second upper surface 42S. The second inner inclined surface 44QA inclines upward from the second inner side surface 42AA toward the second upper surface 42S. The second outer inclined surface 44QB inclines upward from the second outer side surface 42AB toward the second upper surface 42S.

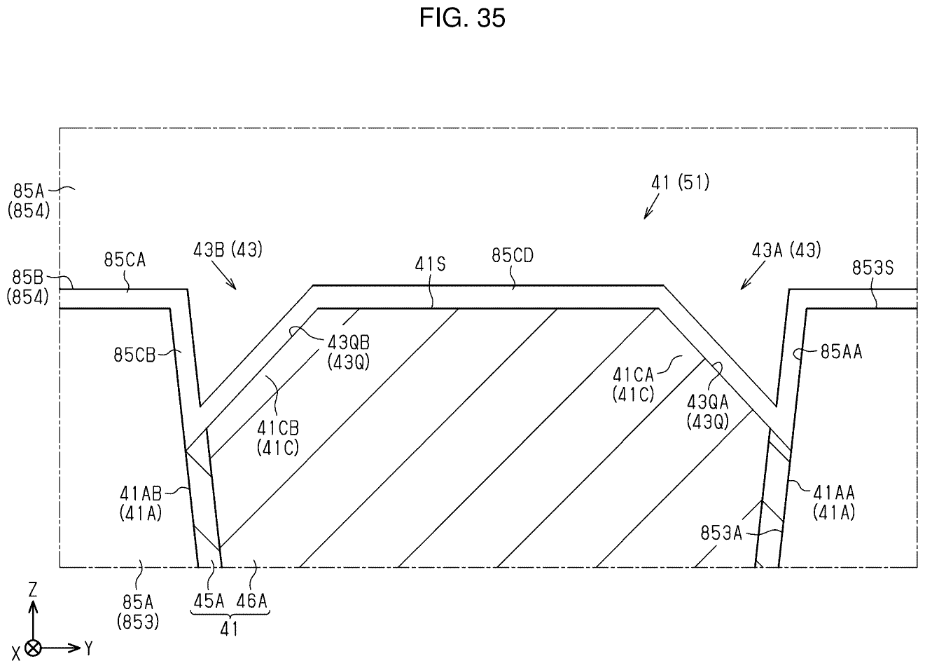

The thin insulating layer 85B of the uppermost insulating layer 85U covers the second inclined surface 44Q. More specifically, the thin insulating layer 85B of the uppermost insulating layer 85U covers both the second inner inclined surface 44QA and the second outer inclined surface 44QB. This thin insulating layer 85B includes a portion that extends along the second inner inclined surface 44QA while being in contact with it, and a portion that extends along the second outer inclined surface 44QB while being in contact with it. A thick insulating layer 85A of the uppermost insulating layer 85U is embedded in the second recess 44. More specifically, the thick insulating layer 85A of the uppermost insulating layer 85U is embedded in both the second inner recess 44A and the second outer recess 44B.
In the first through third embodiments, the shape of the first recess 43 in the first coil 41 of the first conductor 51 may be arbitrarily modified. The cross-sectional shape of the first curved surface 43P of the first recess 43 may differ from an arc shape. In one example, as shown in FIG. 35, the first recess 43 includes a first inclined surface 43Q. More specifically, the first inner recess 43A includes a first inner inclined surface 43QA. The first outer recess 43B includes a first outer inclined surface 43QB. The first inner inclined surface 43QA connects the first inner side surface 41AA and the first upper surface 41S. The first outer inclined surface 43QB connects the first outer side surface 41AB and the first upper surface 41S. The first inner inclined surface 43QA inclines upward from the first inner side surface 41AA toward the first upper surface 41S. The first outer inclined surface 43QB inclines upward from the first outer side surface 41AB toward the first upper surface 41S.

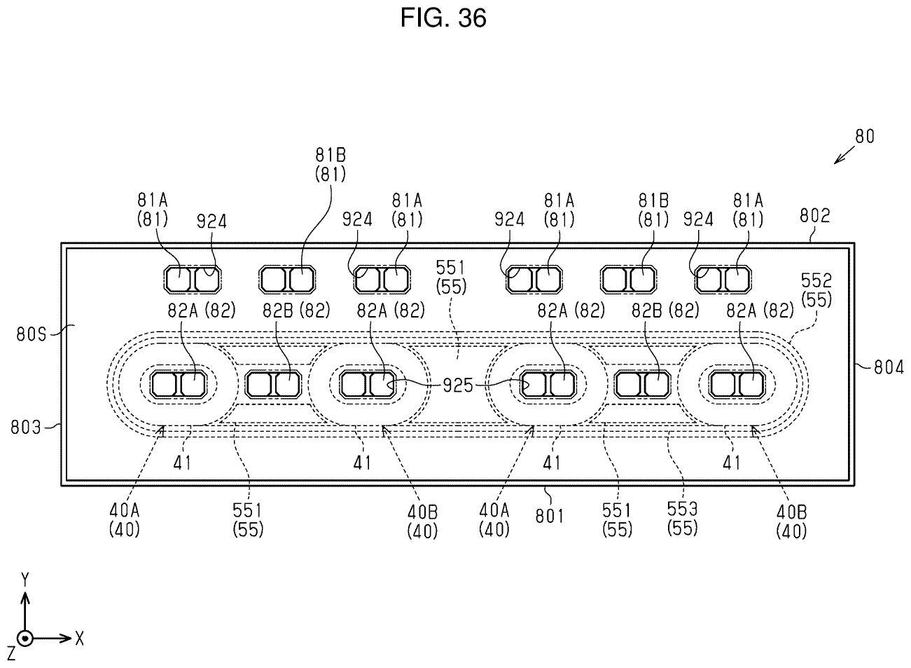

The thin insulating layer 85B of the insulating layer 854 covers the first inclined surface 43Q. More specifically, the thin insulating layer 85B of the insulating layer 854 covers both the first inner inclined surface 43QA and the first outer inclined surface 43QB. This thin insulating layer 85B includes a portion that extends along the first inner inclined surface 43QA while being in contact with it, and a portion that extends along the first outer inclined surface 43QB while being in contact with it. A thick insulating layer 85A of the insulating layer 854 is embedded in the first recess 43. More specifically, the thick insulating layer 85A of the insulating layer 854 is embedded in both the first inner recess 43A and the first outer recess 43B.
The configuration of the second recess 44 shown in FIG. 34 may be applied to at least one of the second inner terminal wiring 52A and the second outer terminal wiring 52B.
The configuration of the second recess 44 shown in FIG. 34 may be applied to at least one of the second layer wirings 63A of the first connection wiring 60A and the second layer wirings 63B of the second connection wiring 60B.
The configuration of the second recess 44 shown in FIG. 34 may be applied to the second seal portion 95 of the seal portion 93.
The configuration of the second recess 44 shown in FIG. 34 may be applied to the dummy pattern 55.
The configuration of the second recess 44 shown in FIG. 34 may be applied to the second electrode plate 202 of the third embodiment.
The configuration of the first recess 43 shown in FIG. 35 may be applied to at least one of the first inner terminal wiring 51A and the first outer terminal wiring 51B.
The configuration of the first recess 43 shown in FIG. 35 may be applied to at least one of the first layer wirings 62A of the first connection wiring 60A and the first layer wirings 62B of the second connection wiring 60B.
The configuration of the first recess 43 shown in FIG. 35 may be applied to the first seal portion 94 of the seal portion 93.
The configuration of the first recess 43 shown in FIG. 35 may be applied to the first electrode plate 201 of the third embodiment.
In the first through third embodiments, the arc length of the cross-sectional shape of the first inner curved surface 43PA in the first inner recess 43A of the first recess 43 in the first coil 41 may differ from the arc length of the cross-sectional shape of the first outer curved surface 43PB in the first outer recess 43B. In one example, the arc length of the cross-sectional shape of the first inner curved surface 43PA may be longer than that of the first outer curved surface 43PB in the first outer recess 43B. In another example, the arc length of the cross-sectional shape of the first outer curved surface 43PB in the first outer recess 43B may be longer than that of the first inner curved surface 43PA.
In the first through third embodiments, the arc length of the cross-sectional shape of the second inner curved surface 44PA in the second inner recess 44A of the second recess 44 in the second coil 42 may differ from the arc length of the cross-sectional shape of the second outer curved surface 44PB in the second outer recess 44B. In one example, the arc length of the second inner curved surface 44PA may be longer than that of the second outer curved surface 44PB. In another example, the arc length of the second outer curved surface 44PB may be longer than that of the second inner curved surface 44PA.
In the first through third embodiments, the arc length of the cross-sectional shape of the first curved surface 43P may differ from the arc length of the cross-sectional shape of the second curved surface 44P. In one example, the arc length of the first curved surface 43P may be longer than that of the second curved surface 44P. In another example, the arc length of the second curved surface 44P may be longer than that of the first curved surface 43P.
In the first through third embodiments, the arc length of the cross-sectional shape of the third curved surface 62AP may differ from the arc length of the cross-sectional shape of the first curved surface 43P. In one example, the arc length of the third curved surface 62AP may be longer than that of the first curved surface 43P. In another example, the arc length of the first curved surface 43P may be longer than that of the third curved surface 62AP. The arc length of the cross-sectional shape of the third curved surface 62AP may also differ from the arc length of the cross-sectional shape of the second curved surface 44P. In one example, the arc length of the third curved surface 62AP may be longer than that of the second curved surface 44P. In another example, the arc length of the second curved surface 44P may be longer than that of the third curved surface 62AP.
In the first through third embodiments, the arc length of the cross-sectional shape of the fourth curved surface 63AP may differ from that of the second curved surface 44P. In one example, the arc length of the fourth curved surface 63AP may be longer than that of the second curved surface 44P. In another example, the arc length of the second curved surface 44P may be longer than that of the fourth curved surface 63AP. The arc length of the fourth curved surface 63AP may also differ from that of the first curved surface 43P. In one example, the arc length of the fourth curved surface 63AP may be longer than that of the first curved surface 43P. In another example, the arc length of the first curved surface 43P may be longer than that of the fourth curved surface 63AP.
In the first through third embodiments, the arc length of the cross-sectional shape of the fifth curved surface 94CP may differ from that of the first curved surface 43P. In one example, the arc length of the fifth curved surface 94CP may be longer than that of the first curved surface 43P. In another example, the arc length of the first curved surface 43P may be longer than that of the fifth curved surface 94CP. The arc length of the fifth curved surface 94CP may also differ from that of the second curved surface 44P. In one example, the arc length of the fifth curved surface 94CP may be longer than that of the second curved surface 44P. In another example, the arc length of the second curved surface 44P may be longer than that of the fifth curved surface 94CP.
In the first through third embodiments, the arc length of the cross-sectional shape of the sixth curved surface 95CP may differ from that of the second curved surface 44P. In one example, the arc length of the sixth curved surface 95CP may be longer than that of the second curved surface 44P. In another example, the arc length of the second curved surface 44P may be longer than that of the sixth curved surface 95CP. The arc length of the sixth curved surface 95CP may also differ from that of the first curved surface 43P. In one example, the arc length of the sixth curved surface 95CP may be longer than that of the first curved surface 43P. In another example, the arc length of the first curved surface 43P may be longer than that of the sixth curved surface 95CP.
In the first through third embodiments, one of the first inner recess 43A and the first outer recess 43B of the first recess 43 in the first coil 41 may be omitted.
In the first through third embodiments, one of the second inner recess 44A and the second outer recess 44B of the second recess 44 in the second coil 42 may be omitted.
In the first through third embodiments, the configuration of the first coil 41 is not limited to the seed layer 45A and the plating layer 46A and may be arbitrarily changed. In one example, the first coil 41 may be configured by a metal body embedded in the first groove 86A. The metal body may be formed from a material including at least one of Cu and Al.
In the first through third embodiments, the configuration of the second coil 42 is not limited to the seed layer 45B and the plating layer 46B and may be arbitrarily changed. In one example, the second coil 42 may be configured by a metal body embedded in the second groove 86B. The metal body may be formed from a material including at least one of Cu and Al.
In the first through third embodiments, the formation range of the first recess 43 may be arbitrarily changed. In one example, the first recess 43 may be provided not in the pair of first straight sections 41D but in the pair of first curved sections 41E. That is, the first recess 43 may be provided spaced apart in the direction in which the coil wiring 41P of the first coil 41 extends in a plan view.
In the first through third embodiments, the formation range of the second recess 44 may be arbitrarily changed. In one example, the second recess 44 may be provided not in the pair of second straight sections 42D but in the pair of second curved sections 42E. That is, the second recess 44 may be provided spaced apart in the direction in which the coil wiring 41Q of the second coil 42 extends in a plan view.
In the first through third embodiments, the shape of the first coil 41 in a plan view may be arbitrarily changed. In one example, the first coil 41 may be of a circular or elliptical spiral shape in a plan view. In another example, the first coil 41 may be of a rectangular spiral shape in a plan view.
In the first through third embodiments, the shape of the second coil 42 in a plan view may be arbitrarily changed. In one example, the second coil 42 may be of a circular or elliptical spiral shape in a plan view. In another example, the second coil 42 may be of a rectangular spiral shape in a plan view.
In the first through third embodiments, the structure of the insulating chip 80 may be arbitrarily changed. In one example, as shown in FIG. 36, the insulating chip 80 may include two pairs of transformers 40A and 40B. The insulating chip 80 includes a plurality of first electrode pads 81 and a plurality of second electrode pads 82 corresponding to the two pairs of transformers 40A and 40B. Each pair of transformers 40A and 40B have the same configuration and are configured the same as the transformers 40A and 40B in the first through third embodiments. The same modifications may also be made in the fourth embodiment.
In the fourth embodiment, the arc length of the cross-sectional shape of the first curved surface 201CP may differ from that of the second curved surface 202CP. In one example, the arc length of the second curved surface 202CP may be longer than that of the first curved surface 201CP. In another example, the arc length of the first curved surface 201CP may be longer than that of the second curved surface 202CP.
In the dummy pattern 55 of each embodiment, the recess 55Q may be omitted from the first dummy pattern 551.
In the dummy pattern 55 of each embodiment, the recess 55Q may be omitted from the second dummy pattern 552.
In the dummy pattern 55 of each embodiment, the recess 55Q may be omitted from the third dummy pattern 553.
In each embodiment, the dummy pattern 55 may be omitted from the insulating chip 80.
In each embodiment, the configuration of the topmost insulating layer 85U among the plurality of insulating layers 85 may be arbitrarily changed. In one example, the thin insulating layer 85B may be omitted from the topmost insulating layer 85U. In this case, the topmost insulating layer 85U is constituted by the thick insulating layer 85A.
In each embodiment, the shape of the sealing portion 93 in a plan view is not limited to a rectangular frame shape and may be arbitrarily changed. In one example, the four corners of the sealing portion 93 in a plan view may be formed as curved portions.
In the first, second, and fourth embodiments, the sealing portion 93 may be omitted from the insulating chip 80.
In each embodiment, at least one of the passivation film 91 and the resin layer 92 may be omitted from the insulating chip 80.

### MODIFICATION EXAMPLES OF THE THROUGH WIRING OF THE CONNECTION WIRING

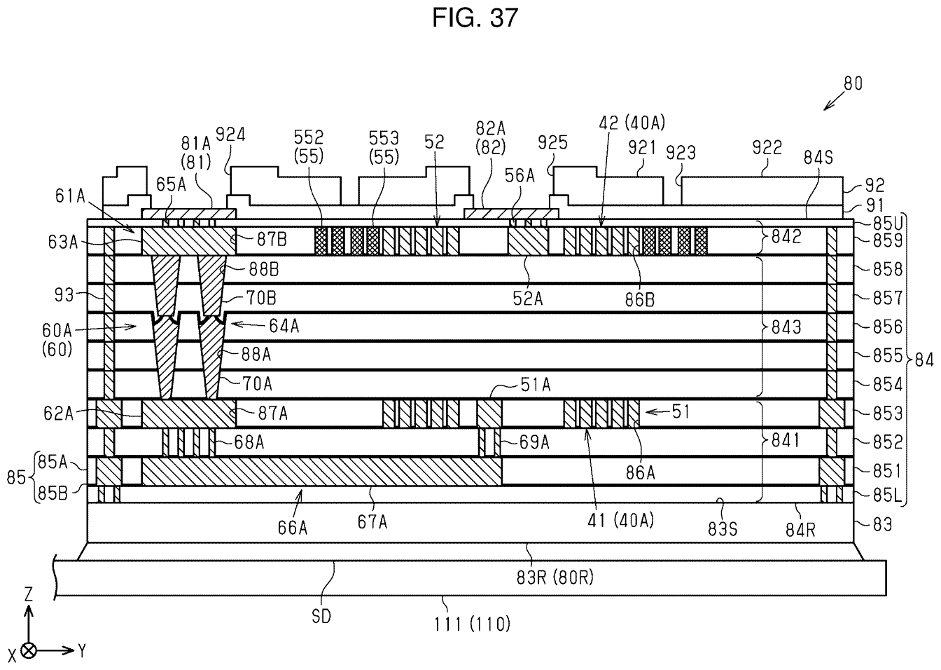

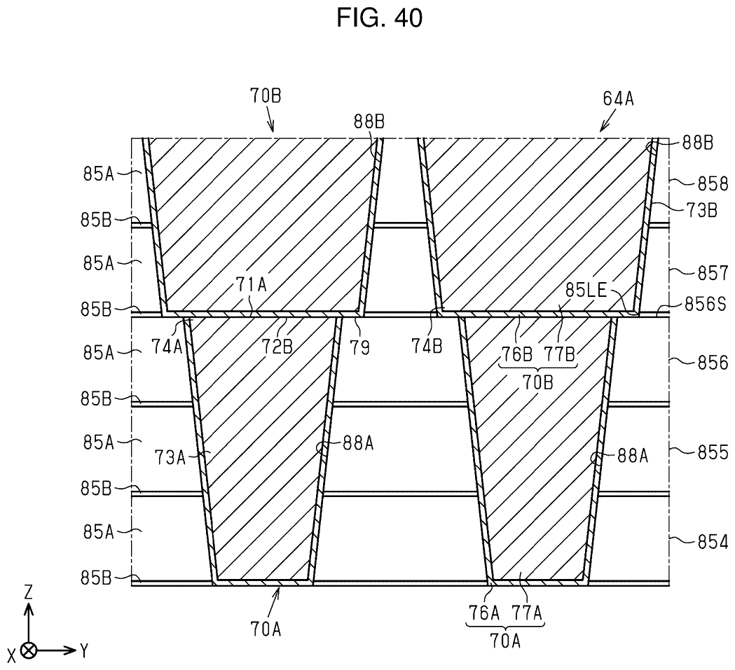

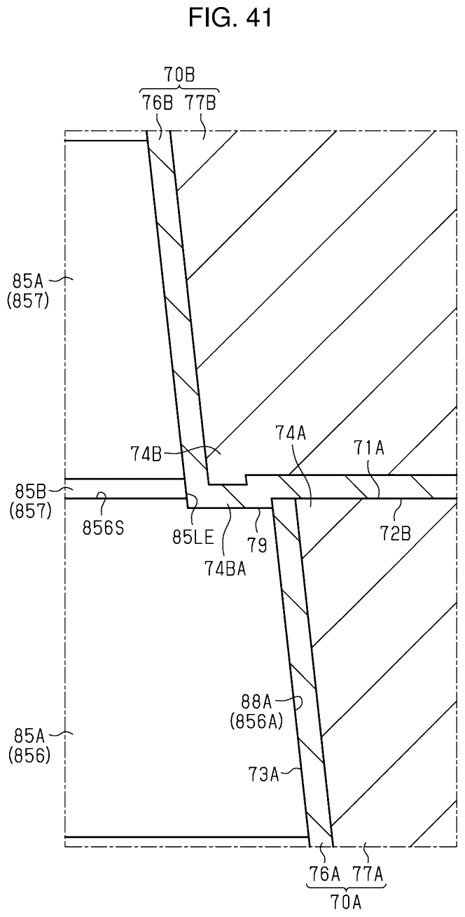

In each embodiment, the configuration of the through wiring 64A and 64B of the connection wiring 60 may be arbitrarily changed. One example includes the first modification example shown in FIGS. 37 to 39 and the second modification example shown in FIGS. 40 and 41. The configuration of the through wiring 64A is the same as that of the through wiring 64B. Accordingly, the following description focuses on the through wiring 64A, and the description of the through wiring 64B is omitted.

### First Modification Example

The through wiring 64A of the first modification example will be described with reference to FIGS. 37 to 39.

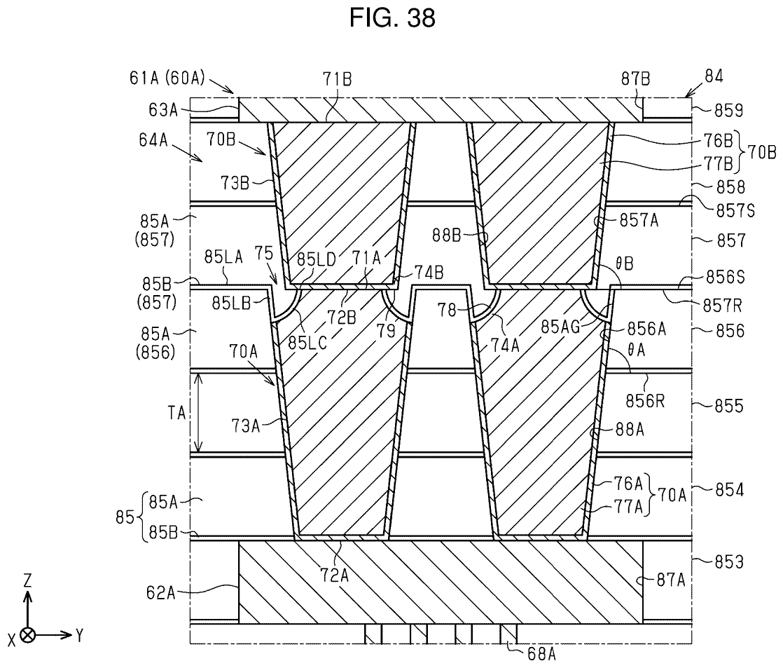

FIG. 37 schematically shows the cross-sectional structure of the insulating chip 80. FIG. 38 shows an enlarged cross-sectional view of the through wiring 64A and its surroundings from FIG. 37.

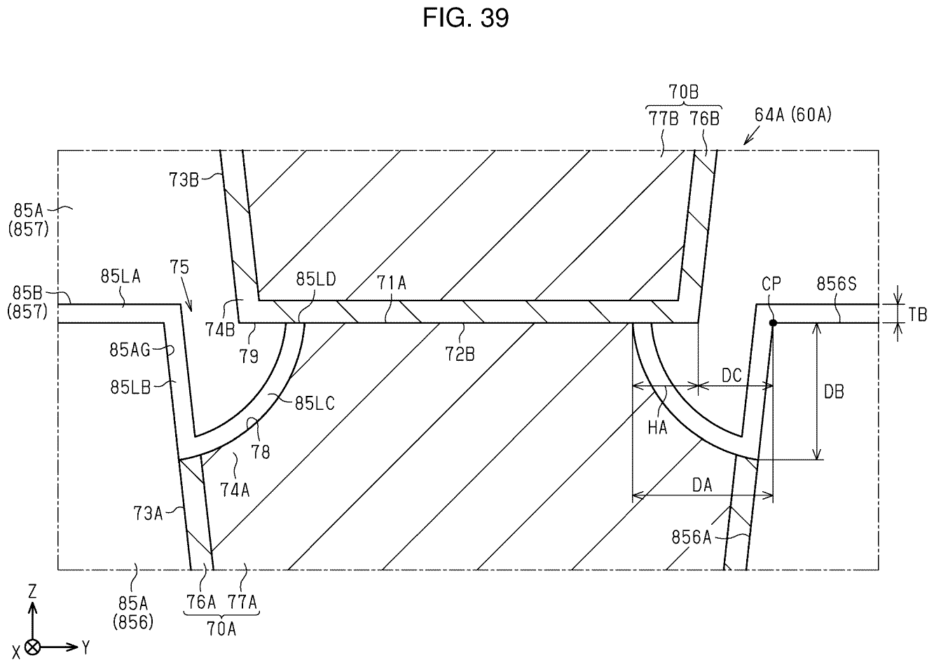

FIG. 39 shows an enlarged cross-sectional view of a portion of the first via 70A and second via 70B of the through wiring 64A and its surroundings.

As one example, as shown in FIG. 37, the insulating chip 80 including the through wiring 64A of the first modification example differs from the first through fourth embodiments in the number of insulating layers 85 of the insulator 84. The plurality of insulating layers 85 include insulating layers 851 to 859. Accordingly, the second conductor 52 and the second-layer wiring 63A are provided in the insulating layer 859.

Each through wiring 64A includes a first via 70A and a second via 70B provided on the first via 70A. More specifically, the insulator 84 includes a first through-hole 88A corresponding to the first via 70A and a second through-hole 88B corresponding to the second via 70B. The first through-hole 88A and the second through-hole 88B communicate with each other. The first via 70A is embedded in the first through-hole 88A. The second via 70B is embedded in the second through-hole 88B.

The first through-hole 88A penetrates multiple thick insulating layers 85A and multiple thin insulating layers 85B. Therefore, the first via 70A embedded in the first through-hole 88A penetrates the plurality of thick insulating layers 85A and the plurality of thin insulating layers 85B.

In the first modification example, the first through-hole 88A penetrates three insulating layers 85. Specifically, the first through-hole 88A penetrates insulating layers 854 to 856. Therefore, the first through-hole 88A exposes the first-layer wiring 62A provided in the insulating layer 853. As a result, the first via 70A embedded in the first through-hole 88A penetrates the insulating layers 854 to 856 and comes into contact with the first-layer wiring 62A.

As shown in FIG. 38, the insulating layer 856 includes a side surface 856A forming the first through-hole 88A. The side surface 856A is inclined so that the opening area of the first through-hole 88A in plan view decreases from the upper surface 856S of the insulating layer 856 toward the lower surface 856R. The angle θA of the side surface 856A is between 70° and 90°. In one example, the angle θA is 80°. Here, the angle θA can be defined as the angle between the lower surface 856R of the insulating layer 856 and the side surface 856A. Note that, within the range of angle θA, the side surface 856A may be a surface along the Z direction, that is, the side surface 856A may be non-inclined.

The first via 70A is circular in plan view. In the first modification example, the first via 70A has a truncated cone shape. The first via 70A includes a first via upper surface 71A, a first via lower surface 72A, and a first via side surface 73A.

The first via upper surface 71A is disposed closer to the insulating upper surface 84S of the insulator 84 (see FIG. 37). In one example, the first via upper surface 71A is circular in plan view. The first via lower surface 72A is a surface opposite to the first via upper surface 71A in the Z direction. In one example, the first via lower surface 72A is also circular in plan view. The first via lower surface 72A is in contact with the first-layer wiring 62A. The first via side surface 73A is provided between the first via upper surface 71A and the first via lower surface 72A in the Z direction. The first via side surface 73A has a tapered shape that narrows from the first via upper surface 71A toward the first via lower surface 72A. Note that when the side surface 856A is a surface along the Z direction, the first via 70A has a cylindrical shape. In this case, the first via side surface 73A becomes a surface along the Z direction.

In the first modification example, the first via upper surface 71A is disposed at the same position in the Z direction as the upper surface 856S of the insulating layer 856. Here, the upper surface 856S of the insulating layer 856 is constituted by the upper surface of the thick insulating layer 85A of the insulating layer 856. The upper surface 856S of the insulating layer 856 can also be regarded as the boundary between the thick insulating layer 85A of the insulating layer 856 and the thin insulating layer 85B of the insulating layer 857. The Z-direction position of the first via upper surface 71A may be arbitrarily changed. In one example, the first via upper surface 71A may be disposed closer to the lower surface 856R of the insulating layer 856 in the Z direction than the upper surface 856S.

The first via side surface 73A is in contact with insulating layers 854 to 856. More specifically, the first via side surface 73A is in contact with both the thick insulating layer 85A and the thin insulating layer 85B in insulating layers 854 and 855. The first via side surface 73A is in contact with the thick insulating layer 85A in insulating layer 856 but is not in contact with the thin insulating layer 85B in insulating layer 856. The first via side surface 73A is provided along the side surface 856A of insulating layer 856 (the side surface constituting the first through-hole 88A). Here, the insulating layer 856 is an example of the “first via insulating layer.” The insulating layer 857 laminated on the insulating layer 856 as the first via insulating layer is an example of the “second via insulating layer.”

The first via 70A includes a seed layer 76A and a plating layer 77A provided on the seed layer 76A. The seed layer 76A is provided on the side surface (the side surface 856A of insulating layer 856) constituting the first through-hole 88A and on the upper surface of the first-layer wiring 62A exposed by the first through-hole 88A. Therefore, both the first via lower surface 72A and the first via side surface 73A are formed by the seed layer 76A. The first via upper surface 71A is formed by the plating layer 77A. The seed layer 76A is, for example, a sputtered film formed by sputtering. The seed layer 76A may have a laminated structure of a Ti film and a Cu film, for example. The plating layer 77A is made of a material containing Cu, for example.

The first via 70A includes a first corner portion 74A provided between the first via upper surface 71A and the first via side surface 73A. A recess 75 is provided in the first corner portion 74A. The first via upper surface 71A and the first via side surface 73A are connected via the recess 75. The recess 75 is provided over the entire periphery of the first via 70A in plan view. Therefore, the recess 75 is annular in plan view. The recess 75 is provided across both the seed layer 76A and the plating layer 77A.

Due to the recess 75 being provided in the first via 70A, the first via upper surface 71A becomes smaller than the first via lower surface 72A. That is, the area of the first via upper surface 71A becomes smaller than the area of the first via lower surface 72A. In the first modification example, the diameter of the first via upper surface 71A is smaller than the diameter of the first via lower surface 72A.

As shown in FIG. 39, the recess 75 includes a curved surface 78 that is recessed in a manner such that it protrudes inward toward the center of the first via 70A. In the cross-sectional view shown in FIG. 39, the curved surface 78 is in the shape of an arc centered on a curvature center CP. The curvature center CP is located outward of the first via 70A. In one example, the curvature center CP is located at the same position in the Z direction as the first via upper surface 71A. In another example, the curvature center CP can be defined as the intersection of a virtual line along the side surface 856A of the insulating layer 856 and a virtual line along the upper surface 856S of the insulating layer 856. Because the first via side surface 73A is inclined with respect to the Z direction, the distance DA between the curvature center CP and the first via upper surface 71A is slightly larger than the distance DB between the curvature center CP and the first via side surface 73A in the Z direction. The distance DA may be regarded as the radius of curvature from the curvature center CP to the curved surface 78. The distances DA and DB are smaller than the thickness TA (see FIG. 38) of the thick insulating layer 85A. The distances DA and DB are greater than the thickness TB of the thin insulating layer 85B. The distances DA and DB are greater than twice the thickness TB of the thin insulating layer 85B. In one example, the distances DA and DB are equal to or less than the radius of the first via upper surface 71A. In one example, the distances DA and DB are 1 μm. Note that the distances DA and DB may be arbitrarily changed.

As shown in FIG. 38, the second through-hole 88B penetrates through multiple thick insulating layers 85A and multiple thin insulating layers 85B. In the first modification example, the second through-hole 88B penetrates through two insulating layers 85, specifically insulating layers 857 and 858. Therefore, the second through-hole 88B exposes the first via upper surface 71A. As a result, the second via 70B embedded in the second through-hole 88B penetrates through insulating layers 857 and 858 and is in contact with the first via upper surface 71A.

The insulating layer 857 includes a side surface 857A that constitutes the second through-hole 88B. The side surface 857A is inclined such that the opening area of the second through-hole 88B in plan view decreases from the upper surface 857S to the lower surface 857R of the insulating layer 857. The angle θB of the side surface 857A is between 70° and 90°. In one example, the angle θB is 80°. Here, the angle θB can be defined as the angle between the lower surface 857R and the side surface 857A of the insulating layer 857. Note that the side surface 857A may be a surface along the Z direction, in which case it may not be inclined.

The second via 70B embedded in the second through-hole 88B penetrates through insulating layers 857 and 858. Therefore, the dimension of the second via 70B in the Z direction is smaller than the Z-direction dimension of the first via 70A, which penetrates through insulating layers 854 to 856.

The second via 70B is circular in plan view. In the first modification example, the second via 70B has a truncated cone shape. The second via 70B includes a second via upper surface 71B, a second via lower surface 72B, and a second via side surface 73B.

The second via upper surface 71B is disposed closer to the insulating upper surface 84S of the insulator 84 (see FIG. 37). The second via upper surface 71B is in contact with the lower surface of the second-layer wiring 63A. In one example, the second via upper surface 71B is circular in plan view. The second via lower surface 72B is a surface opposite to the second via upper surface 71B in the Z direction. In one example, the second via lower surface 72B is also circular in plan view. The second via lower surface 72B is smaller than the second via upper surface 71B. That is, the area of the second via lower surface 72B is smaller than the area of the second via upper surface 71B. The diameter of the second via lower surface 72B is smaller than the diameter of the second via upper surface 71B. The second via side surface 73B is provided between the second via upper surface 71B and the second via lower surface 72B in the Z direction. The second via side surface 73B has a tapered shape that narrows from the second via upper surface 71B toward the second via lower surface 72B. Note that when the side surface 857A is a surface along the Z direction, the second via 70B is cylindrical. In this case, the second via side surface 73B becomes a surface along the Z direction.

The second via lower surface 72B is in contact with the first via upper surface 71A. In the first modification example, the second via lower surface 72B is positioned at the same level in the Z direction as the upper surface 856S of the insulating layer 856. The Z-direction position of the second via lower surface 72B may be arbitrarily changed depending on the position of the first via upper surface 71A. In one example, the second via lower surface 72B may be positioned closer to the lower surface 856R of the insulating layer 856 than the upper surface 856S.

The second via lower surface 72B is larger than the first via upper surface 71A. That is, the area of the second via lower surface 72B is greater than that of the first via upper surface 71A. The diameter of the second via lower surface 72B is also larger than that of the first via upper surface 71A. Therefore, the second via lower surface 72B includes an extension portion 79 that protrudes beyond the first via upper surface 71A in plan view. In one example, the extension portion 79 is annular in plan view. In other words, the extension portion 79 is provided so as to surround the entire periphery of the first via upper surface 71A in plan view.

As shown in FIG. 39, the protruding length HA of the extension portion 79 is smaller than the distance DC between the side surface 856A of the insulating layer 856 in plan view and the second via lower surface 72B, which is located at the same level as the upper surface 856S of the insulating layer 856 in the Z direction. In addition, the protruding length HA of the extension portion 79 is smaller than the distance DA between the curvature center CP of the recess 75 of the first via 70A and the first via upper surface 71A. Furthermore, the protruding length HA of the extension portion 79 is smaller than the distance DB between the curvature center CP and the first via side surface 73A in the Z direction. In one example, the protruding length HA of the extension portion 79 is greater than the thickness TB of the thin insulating layer 85B of the insulating layer 857. In another example, the protruding length HA of the extension portion 79 is smaller than the thickness TA of the thick insulating layer 85A of the insulating layer 856. Here, the protruding length HA of the extension portion 79 can be defined, for example, as half the difference between the diameters of the second via lower surface 72B and the first via upper surface 71A.

As shown in FIG. 38, the second via side surface 73B is in contact with the insulating layers 857 and 858. More specifically, the second via side surface 73B is in contact with both the thick insulating layer 85A and the thin insulating layer 85B in the insulating layer 858. The second via side surface 73B is in contact with the thick insulating layer 85A in the insulating layer 857 but not with the thin insulating layer 85B of the insulating layer 857.

The second via 70B includes a seed layer 76B and a plating layer 77B provided on the seed layer 76B. The seed layer 76B is formed on the side surface of the second through-hole 88B and the first via upper surface 71A exposed by the second through-hole 88B. Accordingly, both the second via lower surface 72B and the second via side surface 73B are formed of the seed layer 76B. The second via upper surface 71B is formed of the plating layer 77B. The seed layer 76B is, for example, a sputtered film formed by sputtering. The seed layer 76B may be a laminated structure of a Ti film and a Cu film. The plating layer 77B is made of a material including Cu, for example.

The second via 70B includes a second corner portion 74B formed by the second via lower surface 72B and the second via side surface 73B. The second corner portion 74B includes the extension portion 79. The second via lower surface 72B is positioned at the same level in the Z direction as the upper surface 856S of the insulating layer 856. Therefore, the second corner portion 74B includes a region located closer to the insulating layer 857 than the upper surface 856S of the insulating layer 856 in the Z direction.

As shown in FIG. 39, the thick insulating layer 85A of the insulating layer 856 includes an exposed side surface 85AG that is exposed from the side surface 73A of the first via 70A by the recess 75. The exposed side surface 85AG is a portion of the side surface 856A of the insulating layer 856 located between the upper edge of the side surface 73A of the first via and the upper surface 856S of the insulating layer 856. The exposed side surface 85AG faces the curved surface 78 of the recess 75 in a direction orthogonal to the Z direction. In one example, the length of the exposed side surface 85AG is equal to the radius of curvature of the curved surface 78. Here, the length of the exposed side surface 85AG can be defined as the distance between the upper edge of the side surface 73A of the first via and the upper surface 856S of the insulating layer 856.

The thin insulating layer 85B of the insulating layer 857 includes a top surface portion 85LA, a side surface portion 85LB, and a curved portion 85LC. The top surface portion 85LA, side surface portion 85LB, and curved portion 85LC are integrated.

The top surface portion 85LA is laminated on the upper surface 856S of the insulating layer 856. The top surface portion 85LA faces the second corner portion 74B of the second via 70B in a direction orthogonal to the Z direction. In one example, the top surface portion 85LA is provided to surround the second corner portion 74B in plan view. The top surface portion 85LA is spaced apart from the second corner portion 74B in a direction orthogonal to the Z direction.

The side surface portion 85LB is provided along the exposed side surface 85AG. The side surface portion 85LB includes a first portion that faces the second corner portion 74B of the second via 70B in a direction orthogonal to the Z direction. The side surface portion 85LB also includes a second portion located closer to the lower surface 856R (see FIG. 38) of the insulating layer 856 than the second via 70B in the Z direction. The second portion is provided within the recess 75 in a direction orthogonal to the Z direction.

The curved portion 85LC is provided along the curved surface 78 of the recess 75. The curved portion 85LC is provided within the recess 75. The curved portion 85LC is in contact with a portion of the second via lower surface 72B that is located inward from the second via side surface 73B. The end surface 85LD of the curved portion 85LC is in contact with a portion of the second via lower surface 72B that is spaced apart from the outer edge.

The thick insulating layer 85A of the insulating layer 857 is embedded in the recess 75. More specifically, the thick insulating layer 85A of the insulating layer 857 is embedded in a recessed space formed by the side surface portion 85LB and the curved portion 85LC of the thin insulating layer 85B of the insulating layer 857. Accordingly, the thick insulating layer 85A of the insulating layer 857 is interposed between the top surface portion 85LA of the thin insulating layer 85B of the insulating layer 857 and the second corner portion 74B of the second via 70B. Thus, it can be said that the recess 75 is filled with the insulating layer 857.

The thick insulating layer 85A of the insulating layer 857 is in contact with the second corner portion 74B of the second via 70B. It can be said that the thick insulating layer 85A of the insulating layer 857 covers the second corner portion 74B. More specifically, the thick insulating layer 85A of the insulating layer 857 is in contact with both the second via side surface 73B and the second via lower surface 72B, which constitute the second corner portion 74B. The thick insulating layer 85A of the insulating layer 857 extends over the outer edge of the second via lower surface 72B and the second via side surface 73B continuing from this outer edge. The thick insulating layer 85A of the insulating layer 857 is in contact with the portion of the second via lower surface 72B between the outer edge of the second via lower surface 72B and the portion where the end surface 85LD of the thin insulating layer 85B contacts. Therefore, it can be said that the thick insulating layer 85A of the insulating layer 857 is in contact with the end portion of the extension portion 79. Here, the end portion of the extension portion 79 is a portion of the extension portion 79 including the outer periphery of the second via lower surface 72B, which is located closer to the outer periphery than the portion where the curved portion 85LC of the thin insulating layer 85B contacts. Thus, the extension portion 79 is in contact with both the thick insulating layer 85A and the thin insulating layer 85B of the insulating layer 857.

According to the first modification, the following effects can be obtained.

(A) The lower surface 72B of the second via 70B includes an extension portion 79 that protrudes beyond the upper surface 71A of the first via 70A in plan view. An end portion of the extension portion 79 is in contact with the thick insulating layer 85A of the insulating layer 857.

According to this configuration, it is possible to reduce stress concentration on the lower surface 72B of the second via 70B and suppress the occurrence of cracks in the thick insulating layer 85A caused by the thin insulating layer 85B. Accordingly, it is possible to suppress a decrease in the breakdown voltage of the insulating chip 80 due to such cracks.

(B) The first via 70A includes a first corner portion 74A provided between the upper surface 71A and the side surface 73A of the first via 70A. The first corner portion 74A is provided with a recess 75. Due to the recess 75, the upper surface 71A of the first via 70A becomes smaller than the lower surface 72B of the second via 70B. According to this configuration, it is possible to suppress an increase in the size of the second via 70B in a direction orthogonal to the Z direction.

(C) The recess 75 includes a curved surface 78 that is concave inward toward the interior of the first via 70A.

According to this configuration, the recess 75 forms a reverse taper shape from the upper surface 71A to the side surface 73A of the first via 70A, so the stress generated in the recess 75 is directed inward of the first via 70A. That is, stress is less likely to be applied from the recess 75 to the insulating layer 857. Accordingly, it is possible to suppress the occurrence of cracks in the insulating layers 856 and 857. Furthermore, even when the recess 75 is provided, it is possible to suppress the area of the upper surface 71A of the first via 70A from becoming excessively small. As a result, it is possible to suppress an excessive increase in the electrical resistance of the conduction path formed by the first via 70A and the second via 70B.

(D) The cross-sectional shape of the curved surface 78 is arc-shaped.

According to this configuration, the recess 75 forms a reverse taper shape from the upper surface 71A to the side surface 73A of the first via 70A, so the stress generated in the recess 75 is directed inward of the first via 70A. That is, stress is less likely to be applied from the recess 75 to the insulating layer 857. Accordingly, it is possible to suppress the occurrence of cracks in the insulating layers 856 and 857. Furthermore, even when the recess 75 is provided, it is possible to suppress the area of the upper surface 71A of the first via 70A from becoming excessively small. As a result, it is possible to suppress an excessive increase in the electrical resistance of the conduction path formed by the first via 70A and the second via 70B.

(E) The protrusion length HA of the extension portion 79 is greater than the thickness TB of the thin insulating layer 85B of the insulating layer 856. The thin insulating layer 85B of the insulating layer 856 is in contact with an inward portion of the lower surface 72B of the second via 70B relative to the side surface 73B.

According to this configuration, it is possible to prevent the thin insulating layer 85B of the insulating layer 856 from contacting the connection portion between the lower surface 72B and the side surface 73B of the second via 70B. Accordingly, stress is less likely to be applied to the thin insulating layer 85B due to stress concentration at the above-mentioned connection portion of the second via 70B. Therefore, it is possible to suppress the occurrence of cracks caused by the thin insulating layer 85B, and thus suppress a decrease in the breakdown voltage of the insulating chip 80.

(F) The thick insulating layer 85A of the insulating layer 857 is in contact with both the outer edge of the lower surface 72B of the second via 70B and the side surface 73B continuing from the outer edge.

According to this configuration, the connection portion between the lower surface 72B and the side surface 73B of the second via 70B is covered by the thick insulating layer 85A. In other words, it is possible to suppress contact between the thin insulating layer 85B and the above-mentioned connection portion. Therefore, it is possible to suppress the occurrence of cracks caused by the thin insulating layer 85B, and thus suppress a decrease in the breakdown voltage of the insulating chip 80.

(G) The thick insulating layer 85A of the insulating layer 857 is embedded in the recess 75. According to this configuration, it is possible to suppress the formation of voids within the recess 75. Therefore, the occurrence of cracks in the insulating layer 856 due to voids can be suppressed.

(H) The thick insulating layer 85A of the insulating layer 856 includes the side surface 856A that forms the first through-hole 88A in which the first via 70A is embedded. The protrusion length HA of the extension portion 79 is located at the same Z-direction position as the upper surface of the thick insulating layer 85A of the insulating layer 856 and is smaller than the distance DC in plan view between the side surface 856A and the lower surface 72B of the second via.

According to this configuration, a sufficient distance can be secured between the extension portion 79 and the portion of the thin insulating layer 85B of the insulating layer 856 that is laminated on the thick insulating layer 85A. Therefore, the thick insulating layer 85A of the insulating layer 857 can be easily embedded in the recess 75.

(I) The upper surface of the thick insulating layer 85A of the insulating layer 856 is at the same Z-direction position as the upper surface 71A of the first via 70A. The thin insulating layer 85B of the insulating layer 856 includes an upper surface portion 85LA laminated on the upper surface of the thick insulating layer 85A. The upper surface portion 85LA faces a second corner portion 74B, which is formed by the extension portion 79 and the side surface 73B of the second via 70B. The upper surface portion 85LA is spaced apart from the second corner portion 74B. A portion of the thick insulating layer 85A of the insulating layer 857 is interposed between the upper surface portion 85LA and the second corner portion 74B.

According to this configuration, the thick insulating layer 85A interposed between the upper surface portion 85LA and the second corner portion 74B reduces the transmission of stress from the second corner portion 74B to the upper surface portion 85LA. Accordingly, it is possible to suppress the upper surface portion 85LA from peeling off the thick insulating layer 85A of the insulating layer 856.

(J) Both the first via 70A and the second via 70B are provided so as to penetrate through multiple thick insulating layers 85A and multiple thin insulating layers 85B.

Compared to a configuration in which the first via 70A penetrates only one thick insulating layer 85A and one thin insulating layer 85B and the second via 70B penetrates only one thick insulating layer 85A and one thin insulating layer 85B, the stress generated at the first corner portion 74A of the first via 70A and the second corner portion 74B of the second via 70B is greater. In other words, cracks are more likely to occur in the insulating layer 856 due to such stress. However, in the insulating chip 80 of the first modification, the lower surface 72B of the second via 70B includes the extension portion 79, and the extension portion 79 is in contact with the thick insulating layer 85A of the insulating layer 857. As a result, stress concentration at the first corner portion 74A and second corner portion 74B of the second via 70B can be alleviated, and the occurrence of cracks in the insulating layer 856 can be suppressed.

(K) The thickness of the first via 70A is greater than the thickness of the second via 70B. According to this configuration, even when the recess 75 is provided in the first via 70A, it is possible to suppress the area of the upper surface 71A of the first via 70A from becoming excessively small. Therefore, it is possible to suppress an excessive increase in the electrical resistance of the conduction path formed by the first via 70A and the second via 70B.

### Second Modification

With reference to FIGS. 40 and 41, the through wiring 64A of the second modification will be described. FIG. 40 is an enlarged cross-sectional view of the through wiring 64A and its surrounding area. FIG. 41 is an enlarged cross-sectional view of part of the first via 70A and the second via 70B and their surrounding area. Since the through wiring 64B has the same configuration as the through wiring 64A, its description is omitted.

As shown in FIG. 40, the first via 70A of the through wiring 64A in the second modification does not include the recess 75 shown in FIG. 39. Therefore, the side surface 856A of the insulating layer 856 that forms the first through-hole 88A does not include the first exposed side surface 85AA shown in FIG. 39. The thin insulating layer 85B of the insulating layer 856 does not include the side surface portion 85LB and the curved portion 85LC shown in FIG. 39.

In the through wiring 64A of the second modification, the lower surface 72B of the second via 70B is larger than the upper surface 71A of the first via 70A. In other words, the area of the lower surface 72B of the second via is greater than that of the upper surface 71A of the first via. In one example, the diameter of the lower surface 72B of the second via is larger than the diameter of the upper surface 71A of the first via. Therefore, the lower surface 72B of the second via includes an extension portion 79 that protrudes beyond the upper surface 71A of the first via in plan view.

In the second modification, the upper surface 71A of the first via is positioned at the same Z-direction location as the upper surface 856S of the insulating layer 856. Accordingly, the lower surface 72B of the second via that contacts the upper surface 71A of the first via is also positioned at the same Z-direction location as the upper surface 856S of the insulating layer 856.

As shown in FIG. 41, the side surface 73B of the second via 70B, which forms the second corner portion 74B, is in contact with the thin insulating layer 85B of the insulating layer 857. In other words, the side surface 85LE of the thin insulating layer 85B of the insulating layer 857 is in contact with the side surface 73B of the second via. The extension portion 79 is in contact with the upper surface 856S of the insulating layer 856. In this way, the second corner portion 74B is in contact with both the thick insulating layer 85A and the thin insulating layer 85B of the insulating layer 857.

The second corner portion 74B includes a protruding portion 74BA that extends toward the lower surface 72A of the first via with respect to the upper surface 71A of the first via 70A. The protruding portion 74BA is annular in plan view. In the second modification, the protruding portion 74BA is circularly annular in plan view. The extension portion 79 forms the lower surface of the protruding portion 74BA. As shown in FIG. 41, the protruding portion 74BA is covered by the thick insulating layer 85A of the insulating layer 856. That is, the thick insulating layer 85A of the insulating layer 856 extends from the extension portion 79 that constitutes the protruding portion 74BA to the side surface 73B of the second via. The edge of the extension portion 79 is also in contact with the thick insulating layer 85A of the insulating layer 856. Therefore, the side surface 85LE of the thin insulating layer 85B of the insulating layer 856 contacts the side surface 73B of the second via in a state where it is spaced apart from the extension portion 79 in the Z direction.

According to the second modification, the following effects are obtained.

The second via 70B includes the second corner portion 74B that includes the extension portion 79 and the side surface 73B. The second corner portion 74B includes the protruding portion 74BA that extends toward the lower surface 72A of the first via with respect to the upper surface 71A of the first via. The extension portion 79 forms the lower surface of the protruding portion 74BA. The side surface 85LE of the thin insulating layer 85B of the insulating layer 856 contacts the side surface 73B of the second via while being spaced apart from the extension portion 79 in the Z direction.

According to this configuration, it is possible to suppress contact between the extension portion 79 and the thin insulating layer 85B of the insulating layer 856. As a result, stress from the second corner portion 74B is less likely to be transmitted to the thin insulating layer 85B of the insulating layer 856. Therefore, it is possible to suppress the occurrence of cracks in the insulating layer 856 due to the thin insulating layer 85B.

### Other Modifications of Through Wiring

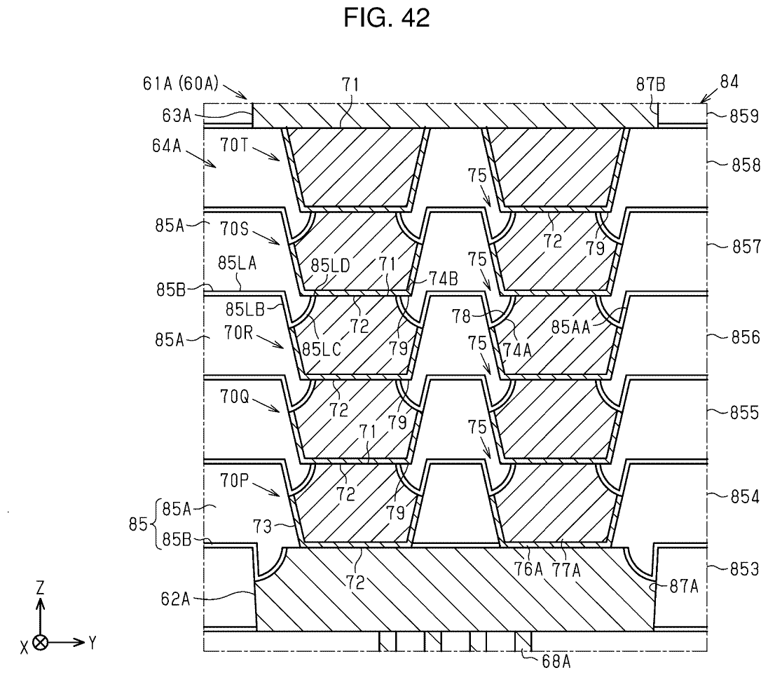

In the first modification, the structure of the through wiring 64A (64B) can be arbitrarily changed. In one example, as shown in FIG. 42, the through wiring 64A may include first to fifth vias 70P, 70Q, 70R, 70S, and 70T corresponding to each of the insulating layers 854 to 858. The first to fifth vias 70P to 70T have the same structure and are similar to the structure of the first via 70A (see FIG. 39). Therefore, the first to fifth vias 70P to 70T include a common via upper surface 71, via lower surface 72, and via side surface 73. The fifth via 70T is a structure in which the recess 75 is omitted from the first to fourth vias 70P to 70S. Thus, the fifth via 70T includes the via upper surface 71, via lower surface 72, and via side surface 73. The area of the via upper surface 71 of the fifth via 70T is larger than that of the first to fourth vias 70P to 70S, due to the absence of the recess 75.

The first via 70P penetrates the insulating layer 854 and is in contact with the first-layer wiring 62A. The second via 70Q penetrates the insulating layer 855 and is laminated on top of the first via 70P. Thus, the lower surface 72 of the second via 70Q is in contact with the upper surface 71 of the first via 70P. The third via 70R penetrates the insulating layer 856 and is laminated on top of the second via 70Q. Thus, the lower surface 72 of the third via 70R is in contact with the upper surface 71 of the second via 70Q. The fourth via 70S penetrates the insulating layer 857 and is laminated on top of the third via 70R. Thus, the lower surface 72 of the fourth via 70S is in contact with the upper surface 71 of the third via 70R. The fifth via 70T penetrates the insulating layer 858 and is laminated on top of the fourth via 70S. Thus, the lower surface 72 of the fifth via 70T is in contact with the upper surface 71 of the fourth via 70S. The upper surface 71 of the fifth via 70T is in contact with the second-layer wiring 63A.

As shown in FIG. 42, the first to fifth vias 70P-70T include recesses 75 in the same manner as the first via 70A. The thin insulating layers 85B of the insulating layers 854-858 are formed along the recesses 75, similarly to the recess 75 of the first via 70A. The thick insulating layer 85A of the insulating layer 855 is embedded in the recess 75 of the first via 70P. The thick insulating layer 85A of the insulating layer 856 is embedded in the recess 75 of the second via 70Q. The thick insulating layer 85A of the insulating layer 857 is embedded in the recess 75 of the third via 70R. The thick insulating layer 85A of the insulating layer 858 is embedded in the recess 75 of the fourth via 70S.

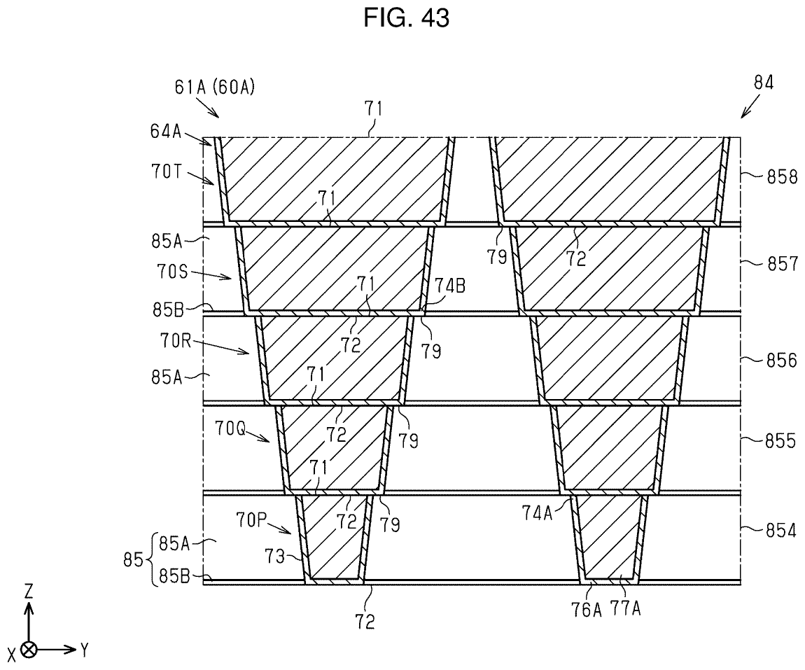

In the second modification, the configuration of the through wiring 64A (64B) can be arbitrarily modified. For example, as shown in FIG. 43, the through wiring 64A may include first to fifth vias 70P, 70Q, 70R, 70S, and 70T corresponding to the insulating layers 854-858. The lamination pattern of the first to fifth vias 70P-70T is the same as that shown in FIG. 42.

The area of the lower surface 72 of the second via 70Q is larger than the area of the upper surface 71 of the first via 70P. That is, the lower surface 72 of the second via 70Q includes an extension portion 79 that protrudes beyond the upper surface 71 of the first via 70P in plan view. The area of the lower surface 72 of the third via 70R is larger than the area of the upper surface 71 of the second via 70Q. That is, the lower surface 72 of the third via 70R includes an extension portion 79 that protrudes beyond the upper surface 71 of the second via 70Q in plan view. The area of the lower surface 72 of the fourth via 70S is larger than the area of the upper surface 71 of the third via 70R. That is, the lower surface 72 of the fourth via 70S includes an extension portion 79 that protrudes beyond the upper surface 71 of the third via 70R in plan view. The area of the lower surface 72 of the fifth via 70T is larger than the area of the upper surface 71 of the fourth via 70S. That is, the lower surface 72 of the fifth via 70T includes an extension portion 79 that protrudes beyond the upper surface 71 of the fourth via 70S in plan view.

In the first and second modifications, the number of insulating layers 85 between the first-layer wiring 62A and the second-layer wiring 63A may be arbitrarily changed. In one example, the number of insulating layers 85 between the first-layer wiring 62A and the second-layer wiring 63A may be three. In this case, the first via 70A of the through wiring 64A penetrates two insulating layers 85, and the second via 70B of the through wiring 64A penetrates one insulating layer 85.

In the first and second modifications, the structure of the first via 70A is not limited to the seed layer 76A and plating layer 77A and may be arbitrarily modified. In one example, the first via 70A may be formed of a metal body embedded in the first through-hole 88A. The metal body may be formed of a material that includes at least one of Cu and Al.

In the first and second modification examples, the configuration of the second via 70B is not limited to the seed layer 76B and the plating layer 77B, and may be arbitrarily modified. For example, the second via 70B may be formed of a metal body embedded in the second through-hole 88B. The metal body may be composed of a material including at least one of Cu and Al.

In the first and second modification examples, the relationship between the thickness of the first via 70A and the thickness of the second via 70B may be arbitrarily changed. In one example, the thickness of the first via 70A and the thickness of the second via 70B may be equal. In another example, the thickness of the first via 70A may be smaller than that of the second via 70B. In this case, for instance, the first via 70A may penetrate the insulating layers 855 and 856, and the second via 70B may penetrate the insulating layers 857 through 859.

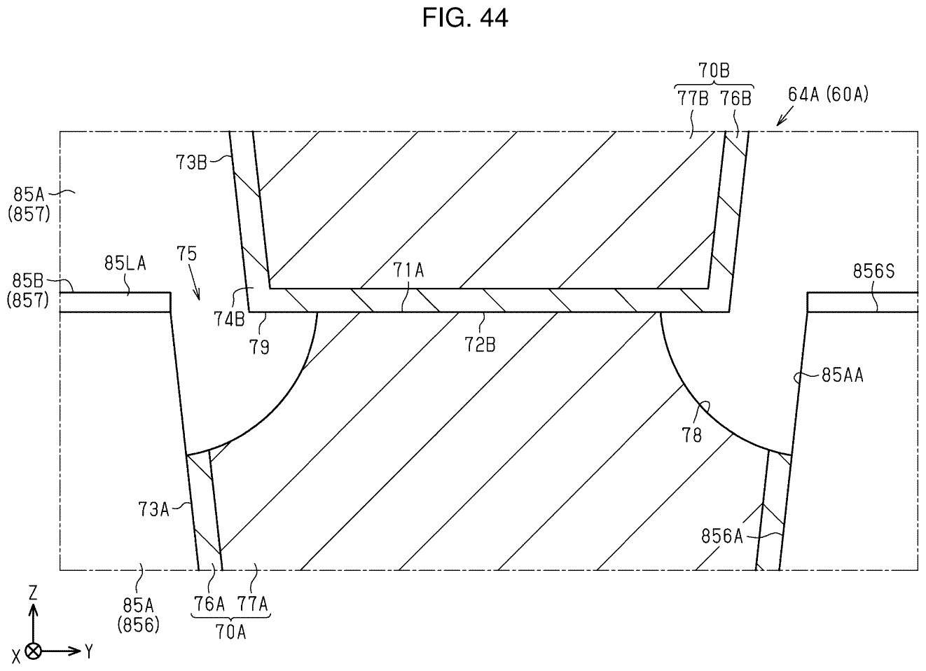

In the first modification example, the formation area of the thin insulating layer 85B of the insulating layer 856 may be arbitrarily modified. In one example, as shown in FIG. 44, the thin insulating layer 85B need not be formed along the recess 75 of the first via 70A. In this case, the thick insulating layer 85A of the insulating layer 857 (third insulating layer) is embedded so as to contact the curved surface 78 of the recess 75 of the first via 70A. Also, the thin insulating layer 85B of the insulating layer 856 is spaced apart from the second via 70B. That is, the thick insulating layer 85A of the insulating layer 857 is interposed between the thin insulating layer 85B of the insulating layer 856 and the second via 70B.

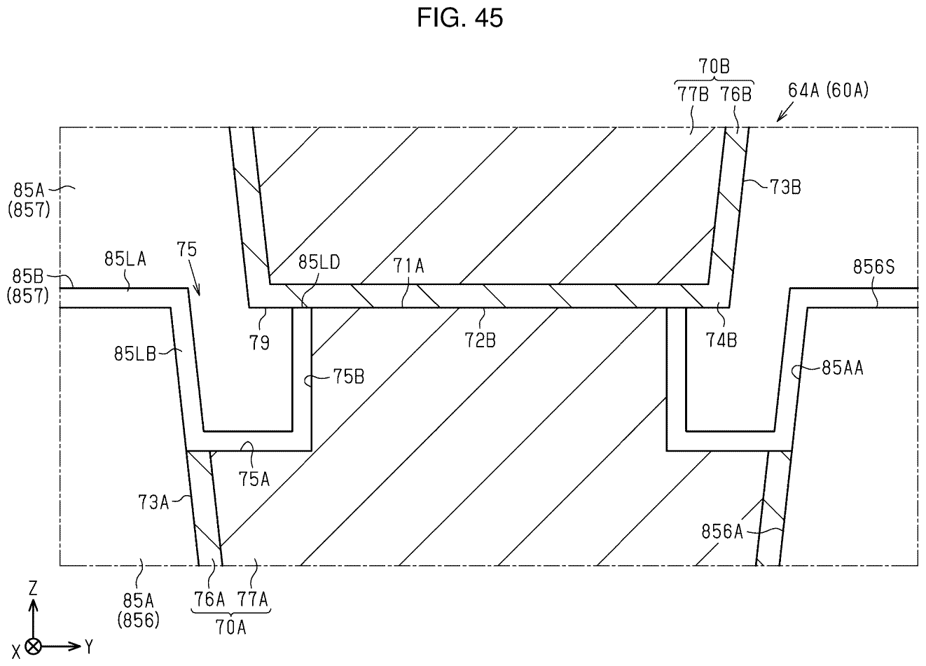

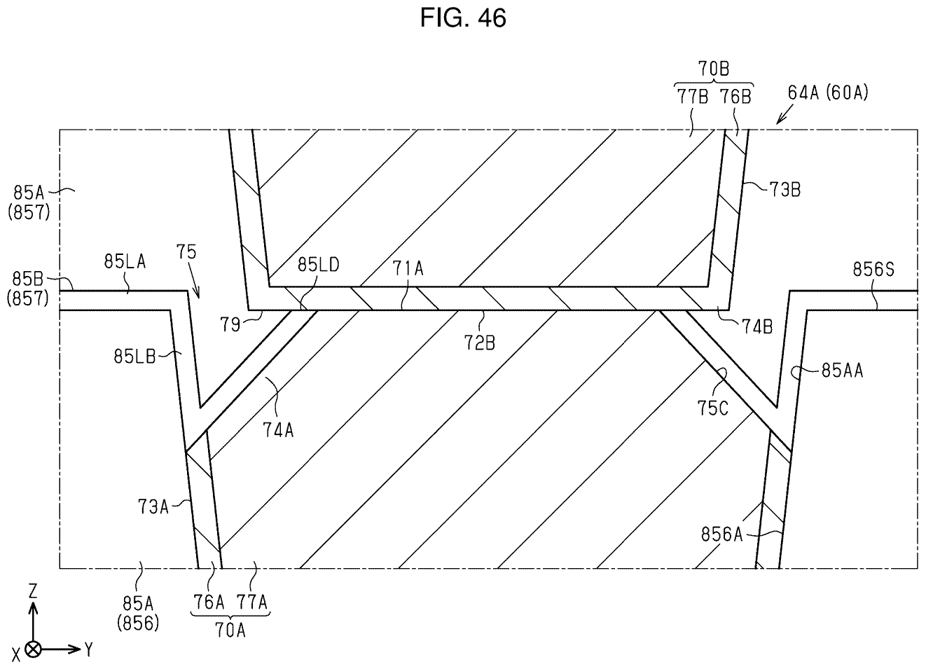

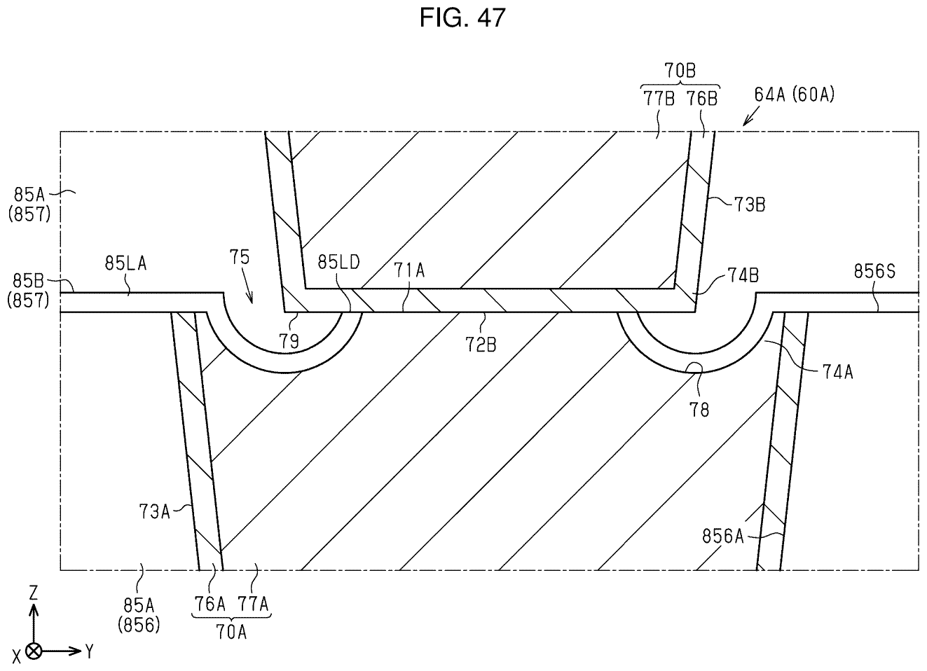

In the first modification example, the shape of the recess 75 formed in the first corner portion 74A of the first via 70A may be arbitrarily modified. For example, the recess 75 may be modified as shown in a first example in FIG. 45, a second example in FIG. 46, or a third example in FIG. 47.

As shown in FIG. 45, the recess 75 of the first example may have a rectangular recessed shape. The recess 75 shown in FIG. 45 includes a bottom surface 75A and a side surface 75B. The bottom surface 75A is defined by a plane orthogonal to the Z direction. In one example, the bottom surface 75A is annular in plan view. The bottom surface 75A connects the side surface 75B and the via side surface 73A of the first via. In one example, the side surface 75B is defined by a plane along the Z direction. The side surface 75B connects the bottom surface 75A and the upper surface 71A of the first via. The side surface 75B is located inward of the lower surface 72B of the second via 70B in plan view.

The thin insulating layer 85B of the insulating layer 856 covers the bottom surface 75A and the side surface 75B. The thick insulating layer 85A of the insulating layer 857 is embedded within the recess 75. Thus, the second corner portion 74B of the second via 70B is covered by the thick insulating layer 85A of the insulating layer 857.

Note that the bottom surface 75A is not limited to a plane orthogonal to the Z direction, and may be a plane intersecting the Z direction. Likewise, the side surface 75B is not limited to a plane along the Z direction and may be a plane intersecting the Z direction.

As shown in FIG. 46, the recess 75 of the second example includes an inclined surface 75C. The inclined surface 75C slopes upward from the side surface 73A of the first via toward the upper surface 71A. The thin insulating layer 85B of the insulating layer 856 covers the inclined surface 75C. The thick insulating layer 85A of the insulating layer 857 is embedded within the recess 75. Thus, the second corner portion 74B of the second via 70B is covered by the thick insulating layer 85A of the insulating layer 857.

As shown in FIG. 47, in the third example, the recess 75 may be formed at a position spaced apart from the side surface 73A of the first via. That is, in the third example, the side surface 856A of the insulating layer 856 does not include the first exposed side surface 85AA shown in FIG. 39. The recess 75 shown in FIG. 47 is recessed in a curved shape downward from the side surface 73A of the first via. The recess 75 includes a curved surface 78. In one example, the recess 75 is annular in plan view. The recess 75 is formed in the plating layer 77A of the first via 70A. On the other hand, the recess 75 is not formed in the seed layer 76A of the first via 70A. The thin insulating layer 85B of the insulating layer 856 covers the curved surface 78 of the recess 75. The thick insulating layer 85A of the insulating layer 857 is embedded within the recess 75. As a result, the second corner portion 74B of the second via 70B is covered by the thick insulating layer 85A of the insulating layer 857.

In the first modification example, the configuration of the second via 70B may be arbitrarily modified. In one example, the protrusion length HA of the extended portion 79 may be equal to or greater than the distance DC between the side surface 856A of the insulating layer 856, which forms the side wall of the first through-hole 88A, and the lower surface 72B of the second via. In this case, the process of embedding the recess 75 with the thick insulating layer 85A may be performed before forming the second via 70B. In another example, the protrusion length HA of the extended portion 79 may be equal to the film thickness of the thin insulating layer 85B of the insulating layer 856.

In the second modification example, the projection 74BA from the second corner portion 74B of the second via 70B may be omitted.

In the first and second modification examples, the shape of the first through-hole 88A may be arbitrarily changed. In one example, the first through-hole 88A may have a constant opening area in the Z direction. That is, the side surface 856A of the insulating layer 856 may extend along the Z direction.

In the first and second modification examples, the planar shapes of the first via 70A and the second via 70B may be arbitrarily modified. In one example, the first via 70A may be rectangular in plan view. In another example, the second via 70B may be rectangular in plan view.

### <Modification of the Signal Transmission Device>

In each embodiment, the configuration of the signal transmission device 10 may be arbitrarily modified.

In one example, the signal transmission device 10 may be configured to transmit signals between the first circuit chip 160 and the second circuit chip 170 via multiple insulating chips 80.

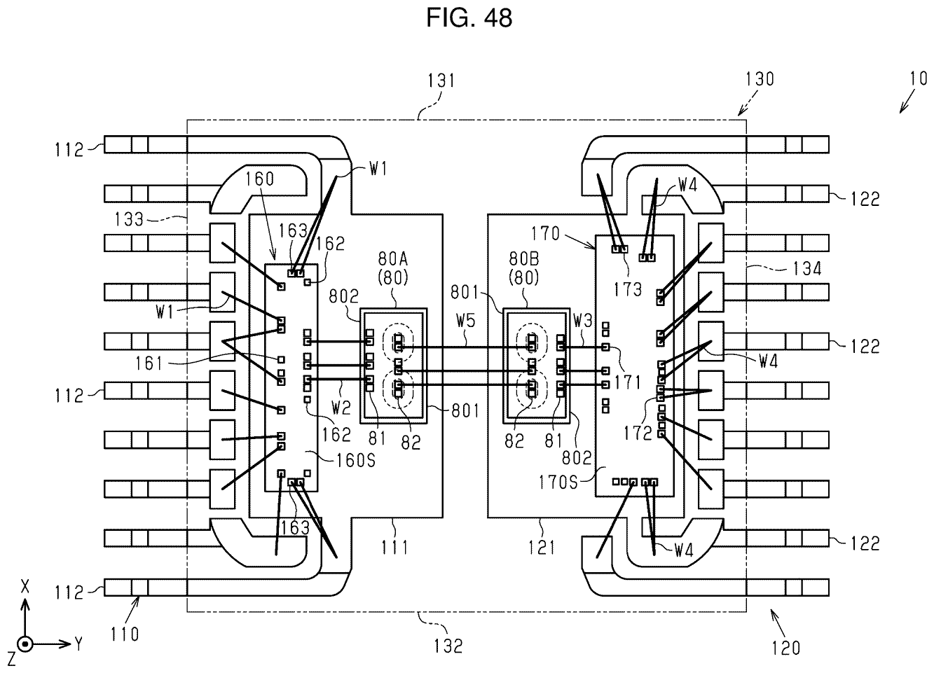

FIG. 48 schematically shows a plan view of the internal structure of the modified signal transmission device 10.

The modified signal transmission device 10 includes a first circuit chip 160, a second circuit chip 170, a first insulating chip 80A, and a second insulating chip 80B. In one example, the first insulating chip 80A and the second insulating chip 80B have the same configuration as the insulating chip 80. The first circuit chip 160, second circuit chip 170, first insulating chip 80A, and second insulating chip 80B are arranged spaced apart from each other in the Y direction. In the example shown in FIG. 48, the components are arranged in the following order from the first lead terminal 112 to the second lead terminal 122: the first circuit chip 160, the first insulating chip 80A, the second insulating chip 80B, and the second circuit chip 170.

Both the first circuit chip 160 and the first insulating chip 80A are mounted on the first die pad 111. Both the second insulating chip 80B and the second circuit chip 170 are mounted on the second die pad 121.

The first electrode pad 81 of the second insulating chip 80B is electrically connected to the second circuit chip 170 by a wire W3. The second electrode pad 82 of the second insulating chip 80B is electrically connected to the second electrode pad 82 of the first insulating chip 80A by a wire W5. In other words, the first insulating chip 80A and the second insulating chip 80B are connected in series between the first circuit chip 160 and the second circuit chip 170.

Since the second insulating chip 80B has the same configuration as the first insulating chip 80A as described above, the second insulating chip 80B has the same insulation withstand voltage as the first insulating chip 80A. Therefore, the signal transmission device 10 has an insulation withstand voltage corresponding to the withstand voltages of the series-connected first insulating chip 80A and second insulating chip 80B.

In each embodiment, at least one of the first circuit chip 160 and the second circuit chip 170 may be omitted from the signal transmission device 10.

One or more of the various examples described in this specification may be combined within a technically consistent scope.

The term “on” used in this disclosure includes both “on” and “above” unless clearly indicated otherwise by the context. Therefore, for example, the expression “a first element is disposed on a second element” may mean that the first element is directly placed in contact with and on the second element in some embodiments, while in other embodiments it may mean that the first element is placed above the second element without contacting it. In other words, the term “on” does not exclude the presence of another element formed between the first and second elements.

The Z-direction used in this disclosure does not necessarily have to be the vertical direction, nor does it have to be perfectly aligned with the vertical direction. Therefore, various structures according to the present disclosure are not limited to cases in which “above” and “below” in the Z-direction correspond to “up” and “down” in the vertical direction. For example, the X-direction or Y-direction may be the vertical direction.

### Supplementary Note

The following describes technical ideas that can be understood from the above embodiments and modification examples. For each supplementary note, reference numerals corresponding to the components in the embodiments are provided in parentheses. These reference numerals are shown as examples to aid understanding and the components in each supplementary note should not be limited to those identified by the numerals.

### [Supplementary Note 1]

An insulating chip (80) includes an insulating body (84) having an insulating upper surface (84S) and an insulating lower surface (84R) opposite to the insulating upper surface (84S), and including a plurality of insulating layers (85) laminated in a thickness direction (Z);
a first conductor (51/41) disposed within the insulating body (84) on the insulating lower surface (84R) side; and a second conductor (52/42) disposed within the insulating body (84) closer to the insulating upper surface (84S) than the first conductor (51), and facing the first conductor (51) in the thickness direction (Z), wherein the second conductor (52/42) includes: a second upper surface (42S) disposed on the insulating upper surface (84S) side; a second lower surface (42R) on the opposite side to the second upper surface (42S); a second side surface (42A) provided between the second upper surface (42S) and the second lower surface (42R) in the thickness direction (Z); and a second corner portion (42C) between the second side surface (42A) and the second upper surface (42S); and wherein the second corner portion (42C) includes a second recess (44) having a second curved surface (44P) recessed so as to be convex inward toward the second conductor (52/42).

### [Supplementary Note 2]

In the insulating chip of Supplementary Note 1, a cross-sectional shape of the second curved surface (44P) is arc-shaped.

### [Supplementary Note 3]

In the insulating chip of Supplementary Note 1 or 2, the second conductor (52/42) has a prescribed width; the second side surface (42A) includes a second inner side surface (42AA) on the inner side in a width direction (X) of the second conductor (52/42), and a second outer side surface (42AB) on the outer side in the width direction (X) of the second conductor (52/42); the second corner portion (42C) includes a second inner corner portion (42CA) between the second inner side surface (42AA) and the second upper surface (42S), and a second outer corner portion (42CB) between the second outer side surface (42AB) and the second upper surface (42S); and the second recess (44) includes a second inner recess (44A) having a second inner curved surface (44PA) provided in the second inner corner portion (42CA), and a second outer recess (44B) having a second outer curved surface (44PB) provided in the second outer corner portion (42CB).

### [Supplementary Note 4]

In the insulating chip of Supplementary Note 3, an arc length of a cross-sectional shape of the second inner curved surface (44PA) is equal to the arc length of a cross-sectional shape of the second outer curved surface (44PB).

### [Supplementary Note 5]

In the insulating chip of any one of Supplementary Notes 1 to 4, the plurality of insulating layers (85) include: a third insulating layer (857) in which the second conductor (52/42) is provided; and a fourth insulating layer (85U) laminated on the third insulating layer (857); both the third insulating layer (857) and the fourth insulating layer (85U) include: a thin insulating layer (85B); and a thick insulating layer (85A) formed on the thin insulating layer (85B) and having a smaller thermal expansion coefficient than the thin insulating layer (85B); and the thin insulating layer (85B) of the fourth insulating layer (85U) includes a second curved portion (85DC) that is in contact with and extends along the second curved surface (44P).

### [Supplementary Note 6]

In the insulating chip of Supplementary Note 5, the thick insulating layer (85A) of the third insulating layer (857) has a side surface (857A) that forms a second groove (86B) in which the second conductor (52/42) is embedded; the side surface (857A) of the thick insulating layer (85A) of the third insulating layer (857) includes a second exposed side surface (85AB) exposed through the second conductor (52/42) by the second recess (44); and the thin insulating layer (85B) of the fourth insulating layer (85U) includes: a second side portion (85DB) that covers the second exposed side surface (85AB) and is connected to the second curved portion (85DC); a second upper portion (85DA) that covers the upper surface (857S) of the thick insulating layer (85A) and is connected to the second side portion (85DC); and a second conductor upper portion (85DD) that covers the second upper surface (42S) of the second conductor (52/42) and is connected to the second curved portion (85DC).

### [Supplementary Note 7]

In the insulating chip of any one of Supplementary Notes 1 to 6, the second conductor (52/42) has a tapered shape in which the second side surface (42A) is inclined such that the second conductor (52/42) becomes narrower from the second upper surface (42S) toward the second lower surface (42R).

### [Supplementary Note 8]

In the insulating chip of any one of Supplementary Notes 1 to 7, the second conductor (52/42) includes: a seed layer (45B); and a plating layer (46B) formed on the seed layer (45B); and the second recess (44) is provided across both the seed layer (45B) and the plating layer (46B).

### [Supplementary Note 9]

In the insulating chip of any one of Supplementary Notes 1 to 8, the first conductor (51/41) includes: a first upper surface (41S); a first lower surface (41R) opposite to the first upper surface (41S); a first side surface (41A) provided between the first upper surface (41S) and the first lower surface (41R) in the thickness direction (Z); and a first corner portion (41C) between the first side surface (41A) and the first upper surface (41S); and the first corner portion (41C) includes a first recess (43) having a first curved surface (43P) recessed so as to be convex inward toward the first conductor (51/41).

### [Supplementary Note 10]

In the insulating chip of Supplementary Note 9, a cross-sectional shape of the first curved surface (43P) is arc-shaped.

### [Supplementary Note 11]

In the insulating chip of Supplementary Note 10, an arc length of the cross-sectional shape of the first curved surface (43P) is equal to an arc length of the cross-sectional shape of the second curved surface (44P).

### [Supplementary Note 12]

In the insulating chip of any one of Supplementary Notes 9 to 11, the first conductor (51/41) has a prescribed width; the first side surface (41A) includes: a first inner side surface (41AA) on an inner side in a width direction (X) of the first conductor (51/41); and a first outer side surface (41AB) on an outer side in the width direction (X) of the first conductor (51/41); the first corner portion (41C) includes: a first inner corner portion (41CA) between the first inner side surface (41AA) and the first upper surface (41S); and a first outer corner portion (41CB) between the first outer side surface (41AB) and the first upper surface (41S); and the first recess (43) includes: a first inner recess (43A) including a first inner curved surface (43PA) provided in the first inner corner portion (41CA); and a first outer recess (43B) having a first outer curved surface (43PB) provided in the first outer corner portion (41CB).

### [Supplementary Note 13]

In the insulating chip of Supplementary Note 12, an arc length of an cross-sectional shape of the first inner curved surface (43PA) is equal to an arc length of the cross-sectional shape of an first outer curved surface (43PB).

### [Supplementary Note 14]

In the insulating chip of any one of Supplementary Notes 9 to 13, the plurality of insulating layers (85) include: a first insulating layer (853) in which the first conductor (51/41) is provided; and a second insulating layer (854) laminated on the first insulating layer (853); both the first insulating layer (853) and the second insulating layer (854) include: a thin insulating layer (85B); and a thick insulating layer (85A) provided on the thin insulating layer (85B) and having a smaller coefficient of thermal expansion than the thin insulating layer (85B); and the thin insulating layer (85B) of the second insulating layer (854) includes a first curved portion (85CC) in contact with and extending along the first curved surface (43P).

### [Supplementary Note 15]

In the insulating chip of Supplementary Note 14, the thick insulating layer (85A) of the first insulating layer (853) has a side surface (853A) forming a first trench (86A) in which the first conductor (51/41) is embedded; the side surface (853A) of the thick insulating layer (85A) of the first insulating layer (853) includes a first exposed side surface (85AA) exposed through the first conductor (51/41) by the first recess (43); and the thin insulating layer (85B) of the second insulating layer (854) includes: a first side surface portion (85CB) that covers the first exposed side surface (85AA) and is connected to the first curved portion (85CC); a first upper surface portion (85CA) that covers an upper surface (853S) of the thick insulating layer (85A) of the first insulating layer (853) and is connected to the first side surface portion (85CB); and a first conductor upper surface portion (85CD) that covers the first upper surface (41S) of the first conductor (51/41) and is connected to the first curved portion (85CC).

### [Supplementary Note 16]

In the insulating chip of any one of Supplementary Notes 9 to 15, the first conductor (51/41) is tapered such that the first side surface (41A) is inclined from the first upper surface (41S) toward the first lower surface (41R).

### [Supplementary Note 17]

In the insulating chip of any one of Supplementary Notes 9 to 16, the first conductor (51/41) includes: a seed layer (45A); and a plating layer (46A) provided on the seed layer (45A); and the first recess (43) is provided across both the seed layer (45A) and the plating layer (46A).

### [Supplementary Note 18]

In the insulating chip of any one of Supplementary Notes 1 to 17, the first conductor (51) and the second conductor (52) include coils (41, 42).

### [Supplementary Note 19]

In the insulating chip of Supplementary Note 18, the second conductor (52/42) includes: a pair of second straight portions (42D); and a pair of second curved portions (42E) connecting both ends of the pair of second straight portions (42D); and the second recess (44) is provided continuously along both the pair of second straight portions (42D) and the pair of second curved portions (42E).

### [Supplementary Note 20]

In the insulating chip of any one of Supplementary Notes 9 to 16, the first conductor (51) and the second conductor (52) include coils (41, 42); the first conductor (51/41) includes: a pair of first straight portions (41D); and a pair of first curved portions (41E) connecting both ends of the pair of first straight portions (41D); and the first recess (43) is provided continuously along both the pair of first straight portions (41D) and the pair of first curved portions (41E).

### [Supplementary Note 21]

In the insulating chip of any one of Supplementary Notes 1 to 17, the first conductor (51) and the second conductor (52) include electrode plates (201, 202).

### [Supplementary Note 22]

In the insulating chip of any one of Supplementary Notes 1 to 21, the chip includes: a first electrode pad (81) electrically connected to the first conductor (51/41); a second electrode pad (82) electrically connected to the second conductor (52/42); and a connection wiring (60/60A) provided within the insulating body (84) and connecting the first conductor (51/41) and the first electrode pad (81), the connection wiring (60/60A) includes: a first wiring portion (61A) connected to the first electrode pad (81) and extending in the thickness direction (Z); and a second wiring portion (66A) connected to the first conductor (51/51A) and extending outward of the first conductor (51/41) in plan view; and the first wiring portion (61A) includes: a first-layer wiring (62A) provided at the same position in the thickness direction (Z) as the first conductor (51/41, 51A) and electrically connected to the second wiring portion (66A); a second-layer wiring (63A) provided at the same position in the thickness direction (Z) as the second conductor (52/42); a through wiring (64A) provided between the first-layer wiring (62A) and the second-layer wiring (63A) in the thickness direction (Z); and a surface-side via wiring (65A) connecting the second-layer wiring (63A) and the first electrode pad (81).

### [Supplementary Note 23]

In the insulating chip of Supplementary Note 22, the second wiring portion (66A) is disposed, in the thickness direction (Z), across the first conductor (51/41) from the second conductor (52/42); and the second wiring portion (66A) includes: a lead-out wiring (67A) extending in a direction orthogonal to the thickness direction (Z); a first backside via wiring (68A) connecting the first-layer wiring (62A) and the lead-out wiring (67A); and a second backside via wiring (69A) connecting the first conductor (51/51A) and the lead-out wiring (67A).

### [Supplementary Note 24]

In the insulating chip of Supplementary Note 22 or 23, the second-layer wiring (63A) includes: a second wiring upper surface (63AS); a second wiring lower surface (63AR) opposite to the second wiring upper surface (63AS); a second wiring side surface (63AA) connecting the second wiring upper surface (63AS) and the second wiring lower surface (63AR); and a second wiring corner portion (63AD) between the second wiring side surface (63AA) and the second wiring upper surface (63AS); and the second wiring corner portion (63AD) includes a fourth recess (63AE) having a fourth curved surface (63AP) recessed so as to be convex inward toward the second-layer wiring (63A).

### [Supplementary Note 25]

In the insulating chip of Supplementary Note 24, a cross-sectional shape of the fourth curved surface (63AP) is arc-shaped.

### [Supplementary Note 26]

In the insulating chip of Supplementary Note 25, an arc length of the cross-sectional shape of the fourth curved surface (63AP) is equal to an arc length of the cross-sectional shape of the second curved surface (44P).

### [Supplementary Note 27]

In the insulating chip of any one of Supplementary Notes 24 to 26, the plurality of insulating layers (85) include: a third insulating layer (857) in which both the second conductor (52/42) and the second-layer wiring (63A) are provided; and a fourth insulating layer (85U) laminated on the third insulating layer (857); each of the third insulating layer (857) and the fourth insulating layer (85U) includes: a thin insulating layer (85B); and
a thick insulating layer (85A) provided on the thin insulating layer (85B) and having a smaller coefficient of thermal expansion than the thin insulating layer (85B), and the thin insulating layer (85B) of the fourth insulating layer (85U) includes a fourth curved portion (85FC) in contact with and extending along the fourth curved surface (63AP).

### [Supplementary Note 28]

In the insulating chip of Supplementary Note 27, the thick insulating layer (85A) of the third insulating layer (857) includes a side surface (857B) forming a through-hole (87B) in which the second-layer wiring (63A) is embedded; the side surface (857B) of the thick insulating layer (85A) of the third insulating layer (857) includes a fourth exposed side surface (85AD) exposed from the second-layer wiring (63A) due to the fourth recess (63AE);
and the thin insulating layer (85B) of the fourth insulating layer (85U) includes: a fourth side surface portion (85FB) covering the fourth exposed side surface (85AD) and connected to the fourth curved portion (85FC); a fourth upper surface portion (85FA) covering the upper surface (857S) of the thick insulating layer (85A) of the third insulating layer (857) and connected to the fourth side surface portion (85FB); and a second wiring upper surface portion (85FD) covering the second wiring upper surface (63AS) of the second-layer wiring (63A) and connected to the fourth curved portion (85FC).

### [Supplementary Note 29]

In the insulating chip of any one of Supplementary Notes 24 to 28, the second-layer wiring (63A) is tapered such that the second wiring side surface (63AA) is inclined from the second wiring upper surface (63AS) toward the second wiring lower surface (63AR).

### [Supplementary Note 30]

In the insulating chip of Supplementary Note 22 or 23, the first-layer wiring (62A) includes:
a first wiring upper surface (62AS); a first wiring lower surface (62AR) opposite to the first wiring upper surface (62AS); a first wiring side surface (62AA) connecting the first wiring upper surface (62AS) and the first wiring lower surface (62AR); and a first wiring corner portion (62AD) between the first wiring side surface (62AA) and the first wiring upper surface (62AS); and the first wiring corner portion (62AD) includes a third recess (62AE) having a third curved surface (62AP) recessed so as to be convex inward toward the first-layer wiring (62A).

### [Supplementary Note 31]

In the insulating chip of Supplementary Note 30, a cross-sectional shape of the third curved surface (62AP) is arc-shaped.

### [Supplementary Note 32]

In the insulating chip of Supplementary Note 31, an arc length of the cross-sectional shape of the third curved surface (62AP) is equal to an arc length of the cross-sectional shape of the second curved surface (44P).

### [Supplementary Note 33]

In the insulating chip of any one of Supplementary Notes 30 to 32, the plurality of insulating layers (85) include: a first insulating layer (853) in which both the first conductor (51/41) and the first-layer wiring (62A) are provided; and a second insulating layer (854) laminated on the first insulating layer (853), each of the first insulating layer (853) and the second insulating layer (854) includes: a thin insulating layer (85B); and a thick insulating layer (85A) provided on the thin insulating layer (85B) and having a smaller coefficient of thermal expansion than the thin insulating layer (85B); and the thin insulating layer (85B) of the second insulating layer (854) includes a third curved portion (85EC) in contact with and extending along the third curved surface (62AP).

### [Supplementary Note 34]

In the insulating chip of Supplementary Note 33, the thick insulating layer (85A) of the first insulating layer (853) includes a side surface (853B) forming a through-hole (87A) in which the first-layer wiring (62A) is embedded; the side surface (853B) of the thick insulating layer (85A) of the first insulating layer (853) includes a third exposed side surface (85AC) exposed through the first-layer wiring (62A) by the third recess (62AE); and the thin insulating layer (85B) of the second insulating layer (854) includes: a third side surface portion (85EB) covering the third exposed side surface (85AC) and connected to the third curved portion (85EC); a third upper surface portion (85EA) covering the upper surface (853S) of the thick insulating layer (85A) of the first insulating layer (853) and connected to the third side surface portion (85EB); and a first wiring upper surface portion (85ED) covering the first wiring upper surface (62AS) of the first-layer wiring (62A) and connected to the third curved portion (85EC).

### [Supplementary Note 35]

In the insulating chip of any one of Supplementary Notes 30 to 34, the first wiring side surface (62AA) of the first-layer wiring (62A) is inclined so as to taper from the first wiring upper surface (62AS) toward the first wiring lower surface (62AR).

### [Supplementary Note 36]

In the insulating chip of any one of Supplementary Notes 1 to 35, the insulating body (84) includes a sealing portion (93) provided on the outer peripheral portion thereof and surrounding the first conductor (51/41) and the second conductor (52/42) in plan view; and
the sealing portion (93) includes: a first sealing portion (94) provided at the same position as the first conductor (51/41) in the thickness direction (Z); a second sealing portion (95) provided at the same position as the second conductor (52/42) in the thickness direction (Z); and a connecting sealing portion (96) connecting the first sealing portion (94) and the second sealing portion (95) in the thickness direction (Z).

### [Supplementary Note 37]

In the insulating chip of Supplementary Note 36, the second sealing portion (95) includes: a second sealing upper surface (95S); a second sealing lower surface (95R) opposite to the second sealing upper surface (95S); a second sealing side surface (95A) connecting the second sealing upper surface (95S) and the second sealing lower surface (95R); and
a second sealing corner portion (95C) between the second sealing side surface (95A) and the second sealing upper surface (95S), and the second sealing corner portion (95C) includes a sixth recess (95CA) having a sixth curved surface (95CP) recessed so as to be convex inward toward the second sealing portion (95).

### [Supplementary Note 38]

In the insulating chip of Supplementary Note 37, a cross-sectional shape of the sixth curved surface (95CP) is arc-shaped.

### [Supplementary Note 39]

In the insulating chip of Supplementary Note 38, an arc length of the cross-sectional shape of the sixth curved surface (95CP) is equal to an arc length of the cross-sectional shape of the second curved surface (44P).

### [Supplementary Note 40]

In the insulating chip of any one of Supplementary Notes 37 to 39, the plurality of insulating layers (85) include: a third insulating layer (857) in which both the second conductor (52/42) and the second sealing portion (95) are provided; and a fourth insulating layer (85U) laminated on the third insulating layer (857), each of the third insulating layer (857) and the fourth insulating layer (85U) includes: a thin insulating layer (85B); and
a thick insulating layer (85A) provided on the thin insulating layer (85B) and having a smaller coefficient of thermal expansion than the thin insulating layer (85B); and the thin insulating layer (85B) of the fourth insulating layer (85U) includes a sixth curved portion (85HC) in contact with and extending along the sixth curved surface (95CP).

### [Supplementary Note 41]

In the insulating chip of Supplementary Note 40, the thick insulating layer (85A) of the third insulating layer (857) has a side surface (857C) that defines a through hole (89B) in which the second sealing portion (95) is embedded; the side surface (857C) includes a sixth exposed side surface (85AF) exposed from the second sealing portion (95) by the sixth recess (95CA); the thin insulating layer (85B) of the fourth insulating layer (857) includes:
a sixth side portion (85HB) that covers the sixth exposed side surface (85AF) and connects to the sixth curved portion (85HC); a sixth upper portion (85HA) that covers the upper surface (857S) of the thick insulating layer (85A) of the third insulating layer (857) and connects to the sixth side portion (85HB); and a second sealing upper portion (85HD) that covers the second sealing upper surface (95S) of the second sealing portion (95) and connects to the sixth curved portion (85HC).

### [Supplementary Note 42]

In the insulating chip of any one of Supplementary Notes 37 to 41, the second sealing portion (95) has a tapered shape in which the second sealing side surface (95A) is inclined to taper from the second sealing upper surface (95S) toward the second sealing lower surface (95R).

### [Supplementary Note 43]

In the insulating chip of any one of Supplementary Notes 36 to 42, the first sealing portion (94) includes: a first sealing upper surface (94S); a first sealing lower surface (94R) opposite to the first sealing upper surface (94S); a first sealing side surface (94A) connecting the first sealing upper surface (94S) and the first sealing lower surface (94R); and a first sealing corner portion (94C) between the first sealing side surface (94A) and the first sealing upper surface (94S), and the first sealing corner portion (94C) includes a fifth recess (94CA) having a fifth curved surface (94CP) recessed so as to be convex inward toward the first sealing portion (94).

### [Supplementary Note 44]

In the insulating chip of Supplementary Note 43, a cross-sectional shape of the fifth curved surface (94CP) is arc-shaped.

### [Supplementary Note 45]

In the insulating chip of Supplementary Note 44, an arc length of the cross-sectional shape of the fifth curved surface (94CP) is equal to an arc length of the cross-sectional shape of the second curved surface (44P).

### [Supplementary Note 46]

In the insulating chip of any one of Supplementary Notes 43 to 45, the plurality of insulating layers (85) include: a first insulating layer (853) in which both the first conductor (51/41) and the first sealing portion (94) are provided; and a second insulating layer (854) laminated on the first insulating layer (853); each of the first insulating layer (853) and the second insulating layer (854) includes: a thin insulating layer (85B); and a thick insulating layer (85A) provided on the thin insulating layer (85B) and having a smaller coefficient of thermal expansion than the thin insulating layer (85B); and the thin insulating layer (85B) of the second insulating layer (854) includes a fifth curved portion (85GC) in contact with and extending along the fifth curved surface (94CP).

### [Supplementary Note 47]

In the insulating chip of Supplementary Note 46, the thick insulating layer (85A) of the first insulating layer (853) includes a side surface (853C) that defines a through hole (89A) in which the first sealing portion (94) is embedded; the side surface (853C) includes a fifth exposed side surface (85AE) exposed from the first sealing portion (94) by the fifth recess (94CA); the thin insulating layer (85B) of the second insulating layer (854) includes: a fifth side portion (85GB) that covers the fifth exposed side surface (85AE) and connects to the fifth curved portion (85GC); a fifth upper portion (85GA) that covers the upper surface (853S) of the thick insulating layer (85A) of the first insulating layer (853) and connects to the fifth side portion (85GB); and a first sealing upper portion (85GD) that covers the first sealing upper surface (94S) of the first sealing portion (94) and connects to the fifth curved portion (85GC).

### [Supplementary Note 48]

In the insulating chip of any one of Supplementary Notes 43 to 47, the first sealing portion (94) has a tapered shape in which the first sealing side surface (94A) is inclined to taper from the first sealing upper surface (94S) toward the first sealing lower surface (94R).

### [Supplementary Note 49]

In the insulating chip of Supplementary Note 1 or 2, the second recess (44) is arc-shaped about an intersection point (CA2, CB2) of a third virtual line (L3) along the second upper surface (42S) and a fourth virtual line (LA4, LB4) along the second side surface (42A).

### [Supplementary Note 50]

In the insulating chip of Supplementary Note 9 or 10, the first recess (43) is arc-shaped about an intersection point (CA1, CB1) of a first virtual line (L1) along the first upper surface (41S) and a second virtual line (LA2, LB2) along the first side surface (41A).

### [Supplementary Note 51]

In the insulating chip of any one of Supplementary Notes 1 to 21, the insulating chip further includes: a first electrode pad (81) electrically connected to the first conductor (51/41); a second electrode pad (82) electrically connected to the second conductor (52/42); and
a connection wiring (60/60A) provided in the insulating body (84) and connecting the first conductor (51/41) to the first electrode pad (81), the connection wiring (60/60A) includes: a first wiring portion (61A) that is connected to the first electrode pad (81) and extends in the thickness direction (Z); and a second wiring portion (66A) that is connected to the first conductor (51/41) and extends outward of the first conductor (51/41) in plan view; and the first wiring portion (61A) includes: a first-layer wiring (62A) provided at the same position as the first conductor (51/41, 51A) in the thickness direction (Z) and electrically connected to the second wiring portion (66A); a second-layer wiring (63A) provided at the same position as the second conductor (52/42) in the thickness direction (Z); a through wiring (64A) provided between the first-layer wiring (62A) and the second-layer wiring (63A) in the thickness direction (Z); and a surface-side via wiring (65A) connecting the second-layer wiring (63A) and the first electrode pad (81).

### [Supplementary Note 52]

In the insulating chip of Supplementary Note 51, the through wiring (64A) includes: a first via (70A) provided in the insulating body (84); and a second via (70B) provided on the first via (70A) in the insulating body (84); the first via (70A) includes: a first via upper surface (71A) disposed on the insulating upper surface (84S) side; a first via lower surface (72A) opposite to the first via upper surface (71A); and a first via side surface (73A) between the first via upper surface (71A) and the first via lower surface (72A) in the thickness direction (Z); the second via (70B) includes: a second via upper surface (71B) disposed on the insulating upper surface (84S) side; and a second via lower surface (72B) on the opposite side, in contact with the first via upper surface (71A); the plurality of insulating layers (85) include: a first via insulating layer (856) in which the first via (70A) is embedded; and
a second via insulating layer (857) laminated on the first via insulating layer (856) and in which the second via (70B) is embedded; both the first and second via insulating layers (856, 857) include: a thin insulating layer (85B) formed of a material having a smaller thermal expansion coefficient than each of the first and second vias (70A, 70B); and a thick insulating layer (85A) formed of a material having a smaller thermal expansion coefficient than the thin insulating layer (85B), and laminated on the thin insulating layer (85B); the second via lower surface (72B) includes an extension portion (79) that protrudes beyond the first via upper surface (71A) in plan view; and an end of the extension portion (79) is in contact with the thick insulating layer (85A) of the second via insulating layer (857).

### [Supplementary Note 53]

In the insulating chip of Supplementary Note 52, the first via (70A) includes a first corner portion (74A) provided between the first via upper surface (71A) and the first via side surface (73A); a recess (75) is provided in the first corner portion (74A); and the first via upper surface (71A) is smaller than the second via lower surface (72B) due to the recess (75).

### [Supplementary Note 54]

In the insulating chip of Supplementary Note 53, the recess (75) includes a curved surface (78) recessed so as to be convex inward toward the first via (70A).

### [Supplementary Note 55]

In the insulating chip of Supplementary Note 54, the cross-sectional shape of the curved surface (78) is arc-shaped.

### [Supplementary Note 56]

In the insulating chip of Supplementary Note 54 or 55, the thin insulating layer (85B) of the second via insulating layer (857) is in contact with the curved surface (78).

### [Supplementary Note 57]

In the insulating chip of any one of Supplementary Notes 53 to 56, the second via (70B) includes a second via side surface (73B) connecting the second via upper surface (71B) and the second via lower surface (72B); the protrusion length (HA) of the extension portion (79) is greater than the thickness (TB) of the thin insulating layer (85B) of the second via insulating layer (857); and the thin insulating layer (85B) of the second via insulating layer (857) is in contact with a portion of the second via lower surface (72B) that is inward of the second via side surface (73B).

### [Supplementary Note 58]

In the insulating chip of Supplementary Note 57, the thick insulating layer (85A) of the second via insulating layer (857) is in contact with the outer edge of the second via lower surface (72B) and extends continuously along the second via side surface (73B) from the outer edge.

### [Supplementary Note 59]

In the insulating chip of Supplementary Note 58, the thick insulating layer (85A) of the second via insulating layer (857) is embedded in the recess (75).

### [Supplementary Note 60]

In the insulating chip of any one of Supplementary Notes 54 to 59, the first via insulating layer (856) includes a side surface (856A) that defines a through-hole (88A) in which the first via (70A) is embedded; and the protrusion length (HA) of the extension portion (79) is at the same position in the thickness direction (Z) as the upper surface (856S) of the first via insulating layer (856), and is smaller than the distance (DC) between the side surface (856A) and the second via lower surface (72B) in plan view.

### [Supplementary Note 61]

In the insulating chip of Supplementary Note 60, the upper surface (856S) of the first via insulating layer (856) is at the same position in the thickness direction (Z) as the first via upper surface (71A); and the thin insulating layer (85B) of the second via insulating layer (857) includes an upper surface portion (85LA) laminated on the upper surface (856S) of the first via insulating layer (856); the upper surface portion (85LA) faces the second corner portion (74B) formed by the extension portion (79) and the second via side surface (73B) of the second via (70B).

### [Supplementary Note 62]

In the insulating chip of Supplementary Note 61, the upper surface portion (85LA) is spaced apart from the second corner portion (74B), and a thick insulating layer (85A) of the second via insulating layer (857) is interposed between the upper surface portion (85LA) and the second corner portion (74B).

### [Supplementary Note 63]

In the insulating chip of any one of Supplementary Notes 60 to 62, the side surface (856A) of the first via insulating layer (856) is inclined such that the opening area decreases from the upper surface (856S) toward the lower surface (856R), and the first via side surface (73A) is provided along the side surface (856A) of the first via insulating layer (856).

### [Supplementary Note 64]

In the insulating chip of Supplementary Note 63, the side surface (856A) of the first via insulating layer (856) includes an exposed side surface (85AA) that is exposed from the first via side surface (73A) by the recess (75), and the thin insulating layer (85B) of the second via insulating layer (857) is provided along the exposed side surface (85AA).

### [Supplementary Note 65]

In the insulating chip of any one of Supplementary Notes 53 to 64, the first via (70A) includes a seed layer (76A) and a plating layer (77A) formed on the seed layer (76A), and the recess (75) is provided across both the seed layer (76A) and the plating layer (77A).

### [Supplementary Note 66]

In the insulating chip of Supplementary Note 52, the second via (70B) includes a second via side surface (73B) connecting the second via upper surface (71B) and the second via lower surface (72B), and a second corner portion (74B) including the extension portion (79) and the second via side surface (73B); the second corner portion (74B) includes a protruding portion (74BA) extending toward the first via lower surface (72A) side with respect to the first via upper surface (71A); the extension portion (79) forms the lower surface of the protruding portion (74BA); and the side surface (85LE) of the thin insulating layer (85B) of the second via insulating layer (857) is in contact with the second via side surface (73B) while being spaced from the extension portion (79) in the thickness direction (Z).

### [Supplementary Note 67]

In the insulating chip of Supplementary Note 66, the thick insulating layer (85A) of the first via insulating layer (856) extends from the extension portion (79), which constitutes the protruding portion (74BA), to the second via side surface (73B).

### [Supplementary Note 68]

In the insulating chip of any one of Supplementary Notes 52 to 67, both the first via (70A) and the second via (70B) are provided to penetrate through a plurality of the thick insulating layers (85A) and a plurality of the thin insulating layers (85B).

### [Supplementary Note 69]

In the insulating chip of Supplementary Note 68, the thickness of the first via (70A) is greater than the thickness of the second via (70B).

### [Supplementary Note 70]

In the insulating chip of any one of Supplementary Notes 52 to 69, the thick insulating layer (85A) is formed of a material including SiO, and the thin insulating layer (85B) is formed of a material including SiN.

### [Supplementary Note 71]

A signal transmission device (10) includes the insulating chip (80) of any one of Supplementary Notes 1 to 70, and a first circuit (20) and a second circuit (30) electrically connected to the insulating chip (80), and the first circuit (20) and the second circuit (30) are configured to transmit signals via the insulating chip (80).

### [Supplementary Note 72]

In the signal transmission device of Supplementary Note 71, the second circuit (30) includes a driver circuit that drives the gate of a switching element.

### [Supplementary Note 73]

An insulating chip (80) includes: an insulating body (84) having an insulating upper surface (84S) and an insulating lower surface (84R) opposite to the insulating upper surface (84S), and including a plurality of insulating layers (85) laminated in the thickness direction (Z); a first conductor (51/41) disposed on the insulating lower surface (84R) side within the insulating body (84); and a second conductor (52/42) disposed within the insulating body (84) closer to the insulating upper surface (84S) than the first conductor (51/41), and facing the first conductor (51/41) in the thickness direction (Z), wherein the first conductor (51/41) includes: a first upper surface (41S) disposed on the insulating upper surface (84S) side; a first lower surface (41R) on the opposite side of the first upper surface (41S); a first side surface (41A) connecting the first upper surface (41S) and the first lower surface (41R); and a first corner portion (41C) between the first side surface (41A) and the first upper surface (41S), and the first corner portion (41C) includes a first recess (43) having a first curved surface (43P) recessed so as to be convex inward toward the first conductor (51/41).

### [Supplementary Note 74]

An insulating chip includes: an insulating body (84) having an insulating upper surface (84S) and an insulating lower surface (84R) opposite to the insulating upper surface (84S), and including a plurality of insulating layers (85) laminated in the thickness direction (Z); a first conductor (51/41) disposed on the insulating lower surface (84R) side within the insulating body (84); a second conductor (52/42) disposed within the insulating body (84) closer to the insulating upper surface (84S) than the first conductor (51/41), and facing the first conductor (51/41) in the thickness direction (Z); a first electrode pad (81) electrically connected to the first conductor (51/41); a second electrode pad (82) electrically connected to the second conductor (52/42); and a connection wiring (60/60A) provided in the insulating body (84) to connect the first conductor (51/41) and the first electrode pad (81), wherein the connection wiring (60/60A) includes: a first wiring portion (61A) extending in the thickness direction (Z) and connected to the first electrode pad (81); and a second wiring portion (66A) extending outward in a plan view and connected to the first conductor (51/41); the first wiring portion (61A) includes: a first layer wiring (62A) disposed in the same position as the first conductor (51/41) in the thickness direction (Z) and electrically connected to the second wiring portion (66A); a second layer wiring (63A) disposed in the same position as the second conductor (52/42) in the thickness direction (Z); a through wiring (64A) provided between the first layer wiring (62A) and the second layer wiring (63A) in the thickness direction (Z); and a surface-side via wiring (65A) connecting the second layer wiring (63A) and the first electrode pad (81); wherein the first layer wiring (62A) includes: a first wiring upper surface (62AS);
a first wiring lower surface (62AR) opposite to the first wiring upper surface (62AS);
a first wiring side surface (62AA) connecting the first wiring upper surface (62AS) and the first wiring lower surface (62AR); and a first wiring corner portion (62AD) between the first wiring side surface (62AA) and the first wiring upper surface (62AS); and wherein the first wiring corner portion (62AD) includes a third recess (62AE) having a third curved surface (62AP) recessed so as to be convex inward toward the first layer wiring (62A).

### [Supplementary Note 75]

An insulating chip includes: an insulating body (84) having an insulating upper surface (84S) and an insulating lower surface (84R) opposite to the insulating upper surface (84S), and including a plurality of insulating layers (85) laminated in the thickness direction (Z); a first conductor (51/41) disposed on the insulating lower surface (84R) side within the insulating body (84); a second conductor (52/42) disposed within the insulating body (84) closer to the insulating upper surface (84S) than the first conductor (51/41), and facing the first conductor (51/41) in the thickness direction (Z); a first electrode pad (81) electrically connected to the first conductor (51); a second electrode pad (82) electrically connected to the second conductor (52); and a connection wiring (60/60A) provided in the insulating body (84) to connect the first conductor (51/41) and the first electrode pad (81), wherein the connection wiring (60/60A) includes: a first wiring portion (61A) extending in the thickness direction (Z) and connected to the first electrode pad (81); and a second wiring portion (66A) extending outward in a plan view and connected to the first conductor (51/41); the first wiring portion (61A) includes: a first layer wiring (62A) disposed in the same position as the first conductor (51/41) in the thickness direction (Z) and electrically connected to the second wiring portion (66A); a second layer wiring (63A) disposed in the same position as the second conductor (52/42) in the thickness direction (Z); a through wiring (64A) provided between the first layer wiring (62A) and the second layer wiring (63A) in the thickness direction (Z); and a surface-side via wiring (65A) connecting the second layer wiring (63A) and the first electrode pad (81); wherein the second layer wiring (63A) includes: a second wiring upper surface (63AS);
a second wiring lower surface (63AR) opposite to the second wiring upper surface (63AS);
a second wiring side surface (63AA) connecting the second wiring upper surface (63AS) and the second wiring lower surface (63AR); and a second wiring corner portion (63AD) between the second wiring side surface (63AA) and the second wiring upper surface (63AS), and wherein the second wiring corner portion (63AD) includes a fourth recess (63AE) having a fourth curved surface (63AP) recessed so as to be convex inward toward the second layer wiring (63A).

### [Supplementary Note 76]

An insulating chip includes: an insulating body (84) having an insulating upper surface (84S) and an insulating lower surface (84R) opposite to the insulating upper surface (84S), and including a plurality of insulating layers (85) laminated in the thickness direction (Z); a first conductor (51/41) disposed on the insulating lower surface (84R) side within the insulating body (84); a second conductor (52/42) disposed within the insulating body (84) closer to the insulating upper surface (84S) than the first conductor (51/41), and facing the first conductor (51/41) in the thickness direction (Z); and a seal portion (93) provided on an outer peripheral portion of the insulating body (84) and surrounding the first conductor (51/41) and the second conductor (52/42) in plan view, wherein the seal portion (93) includes: a first seal portion (94) provided in the same position as the first conductor (51/41) in the thickness direction (Z); a second seal portion (95) provided in the same position as the second conductor (52/42) in the thickness direction (Z); and a connection seal portion (96) connecting the first seal portion (94) and the second seal portion (95) in the thickness direction (Z); the first seal portion (94) includes: a first seal upper surface (94S); a first seal lower surface (94R) opposite to the first seal upper surface (94S); a first seal side surface (94A) connecting the first seal upper surface (94S) and the first seal lower surface (94R); and a first seal corner portion (94C) between the first seal side surface (94A) and the first seal upper surface (94S), and the first seal corner portion (94C) includes a fifth recess (94CA) having a fifth curved surface (94CP) recessed so as to be convex inward toward the first seal portion (94).

### [Supplementary Note 77]

An insulating chip includes: an insulating body (84) having an insulating upper surface (84S) and an insulating lower surface (84R) opposite to the insulating upper surface (84S), and including a plurality of insulating layers (85) laminated in the thickness direction (Z);
a first conductor (51/41) disposed on the insulating lower surface (84R) side within the insulating body (84); a second conductor (52/42) disposed within the insulating body (84) closer to the insulating upper surface (84S) than the first conductor (51/41), and facing the first conductor (51/41) in the thickness direction (Z); and a seal portion (93) provided on an outer peripheral portion of the insulating body (84) and surrounding the first conductor (51/41) and the second conductor (52/42) in plan view, wherein the seal portion (93) includes: a first seal portion (94) provided in the same position as the first conductor (51/41) in the thickness direction (Z); a second seal portion (95) provided in the same position as the second conductor (52/42) in the thickness direction (Z); and a connection seal portion (96) connecting the first seal portion (94) and the second seal portion (95) in the thickness direction (Z), the second seal portion (95) includes: a second seal upper surface (95S); a second seal lower surface (95R) opposite to the second seal upper surface (95S); a second seal side surface (95A) connecting the second seal upper surface (95S) and the second seal lower surface (95R); and a second seal corner portion (95C) between the second seal side surface (95A) and the second seal upper surface (95S), and the second seal corner portion (95C) includes a sixth recess (95CA) having a sixth curved surface (95CP) recessed so as to be convex inward toward the second seal portion (95).

### [Supplementary Note 78]

A method of manufacturing an insulating chip includes: forming an insulating body (84) having an insulating upper surface (84S) and an insulating lower surface (84R) opposite to the insulating upper surface (84S), by laminating a plurality of insulating layers (85) in the thickness direction (Z); forming a first conductor (51/41) in a position within the insulating body (84) on the insulating lower surface (84R) side; and forming a second conductor (52/42) in a position within the insulating body (84) closer to the insulating upper surface (84S) than the first conductor (51/41), and facing the first conductor (51/41) in the thickness direction (Z), wherein the second conductor (52/42) includes: a second upper surface (42S) disposed on the insulating upper surface (84S) side; a second lower surface (42R) opposite to the second upper surface (42S); a second side surface (42A) between the second upper surface (42S) and the second lower surface (42R); and a second corner portion (42C) between the second side surface (42A) and the second upper surface (42S); and forming the second conductor (52/42) includes forming a second recess (44) including a second curved surface (44P) recessed so as to be convex inward toward the second conductor (52/42) in the second corner portion (42C).

### [Supplementary Note 79]

In the method of manufacturing the insulating chip of Supplementary Note 78, forming the insulating body (84) includes forming a third insulating layer (857) in which the second conductor (52/42) is provided; forming the third insulating layer (857) includes: forming a thin insulating layer (85B); forming a thick insulating layer (85A), which is provided on the thin insulating layer (85B) and has a smaller thermal expansion coefficient than the thin insulating layer (85B); forming the second conductor (52/42) includes: forming a second groove (86B) in the third insulating layer (857); forming a conductive layer (700) in the second groove (86B); etching the thick insulating layer (85A) of the third insulating layer (857) to cause the conductive layer (700) to protrude from the thick insulating layer (85A); and forming the second recess (44) in the second corner portion (42C) includes isotropically etching the conductive layer (700) to remove the protruding portion of the conductive layer (700) and form the second recess (44).

### [Supplementary Note 80]

In the method of manufacturing the insulating chip of Supplementary Note 79, forming the insulating body (84) includes forming a fourth insulating layer (85U) laminated on the third insulating layer (857); and forming the fourth insulating layer (85U) includes forming a thin insulating layer (85B) to cover the third insulating layer (857), the second recess (44), and the second upper surface (42S).

What is claimed is:

1. An insulating chip, comprising:
an insulating body having an insulating upper surface and an insulating lower surface opposite to the insulating upper surface, the insulating body including a plurality of insulating layers laminated in a thickness direction;
a first conductor disposed within the insulating body on an insulating lower surface side; and
a second conductor disposed within the insulating body closer to the insulating upper surface than to the first conductor, and facing the first conductor in the thickness direction;
wherein the second conductor includes:
a second upper surface disposed on an insulating upper surface side;
a second lower surface on an opposite side to the second upper surface;
a second side surface provided between the second upper surface and the second lower surface in the thickness direction; and
a second corner portion between the second side surface and the second upper surface; and
wherein the second corner portion includes a second recess having a second curved surface recessed so as to be convex inward toward the second conductor.

2. The insulating chip according to claim 1, wherein a cross-sectional shape of the second curved surface is arc-shaped.

3. The insulating chip according to claim 1, wherein:
the second conductor has a prescribed width;
the second side surface includes a second inner side surface on an inner side in a width direction of the second conductor, and a second outer side surface on an outer side in the width direction of the second conductor;
the second corner portion includes a second inner corner portion between the second inner side surface and the second upper surface, and a second outer corner portion between the second outer side surface and the second upper surface; and
the second recess includes a second inner recess having a second inner curved surface provided in the second inner corner portion, and a second outer recess having a second outer curved surface provided in the second outer corner portion.

4. The insulating chip according to claim 3, wherein an arc length of a cross-sectional shape of the second inner curved surface is equal to an arc length of a cross-sectional shape of the second outer curved surface.

5. The insulating chip according to claim 1, wherein
the plurality of insulating layers include a third insulating layer in which the second conductor is provided, and a fourth insulating layer laminated on the third insulating layer;
the third insulating layer and the fourth insulating layer each include a thin insulating layer and a thick insulating layer provided on the thin insulating layer and having a smaller thermal expansion coefficient than a thermal expansion coefficient of the thin insulating layer; and
the thin insulating layer of the fourth insulating layer includes a second curved portion in contact with and extending along the second curved surface.

6. The insulating chip according to claim 5, wherein
the thick insulating layer of the third insulating layer has a side surface forming a second groove in which the second conductor is embedded;
the side surface of the thick insulating layer of the third insulating layer includes a second exposed side surface exposed through the second conductor by the second recess; and
the thin insulating layer of the fourth insulating layer includes:
a second side surface portion covering the second exposed side surface and connected to the second curved portion;
a second upper surface portion covering an upper surface of the thick insulating layer and connected to the second side surface portion; and
a second conductor upper surface portion covering a second upper surface of the second conductor and connected to the second curved portion.

7. The insulating chip according to claim 1, wherein the second conductor has a tapered shape in which the second side surface is inclined such that the second conductor narrows from the second upper surface toward the second lower surface.

8. The insulating chip according to claim 1, wherein
the first conductor includes:
a first upper surface;
a first lower surface opposite to the first upper surface;
a first side surface provided between the first upper surface and the first lower surface in the thickness direction; and
a first corner portion between the first side surface and the first upper surface; and
the first corner portion includes a first recess having a first curved surface recessed so as to be convex inward toward the first conductor.

9. The insulating chip according to claim 8, wherein a cross-sectional shape of the first curved surface is arc-shaped.

10. The insulating chip according to claim 9, wherein an arc length of the cross-sectional shape of the first curved surface is equal to an arc length of a cross-sectional shape of the second curved surface.

11. The insulating chip according to claim 8, wherein:
the first conductor has a prescribed width;
the first side surface includes:
a first inner side surface on an inner side in a width direction of the first conductor; and
a first outer side surface on an outer side in the width direction of the first conductor;
the first corner portion includes:
a first inner corner portion between the first inner side surface and the first upper surface; and
a first outer corner portion between the first outer side surface and the first upper surface; and
the first recess includes:
a first inner recess including a first inner curved surface provided at the first inner corner portion; and
a first outer recess including a first outer curved surface provided at the first outer corner portion.

12. The insulating chip according to claim 11, wherein an arc length of a cross-sectional shape of the first inner curved surface is equal to an arc length of a cross-sectional shape of the first outer curved surface.

13. The insulating chip according to claim 8, wherein
the plurality of insulating layers include:
a first insulating layer in which the first conductor is provided; and
a second insulating layer laminated on the first insulating layer;
both the first insulating layer and the second insulating layer include:
a thin insulating layer; and
a thick insulating layer provided on the thin insulating layer and having a smaller thermal expansion coefficient than a thermal expansion coefficient of the thin insulating layer; and
the thin insulating layer of the second insulating layer includes a first curved portion in contact with and extending along the first curved surface.

14. The insulating chip according to claim 13, wherein
the thick insulating layer of the first insulating layer has a side surface forming a first groove in which the first conductor is embedded;
the side surface of the thick insulating layer of the first insulating layer includes a first exposed side surface exposed through the first conductor by the first recess, and
the thin insulating layer of the second insulating layer includes:
a first side surface portion covering the first exposed side surface and connected to the first curved portion;
a first upper surface portion covering an upper surface of the thick insulating layer of the first insulating layer and connected to the first side surface portion; and
a first conductor upper surface portion covering the first upper surface of the first conductor and connected to the first curved portion.

15. The insulating chip according to claim 8, wherein the first conductor has a tapered shape in which the first side surface is inclined such that the first conductor narrows from the first upper surface toward the first lower surface.

16. The insulating chip according to claim 1, wherein the first conductor and the second conductor include a coil.

17. The insulating chip according to claim 16, wherein:
the second conductor includes a pair of second straight portions and a pair of second curved portions connecting ends of the pair of second straight portions; and
the second recess is continuously provided across both the pair of second straight portions and the pair of second curved portions.

18. The insulating chip according to claim 8, wherein:
the first conductor and the second conductor include a coil;
the first conductor includes a pair of first straight portions and a pair of first curved portions connecting ends of the pair of first straight portions; and
the first recess is continuously provided across both the pair of first straight portions and the pair of first curved portions.

19. The insulating chip according to claim 1, wherein the first conductor and the second conductor include electrode plates.

20. A signal transmission device comprising:
the insulating chip according to claim 1; and
a first circuit and a second circuit electrically connected to the insulating chip, wherein
the first circuit and the second circuit are configured to transmit a signal through the insulating chip.
